(19) United States
(12) Patent Application Publication
(10) Pub. No.: US 2026/0337811 A1
(43) Pub. Date: Oct. 29, 2026

(54) Method of Making and Using Precious Metal Nanocrystals

(71) Applicant: Brown University, Providence, RI (US)

(72) Inventors: Ou Chen, Barrington, RI (US); Yasutaka Nagaoka, East Greenwich, RI (US); Zhenyang Liu, Providence, RI (US)

(21) Appl. No.: 19/551,544

(22) Filed: Feb. 26, 2026

Related U.S. Application Data
(60) Provisional application No. 63/763,809, filed on Feb. 26, 2025.
(60) Provisional application No. 63/763,806, filed on Feb. 26, 2025.
(60) Provisional application No. 63/765,452, filed on Feb. 28, 2025.
(60) Provisional application No. 63/765,427, filed on Feb. 28, 2025.

(51) Int. Cl. C30B 7/14; C30B 29/02; C30B 33/00

(52) U.S. Cl. CPC C30B 7/14; C30B 29/02; C30B 33/00

(57) ABSTRACT

A method of making precious metal nanocrystals is provided. The method includes combining a precious metal salt, a reducing agent, a nanocrystal growth promoter agent, a solvent, and a catalyst, and heating to form precious metal nanocrystals. Precious metal nanocrystals can be used to form superlattice structures.

### CROSS-REFERENCE TO RELATED APPLICATIONS

This application claims the benefit of U.S. Ser. No. 63/763,809 filed Feb. 26, 2025, U.S. Ser. No. 63/763,806 filed Feb. 26, 2025, U.S. Ser. No. 63/765,452 filed Feb. 28, 2025 and U.S. Ser. No. 63/765,427 filed Feb. 28, 2025 each of which is hereby incorporated by reference in its entirety.

### FEDERALLY SPONSORED RESEARCH AND DEVELOPMENT

This invention was made with government support under grant number DMR-1943930 awarded by the National Science Foundation. The government has certain rights in the invention.

### TECHNICAL FIELD

The present disclosure relates to methods of making and using precious metal nanocrystals. The present disclosure also relates to precious metal nanocrystals made by the methods and to methods of using such precious metal nanocrystals and to superlattices and films made with precious metal nanocrystals.

### DESCRIPTION OF THE RELATED ART

Methods of making and using precious metal nanocrystals and nanoparticles are known. See for example Zhang et al., Robust, Reproducible, and Scalable Synthesis of Silver Nanocube, Chem. Eur. J. 2024, 30, e202400833 (May 23, 2024); Hang et al., Plasmonic silver and gold nanoparticles: shape- and structure-modulated plasmonic functionality for point-of-caring sensing, bio-imaging and medical therapy, Chem Soc Rev. 2024 Mar. 18; 53(6):2932-2971; Peng, J. Am. Chem. Soc. 2018, 140, 50, 17734-17742.

In nanocrystal (“NC”) synthesis, a choice of solvent is a primal factor of the reaction system, polar vs. non-polar solvents. Due to the wider available temperature range that non-polar solvents can provide, various NC synthesis protocols have been developed across semiconductor, metal, and metal-oxide nanocrystals—particularly in the ~4-20 nm regime. However, syntheses of Ag-NCs in non-polar phases often yield products with compromised shape uniformity, broader size dispersions, and/or reduced crystallinity. A lack of qualities of these characteristics typically stems from unregulated nucleation and growth and poorly surpassing the competing reactions. Notably, Peng, J. Am. Chem. Soc. 2018, 140, 50, 17734-17742, overcame the issue by employing hydrogen chloride as catalyst in a hot-injection reaction system, demonstrating highly monodisperse, spherical, single-crystalline Ag-NCs formation with diameters of 7-20 nm. However, their multi-hot-injection approach relies on injection growth control, which, while effective, introduces practical drawbacks, including sensitivity to subtle variations in processing conditions, limited shape programmability, challenges in reproducibility, and difficulties in scale-up.

### SUMMARY

Aspects of the present disclosure are directed to methods of making precious metal nanocrystals. Aspects of the present disclosure are directed to methods of making precious metal nanocrystals using an oil phase. According to certain aspects, the present disclosure provides a method where a precious metal reactant is mixed with a catalyst, such as copper catalyst, in a solvent medium. According to one aspect, copper plays a central role in catalyzing smooth nucleation-and-growth, leading to Ag-NCs with single crystal-domains and controlled shapes. The mixture is heated to produce precious metal nanocrystals in a thermal decomposition method. Precious metal nanocrystal synthesis may be carried out under an inert atmosphere or under air. According to one aspect, the precious metal nanocrystals are monodisperse. According to one aspect, the precious metal nanocrystals are single-crystalline. According to one aspect, the method may be described as “one-pot” since the precious metal reactant and the copper catalyst are combined in a single reaction vessel in a reaction medium which is heated to catalyze formation of the precious metal nanocrystals. According to one aspect, the reactants and reaction conditions can be altered to form a particular size or diameter nanocrystal and a particular shape nanocrystal. In this aspect, the reaction conditions are “tunable” to form a nanocrystal of desired size or diameter and shape. According to one aspect, the reactants are heated in a step-wise fashion. According to one aspect, the reactants are heated in a first step to produce precious metal clusters. According to one aspect, the reactants are heated in a second step where the precious metal clusters form precious metal nanocrystals. The method described herein advantageously produces precious metal nanocrystals characterized by high crystallinity. The method described herein advantageously produces precious metal nanocrystals characterized by a narrow size distribution of diameter tunable within a range of about 3 nm to about 15 nm, i.e. tunable diameters within a range of about 3 nm to about 15 nm. According to one aspect, the methods described herein produce precious metal nanocrystals of particular size or diameter, such as a product size distribution being less than 7%, where at least about 95% of the precious metal nanocrystals are within about ±15% range of the intended size or diameter. For example, where the intended size is a 10 nm diameter, the one pot methods described herein produce precious metal nanocrystals where at least about 95% of the precious metal nanocrystals have a diameter from about 9.3 nm to 10.7 nm. The method described herein advantageously produces precious metal nanocrystals characterized as having a truncated octahedral (referred to in the art as “mecon”) morphology, spherical morphology or a morphology intermediate a mecon morphology and a spherical morphology. According to one aspect, the precious metal nanocrystals can be functionalized, such as after synthesis, with one or more ligands so as to provide advantageous properties. Exemplary ligands include a sulfur functionality and include thiol-based molecules and thiophen-based molecules. According to one aspect, the method described herein can advantageously be scaled up to provide precious metal nanocrystal production on a larger scale, such as a commercial scale.

Further features and advantages of certain embodiments of the present invention will become more fully apparent in the following description of embodiments and drawings thereof, and from the claims.

### BRIEF DESCRIPTION OF DRAWINGS

The patent or application file contains drawings executed in color. Copies of this patent or patent application publication with the color drawings will be provided by the Office upon request and payment of the necessary fee. The foregoing and other features and advantages of the present embodiments will be more fully understood from the following detailed description of illustrative embodiments taken in conjunction with the accompanying drawings in which:

FIGS. 1A-1I are directed to the synthesis of Ag-NCs. FIG. 1(A) Low-magnification STEM image. FIG. 1(B) HR-TEM image of one individual Ag-NC. FIG. 1(C) Computer-generated atomic model (left) and framework of mecon-shaped Ag-NCs. FIG. 1(D) XRD spectrum of Ag-NCs. FIG. 1(E) UV-Vis absorption spectra. FIG. 1(F) STEM image of mecon-shaped Ag-NC SLs. FIG. 1(G) WAED pattern from the selected area. FIG. 1(H) HR-TEM image (left) and relevant computer-generated atomic model (right) of mecon-shaped Ag-NC SLs. FIG. 1(I) Photograph of 1.3 g Ag-NC SLs from a scale-up one-pot heating-up synthesis.

FIG. 2 is directed to a Powder XRD spectrum of Ag-NCs. XRD spectrum of mecon-shaped Ag-NC presented in FIG. 1A-1I. The detailed results are described in FIG. 3.

FIG. 3 is a Table with results of the XRD shown in FIG. 2.

FIG. 4 is directed to an experimental reaction setup using under-air synthesis

FIGS. 5A-5H are directed to data regarding Ag-NCs. FIG. 5(A) UV-vis absorption spectra of aliquots collected during a typical Ag-NC formation reaction. FIGS. 5(B-E) Representative absorption spectra for each reaction phase: FIG. 5(B) Phase 1 (room temperature), FIG. 5(C) Phase 2 (70 °C, 10 min), FIG. 5(D) Phase 3 (100 °C), and FIG. 5(E) Phase 4 (170 °C, 0 min). Experimental spectra (solid lines) were fit (dashed lines) using the Multipeak Fitting function in Igor Pro with Lorentzian peak components (pale purple). FIG. 5(F) Minimum surface energies of Ag(111), Ag(100), and Ag(110) as a function of the solution-phase Cu chemical potential m_{Cu} when Cu is adsorbed on top of the Ag surfaces. Wulff shapes accounting for {111} (blue), {100} (orange), and {110} (green) facets are shown for three different values of m_{Cu}. FIG. 5(G) with reference to FIG. 14. Surface energies of Ag(111), Ag(100), and Ag(110) as a function of the solution-phase Cu chemical potential m_{Cu} when Cu is included as a layer underneath the top Ag layer. Wulff shapes accounting for {111} (blue), {100} (orange), and {110} (green) facets at three different values of m_{Cu}. FIG. 5(H). The side profile of the top four layers of different Ag slabs of a seven-layer thickness. (top left) pure Ag slab with no stacking faults; (top center) pure Ag slab with a stacking fault on the top layer; (top right) pure Ag slab with a stacking fault under the top layer; (middle left) slab with a Cu layer under the top layer; (middle right) slab with a stacking fault on the top layer and a layer of Cu under the top layer; (bottom left) slab with a Cu layer on top of the Ag slab; (bottom center) slab with Cu on the top layer as a stacking fault; (bottom right) slab with Ag stacking fault under the Cu layer.

FIGS. 6A-6C are directed to absorption spectra of aliquots sampled during the synthesis of mecon-shaped Ag-NCs. FIG. 6(A) UV-vis absorption spectra of reaction aliquots collected from room temperature to 170 °C. FIG. 6(B) Absorption spectra after the reaction reaches 170 °C. Panel (A) is plotted in arbitrary units, whereas panel (B) is plotted on an absolute absorbance scale. FIG. 6(C) Maximum peak intensity as a function of reaction progress.

FIG. 7 is directed to MALDI-TOF spectra for Phase 1 samples. (Left) MALDI-TOF spectrum over m/z 0-5000 and (right) expanded view over m/z 350-800. The top traces show the Phase 1 sample and the bottom spectra show the matrix-only blank (DCTB). Given the atomic mass of Ag (~108 Da), the major peaks at m/z 432 and 540 are assigned to Ag4 and Ag5, respectively.

FIG. 8 is directed to MALDI-TOF spectra for Phase 3 samples.

FIGS. 9A-9B are directed to Ag-NCs synthesized in the absence of oleic acid. FIG. 9(A) UV-Vis absorption spectra of reaction aliquots collected at different time points during the synthesis. FIG. 9(B) TEM images of Ag nanocrystals collected after the completion of the reaction.

FIG. 10 is directed to the effect of Cu acetate on Ag-NC synthesis. Comparison of Ag nanocrystals synthesized without (top row) and with (bottom row) Cu acetate. (Left) XRD patterns and (right) UV-Vis absorption spectra of the corresponding samples.

FIGS. 11A-11B are directed to Ag-NCs synthesized in the absence of Cu acetate. FIG. 11(A) UV-Vis absorption spectra of reaction aliquots collected at different time points during the synthesis. FIG. 11(B) TEM images of Ag nanocrystals collected after the completion of the reaction.

FIG. 12 is directed at ICP results.

FIG. 13 shows the minimum surface energies of Ag(111), Ag(100), and Ag(110) as a function of the solution-phase Cu chemical potential m_{Cu} when Cu is adsorbed on top of the Ag surfaces. Wulff shapes accounting for {111} (blue), {100} (orange), and {110} (green) facets are shown for three different values of m_{Cu}.

FIG. 14 is directed to surface energies of Ag(111), Ag(100), and Ag(110) as a function of the solution-phase Cu chemical potential m_{Cu} when Cu is included as a layer underneath the top Ag layer. Wulff shapes accounting for {111} (blue), {100} (orange), and {110} (green) facets at three different values of m_{Cu}.

FIGS. 15A-15H are directed to the side profile of the top four layers of different Ag slabs of a seven-layer thickness. A) pure Ag slab with no stacking fault; B) pure Ag slab with a stacking fault on the top layer; C) pure Ag slab with a stacking fault under the top layer; D) slab with a Cu layer under the top layer; E) slab with a stacking fault on the top layer and a layer of Cu under the top layer; F) slab with a Cu layer on top of the Ag slab; G) slab with Cu on the top layer as a stacking fault; H) slab with Ag stacking fault under the Cu layer.

FIGS. 16A-16I are directed to plasmonic properties of Ag-NCs as functions of size and shape. FIG. 16(A) Shape evolution of Ag-NC models from a mecon (λ=0) through intermediate shapes (λ=0.2, 0.4, 0.6, 0.8) to a sphere (λ=1.0). FIG. 16(B) Projections of the models along the [110]_{Ag-FCC} viewing direction (top) and simplified schematics highlighting anisotropy (bottom).

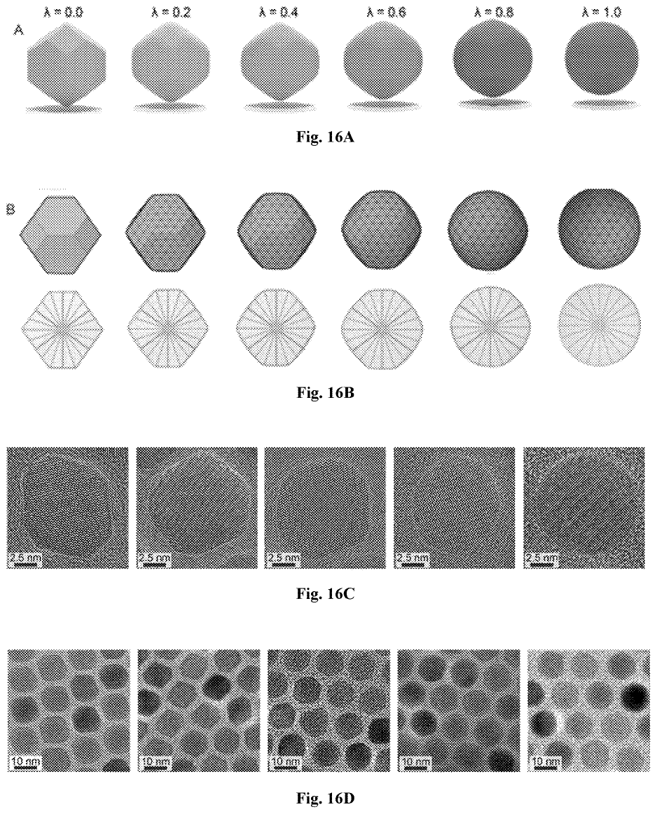

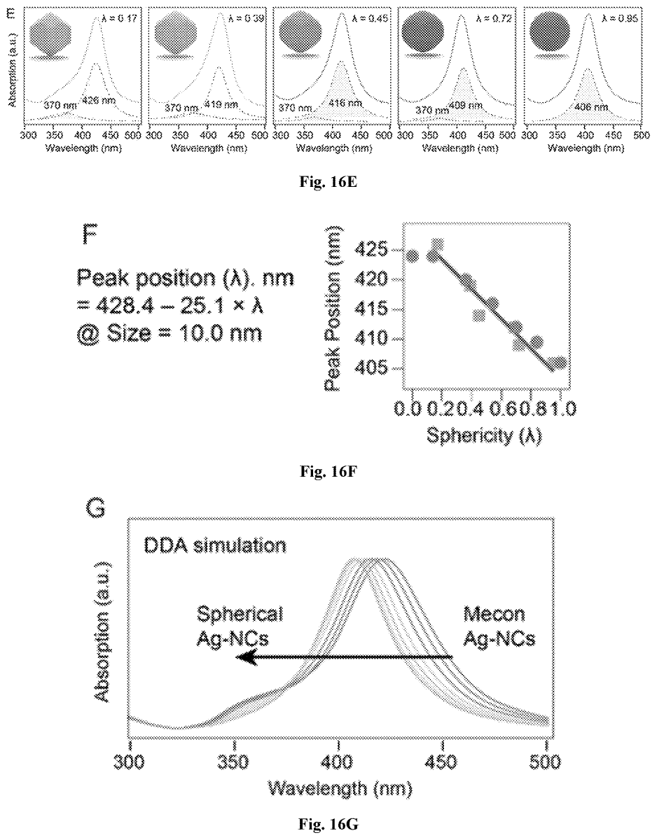

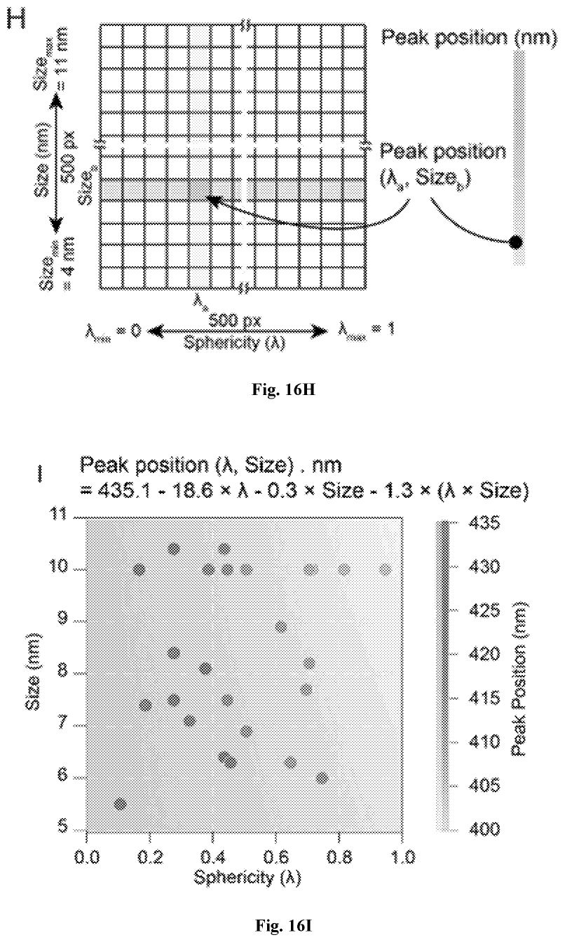

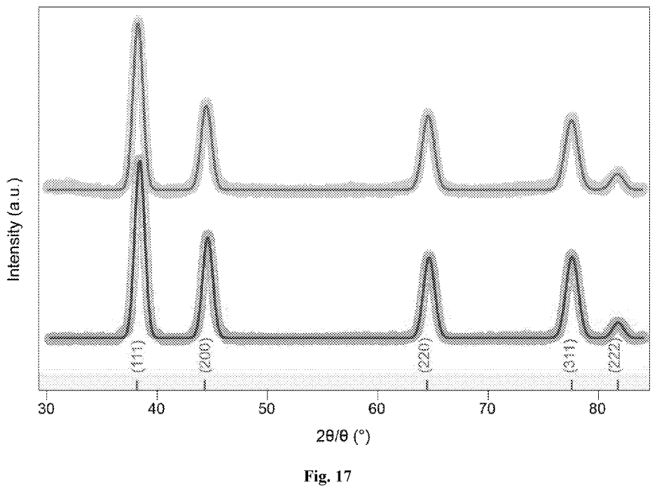

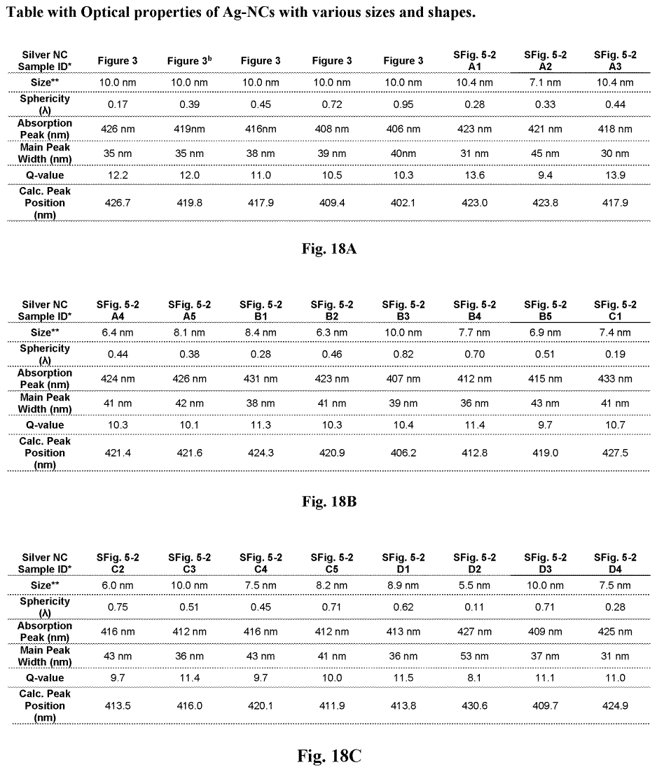

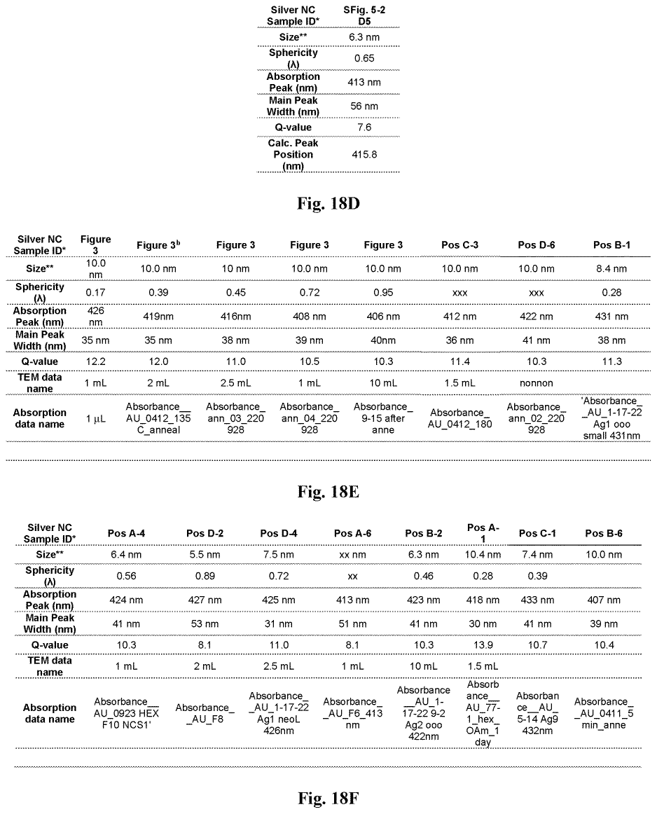

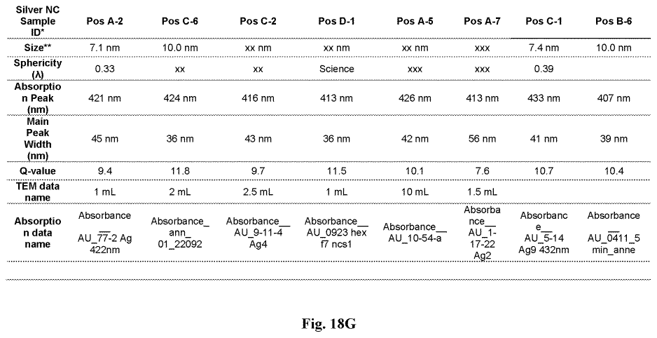

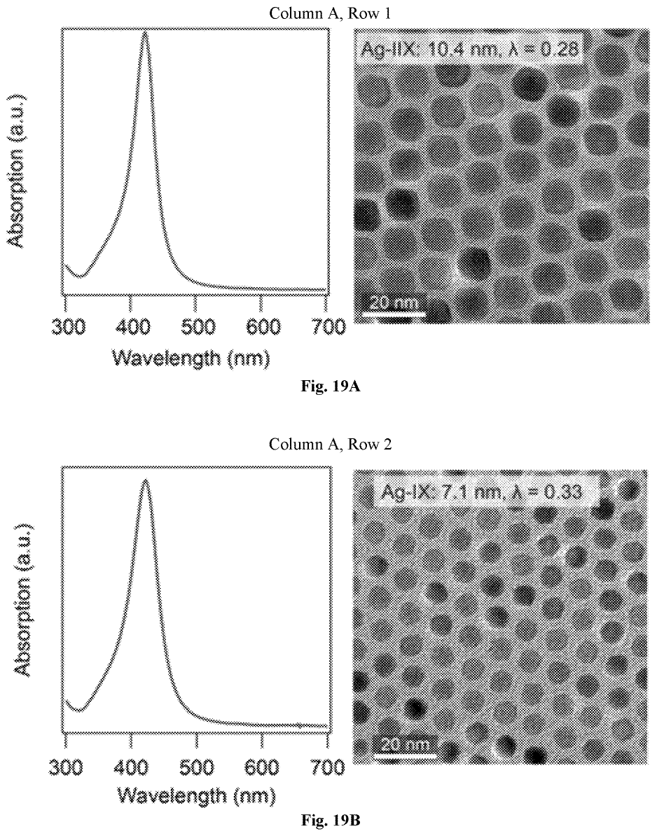

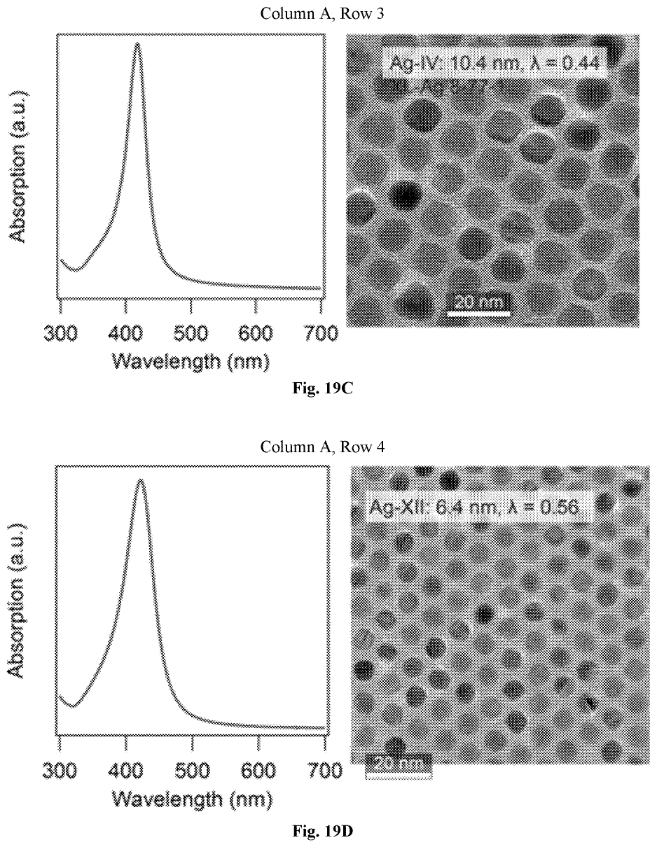

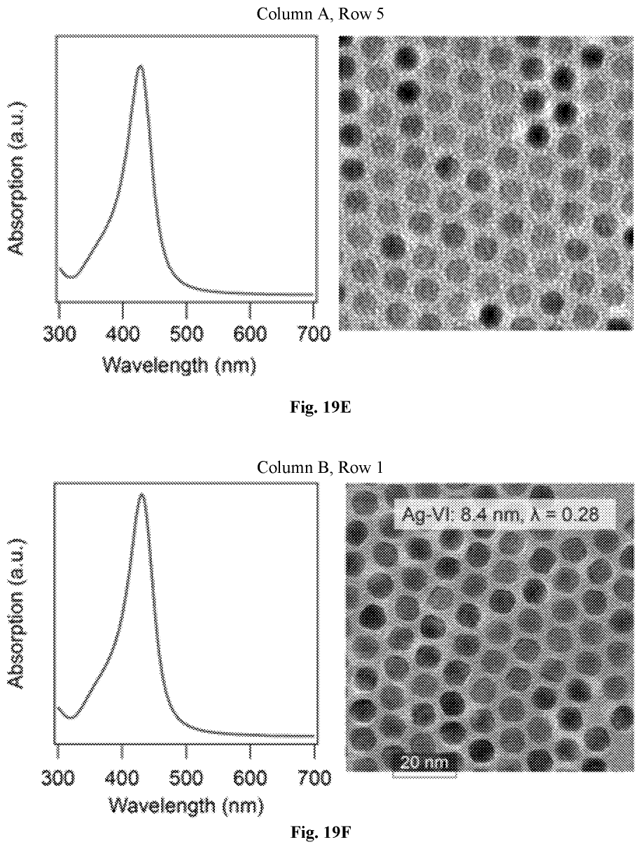

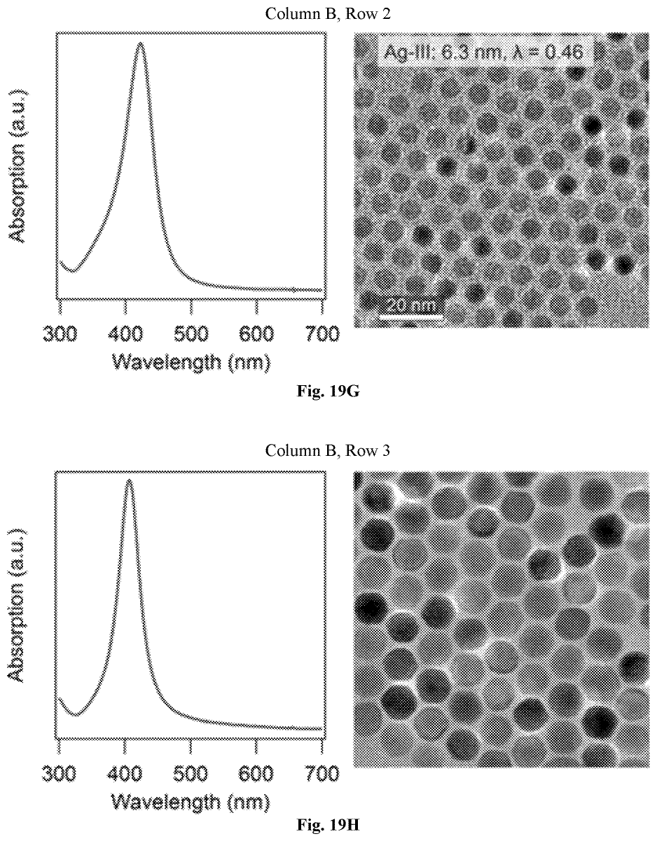

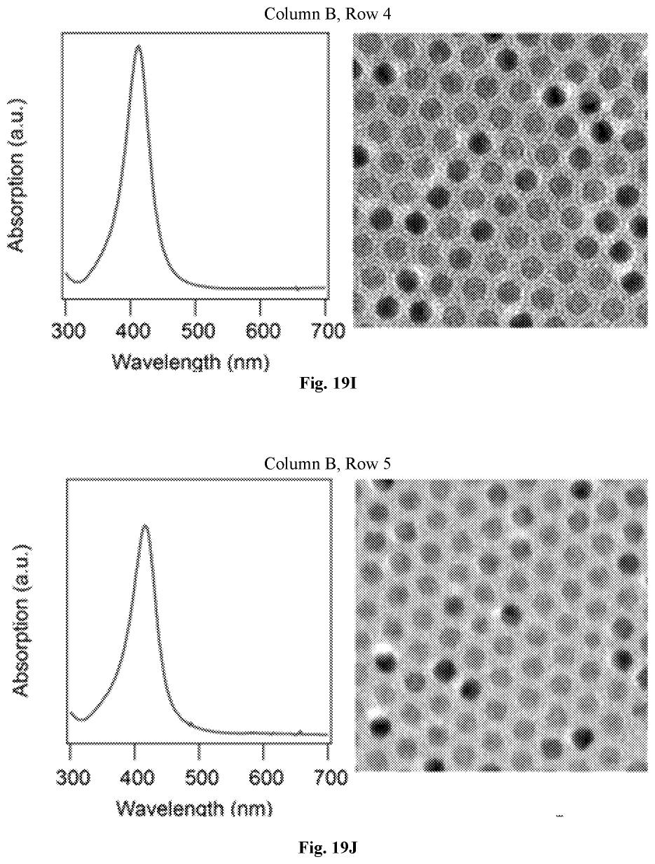

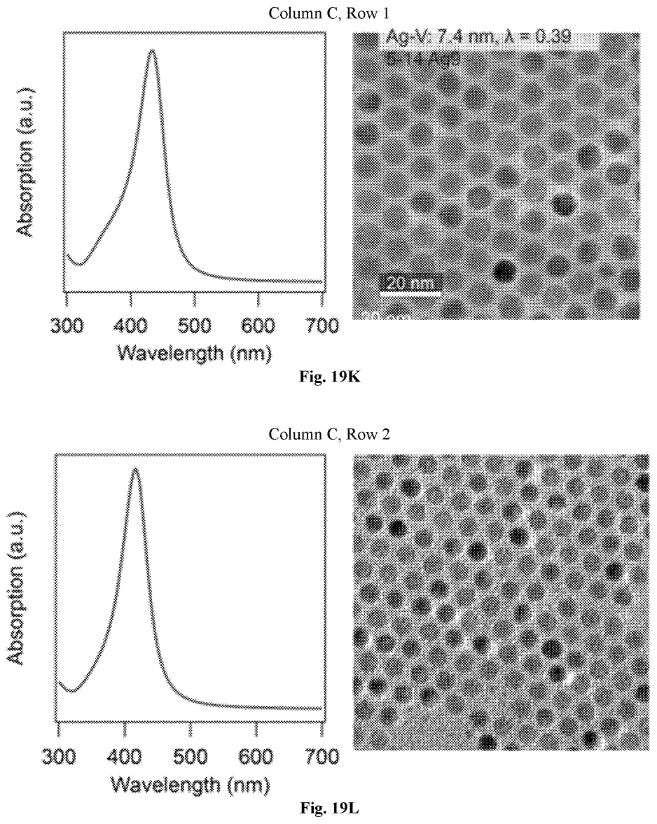

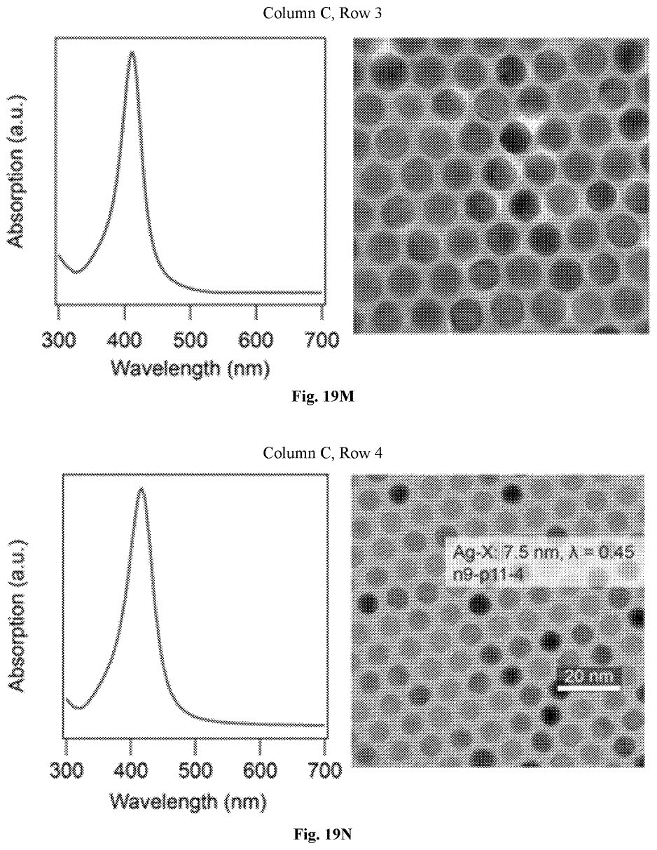

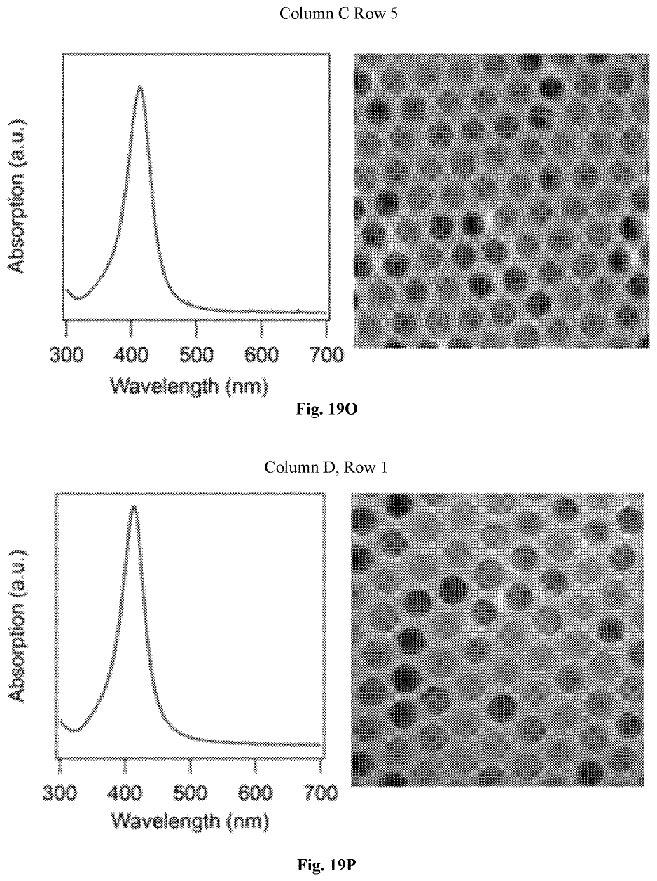

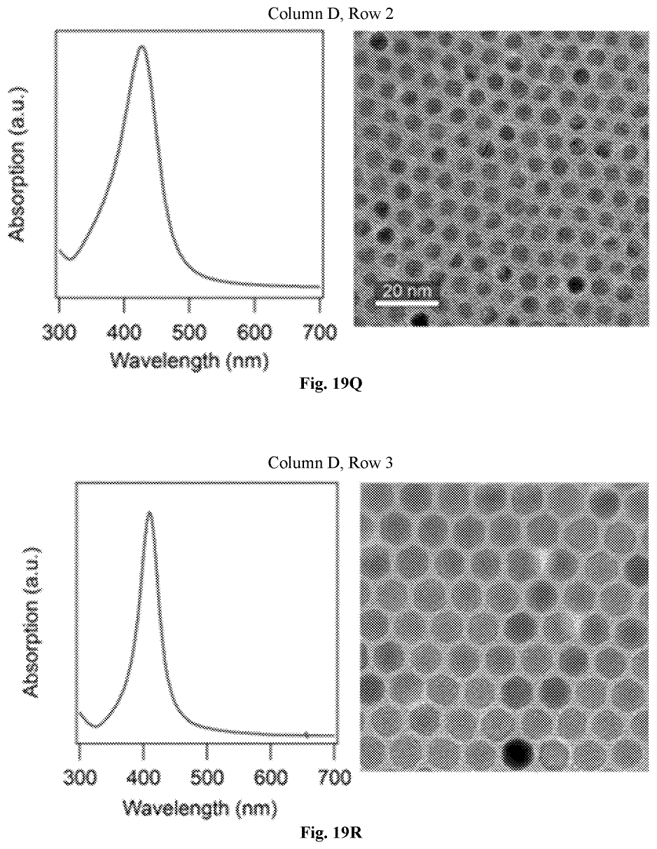

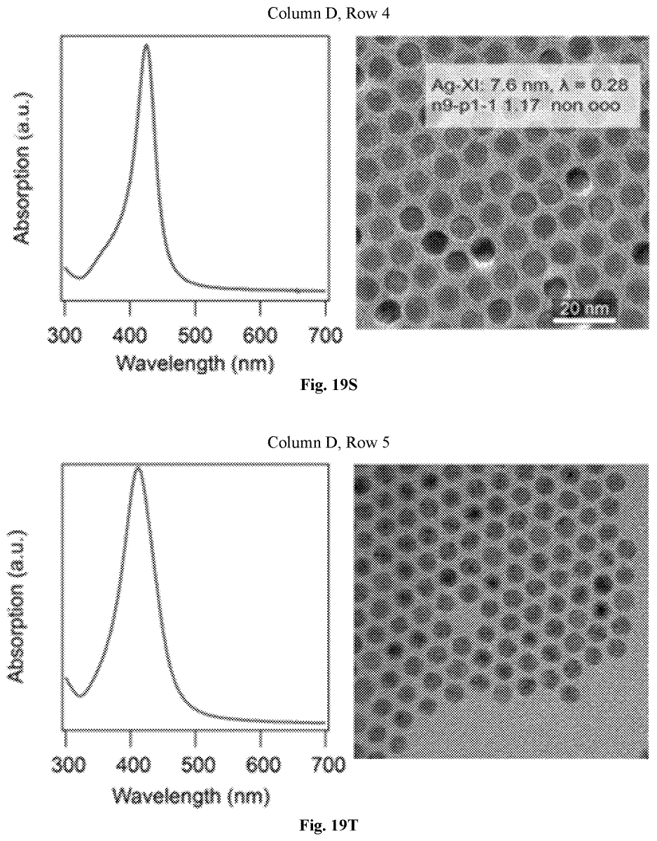

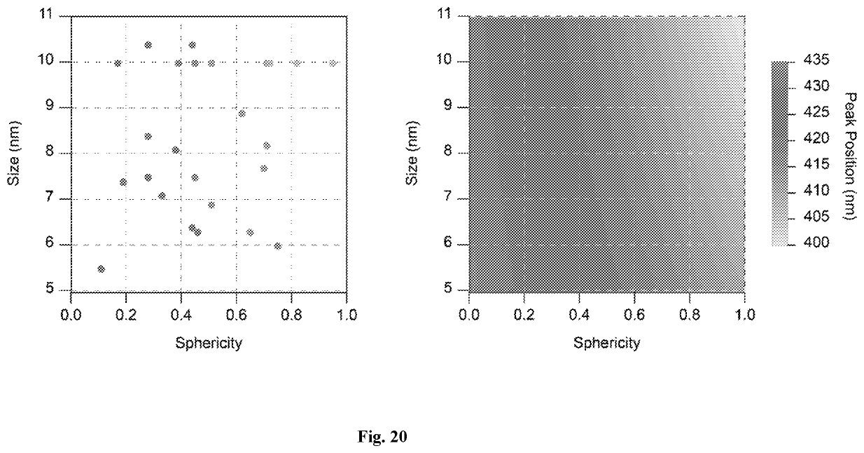

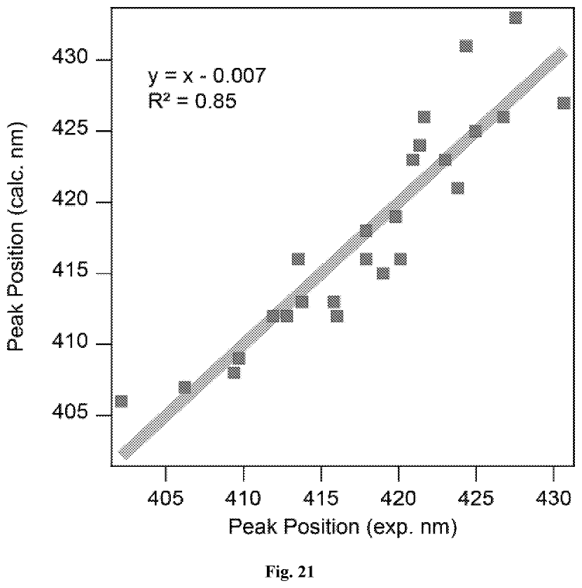

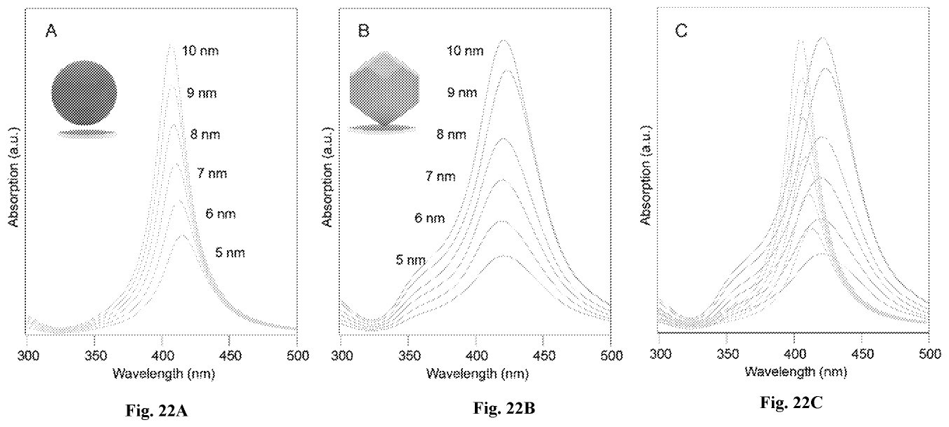

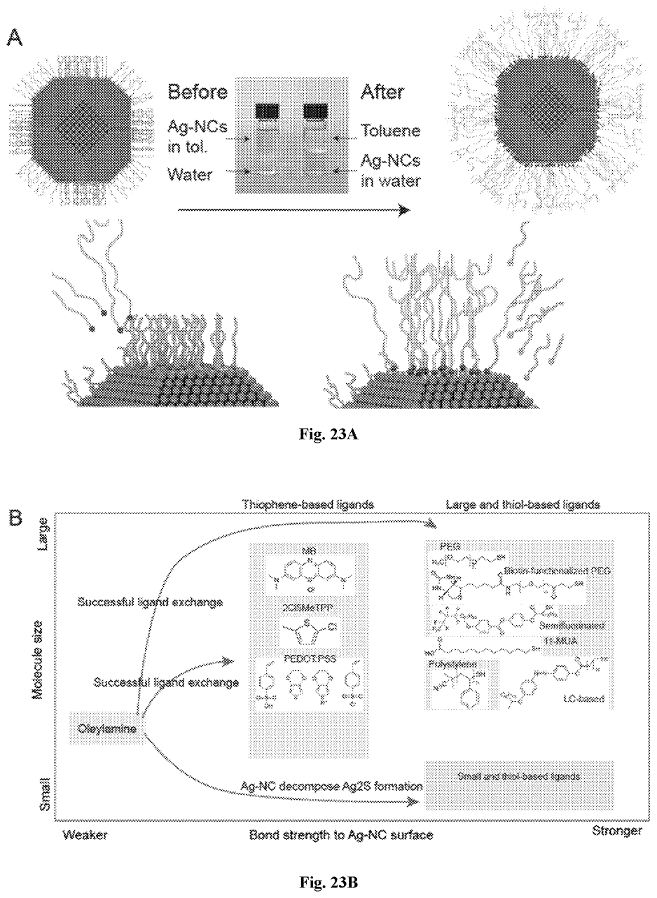

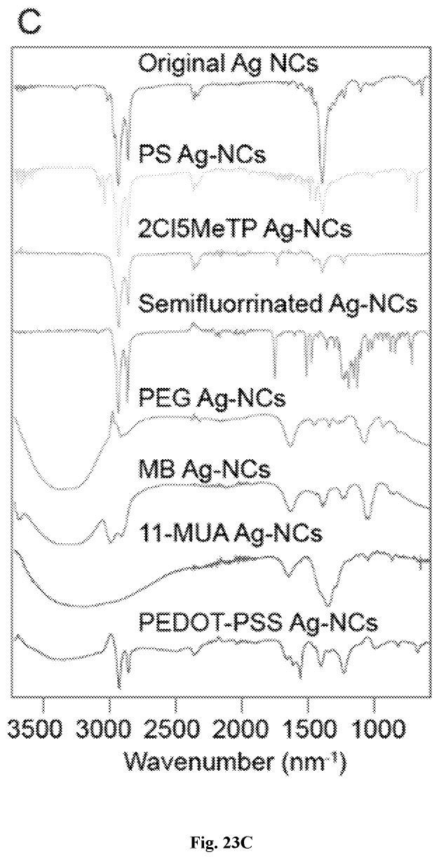

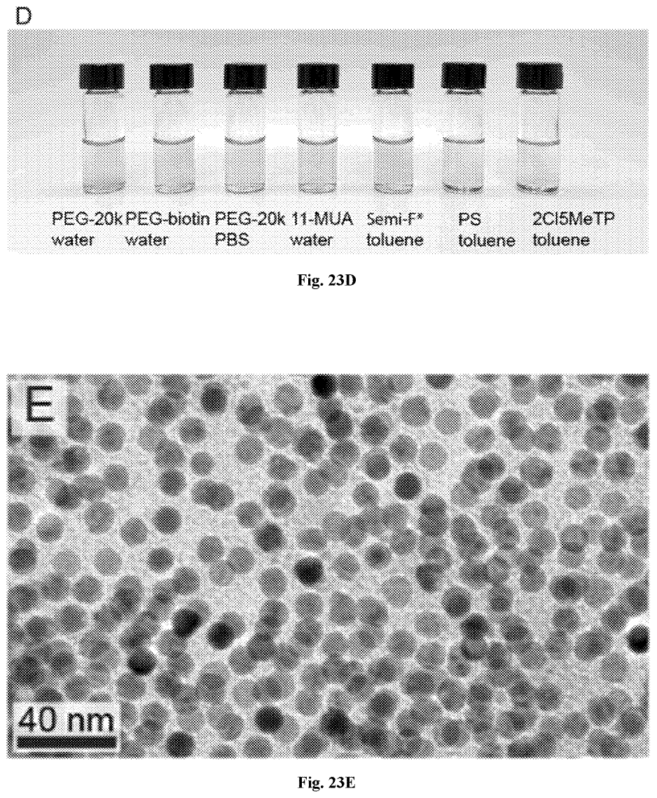

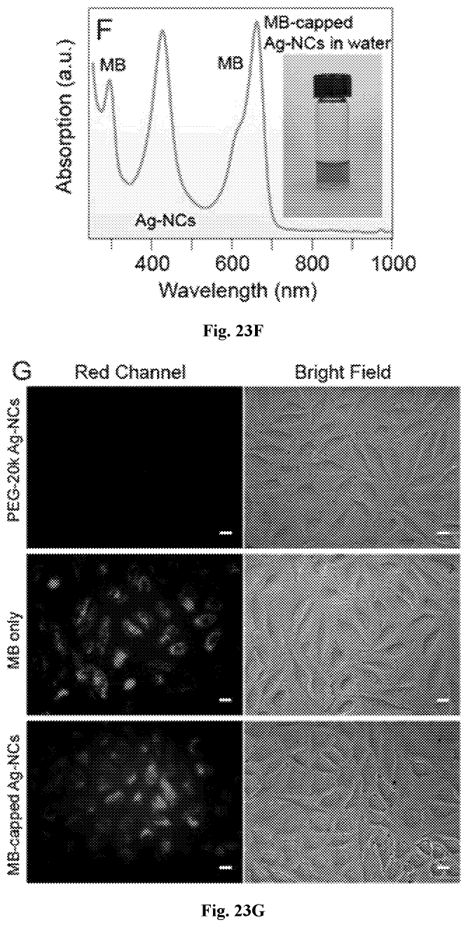

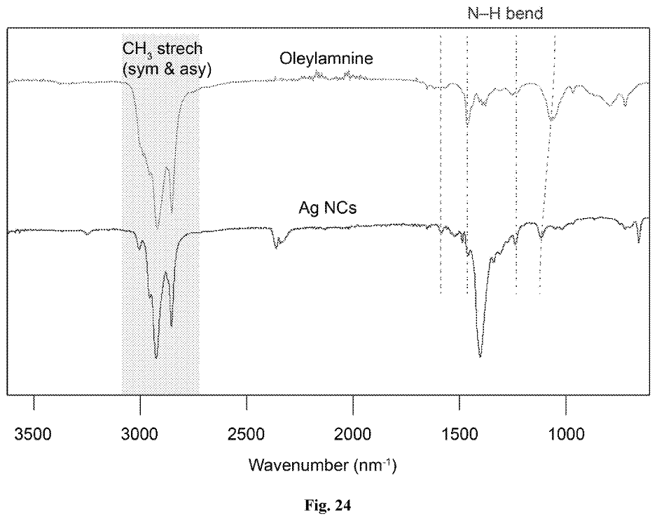

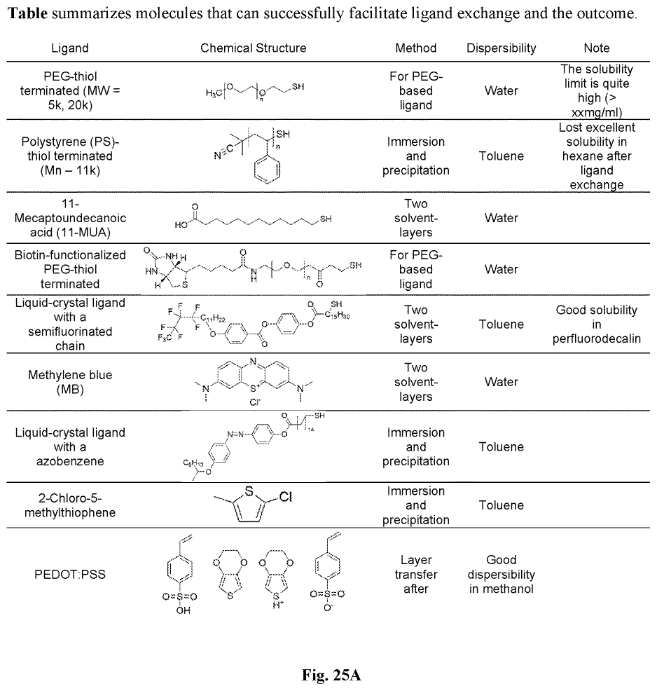

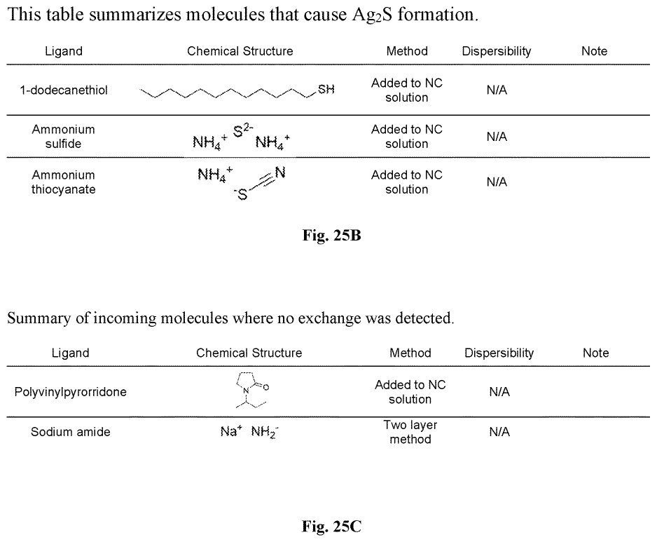

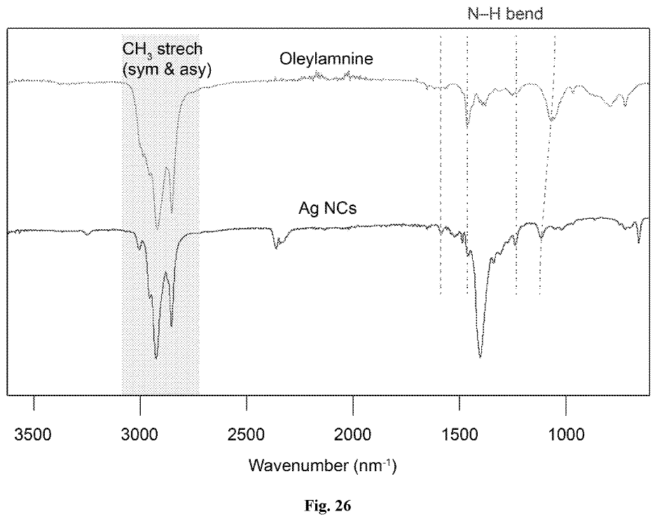

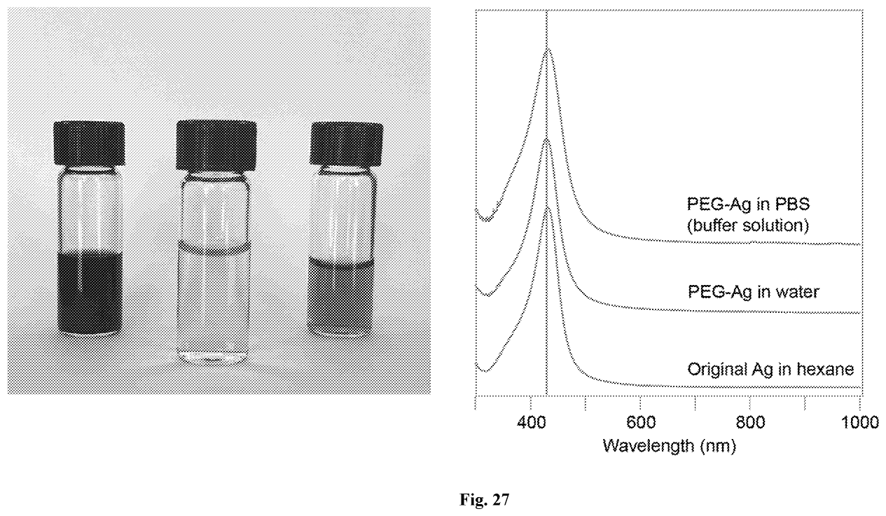

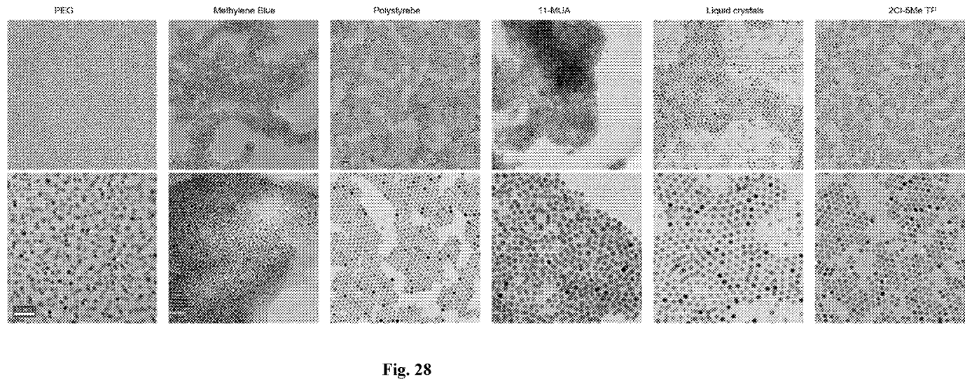

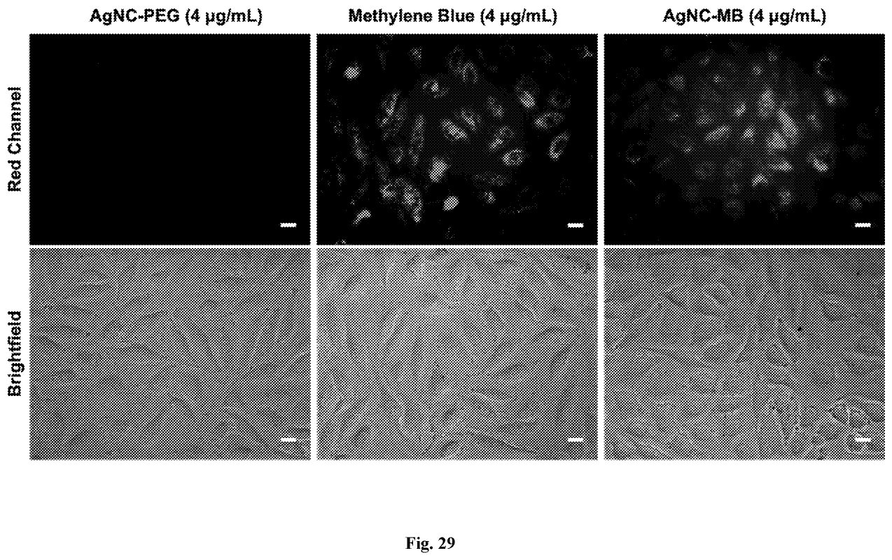

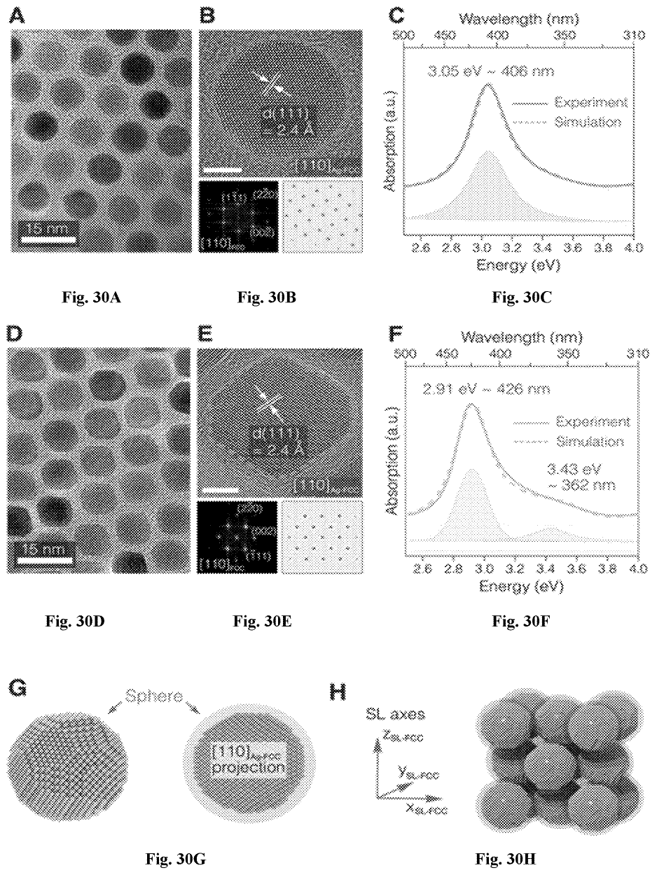

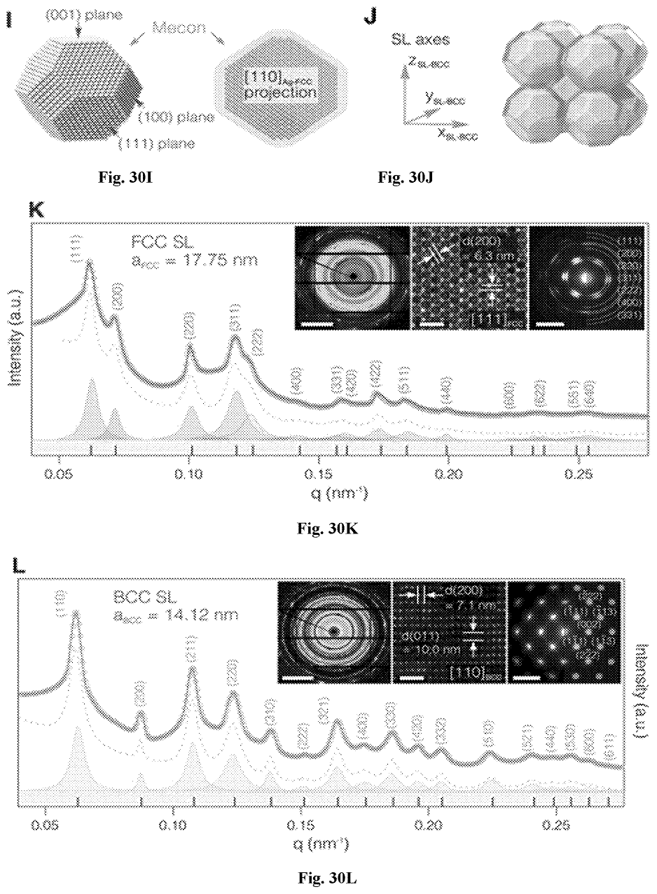

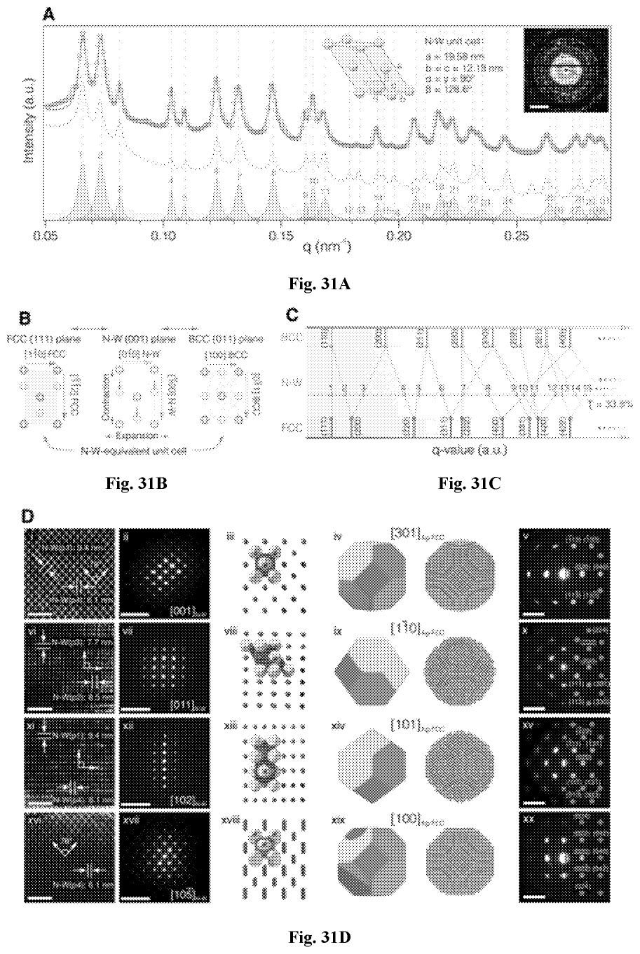

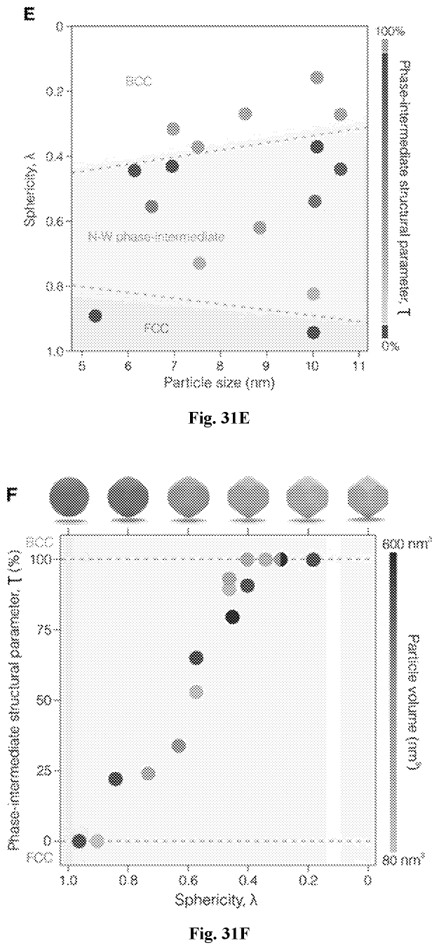

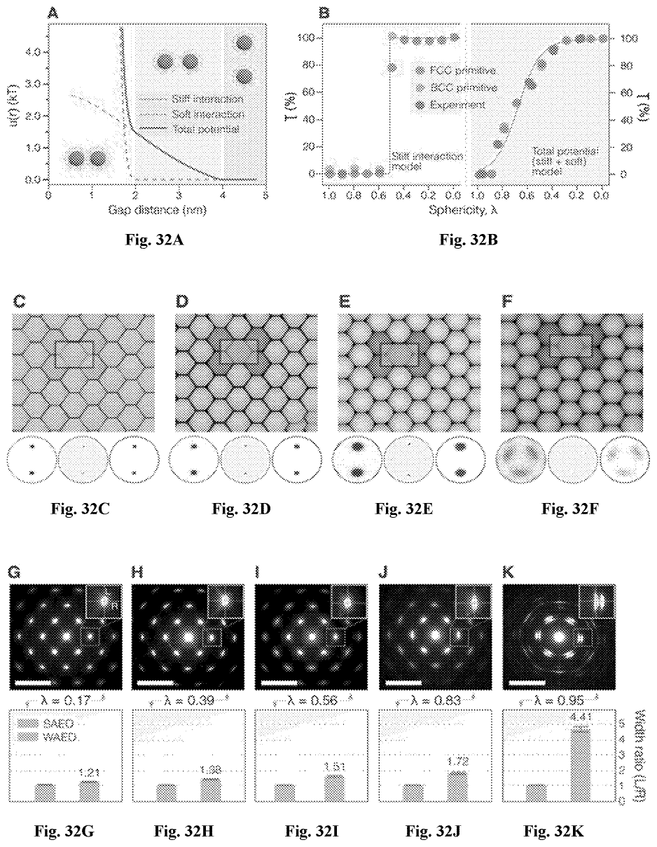

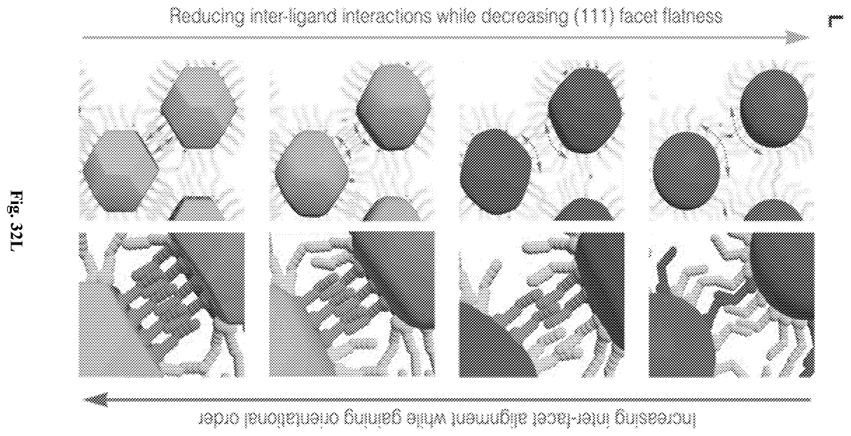

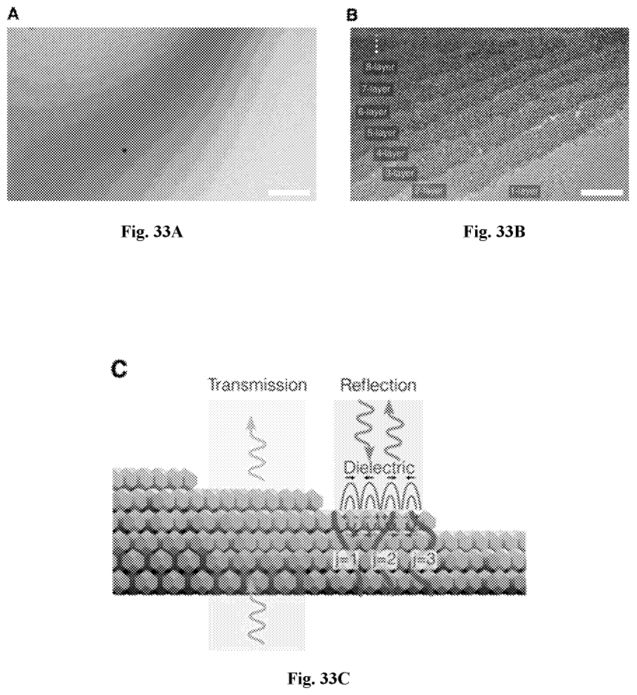

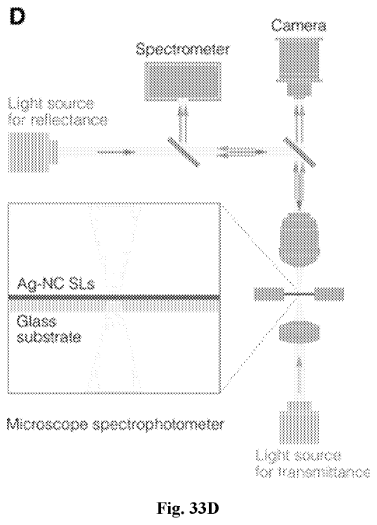

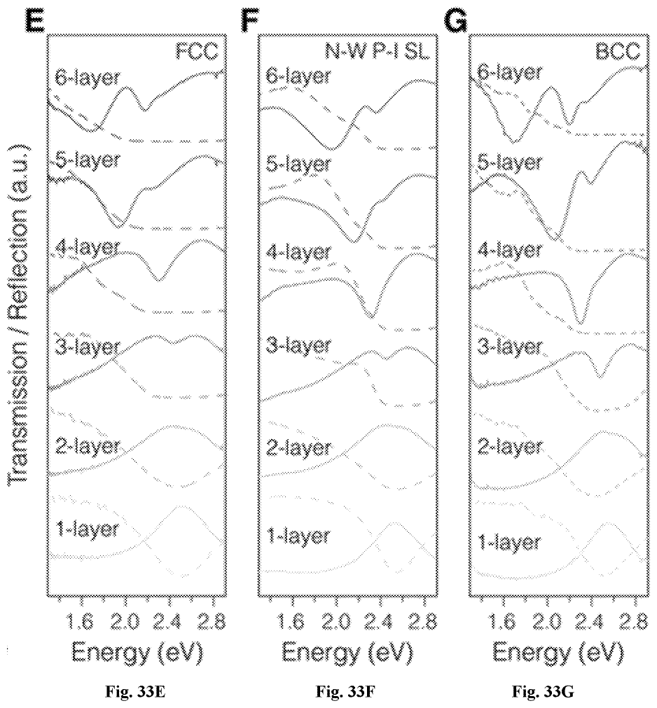

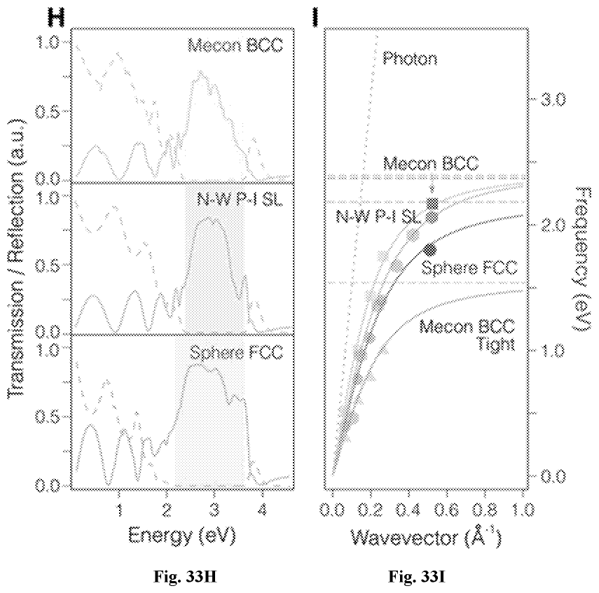

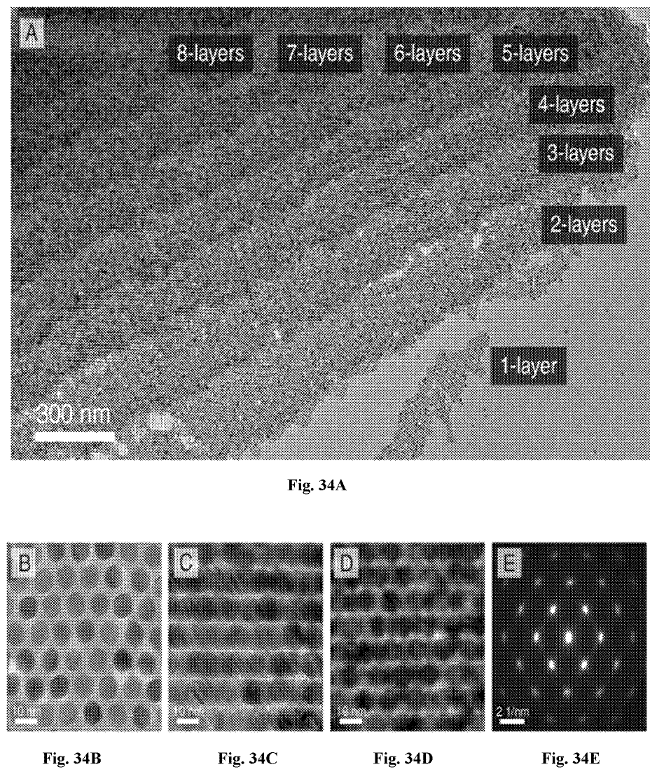

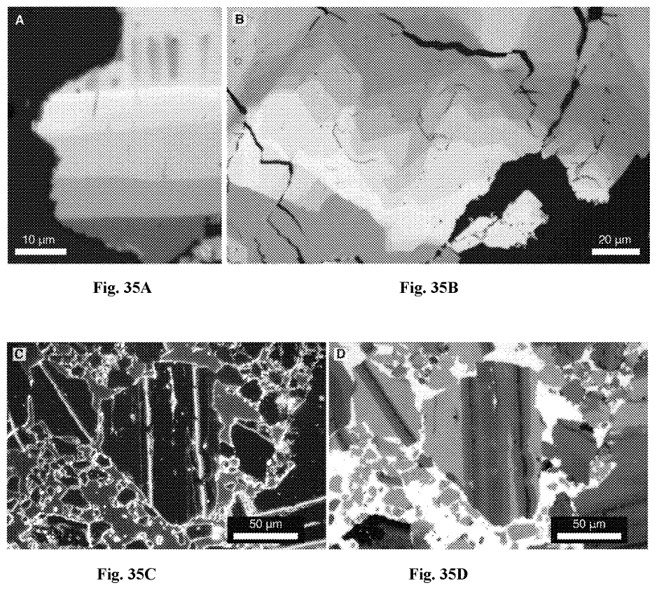

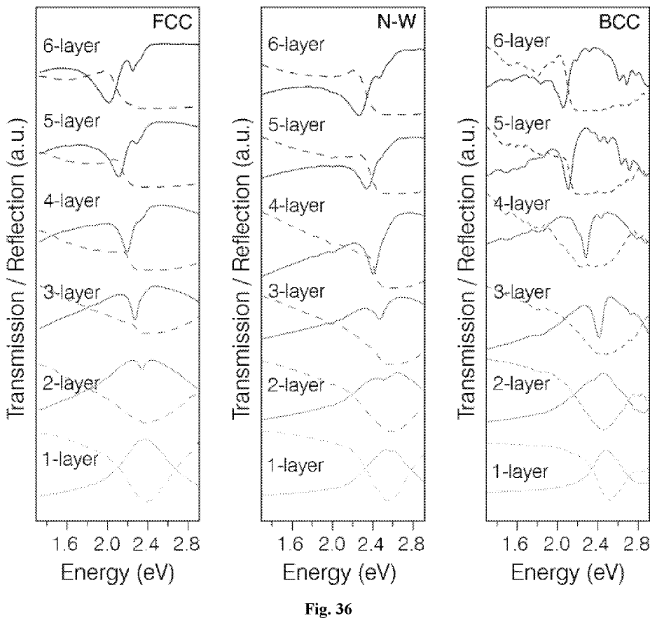

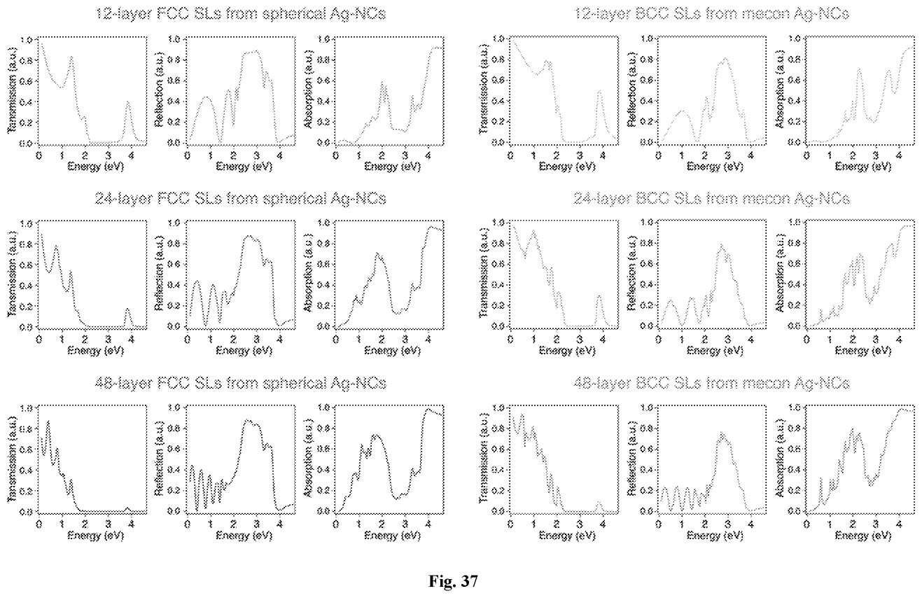

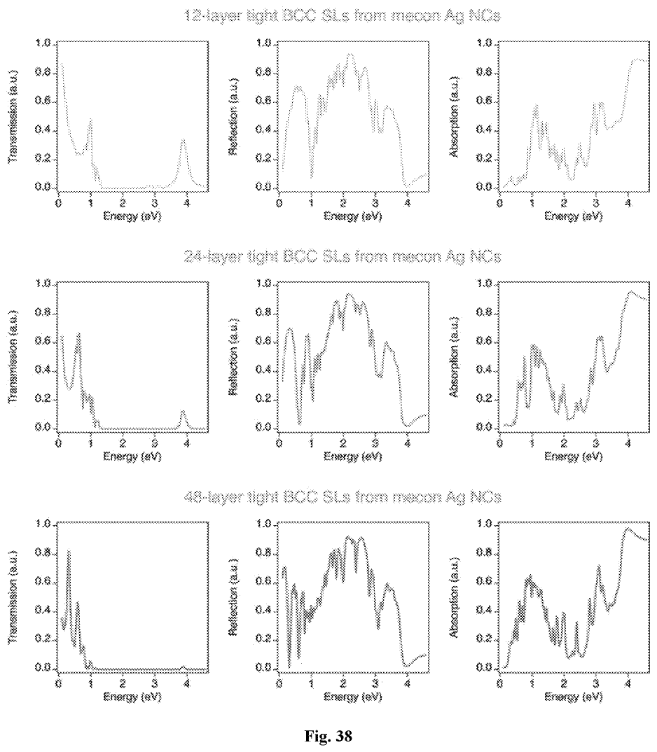

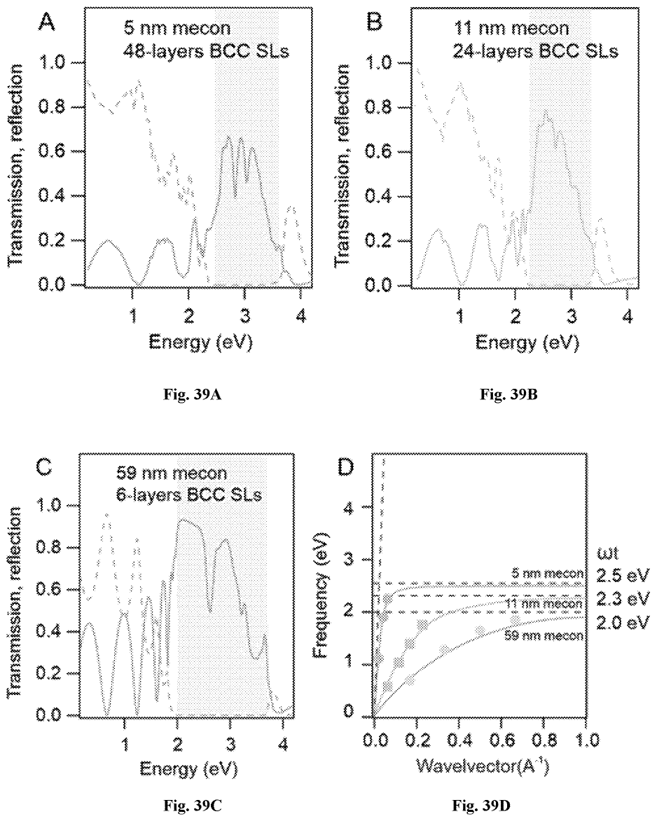

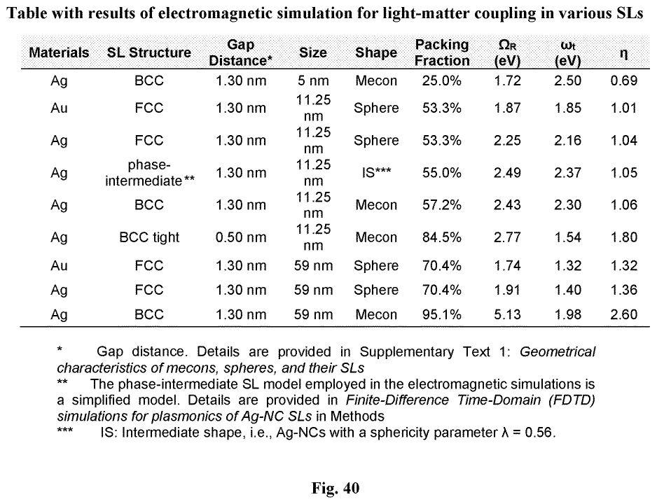

Green and purple lines denote the longest and shortest diameters, respectively. In crystallographic terms, red and purple lines correspond to distances between opposing {100} and opposing {111} facets, which were used to define the sphericity parameter, λ (see Supporting Information). FIGS. 16(C-E) are directed to experimental characterization of Ag NCs with similar size (~10.0 nm) and varying λ (0.17, 0.39, 0.45, 0.72, and 0.95; left to right): FIG. 16(C) low-magnification TEM images, FIG. 16(D) HR-TEM images, and FIG. 16(E) UV-Vis absorption spectra. Spectra (solid lines) were fit (dashed lines) using the Multipeak Fitting function in Igor Pro with Lorentzian components (individual peaks shown below each spectrum). FIG. 16(F) UV-Vis absorption peak position as a function of λ. Pink squares and purple circles represent peak positions extracted from experimental spectra FIG. 16(E) and from DDA simulations FIG. 16(G), respectively. FIG. 16(G) DDA-simulated absorption spectra for 10.0 nm Ag NCs with 0≤λ≤1. (H) Parameter-space mesh used to compute absorption peak positions as functions of Ag-NC size and λ (method detailed in Supporting Information). FIG. 16(I) Contour map of the absorption peak position as a function of λ (x-axis) and size (y-axis) over 0≤λ≤1 and 5-11 nm. The peak position is described by: Peak position (λ, Size) (nm)=435.1−18.6×λ−0.3×Size−1.3×(λ×Size). Experimental data from 25 Ag NCs (solid circles) are overlaid.

FIG. 17 is directed to XRD spectra of spherical and mecon-shaped Ag NCs shown in FIG. 16C-16D. (Top) XRD pattern of spherical Ag NCs. (Bottom) XRD pattern of mecon-shaped Ag NCs. The two patterns exhibit nearly identical diffraction peak positions and peak widths, indicating comparable crystalline domain sizes. Accordingly, the NC sizes estimated from the XRD peak broadening are essentially the same for both morphologies.

FIGS. 18A-18G are Tables of Optical properties of Ag-NCs with various sizes and shapes.

FIGS. 19A-19T are directed to UV-Vis absorption spectra and TEM images of 20 additional Ag-NCs (Rows 1-5, Columns A-D). (Left) UV-Vis absorption spectra and (right) TEM images. The details of the results are listed in FIGS. 18A-18G.

FIG. 20 is directed to absorption peak position dependence on the size and shape of Ag-NCs (presented in FIG. 16I). (Left) Experimental peak-position map as a function of nanocrystal size and sphericity factor (k). (Right) Calculated peak-position contour map generated using the empirical equation: Peak position (λ, Size). nm=435.1−18.6×λ−0.3×Size−1.3×(λ×Size). In both panels, the peak position is represented using the same color scale placed in the right.

FIG. 21 is directed to a correlation plot between calculated and experimental peak positions. This plot compares the peak positions predicted by the empirical model with the experimentally observed peak positions from UV-Vis absorption spectra. The x-axis shows the calculated peak position (nm) obtained from the equation, Peak position (λ, Size). nm=435.1−18.6×−0.3×Size−1.3×(λ×Size). The y-axis shows the experimentally measured peak position (nm). A linear regression between the calculated and experimental values yields: y=x−0.007 with R2 value of 0.85, indicating strong agreement between the model prediction and experimental observations.

FIGS. 22A-22C are directed to a DDA simulation of spherical and mecon-shaped Ag-NCs. FIGS. 22A-22B) UV-Vis absorption spectra simulated by the discrete dipole approximation (DDA) for FIG. 22(A) spherical and FIG. 22(B) mecon-shaped Ag nanocrystals with diameters of 5, 6, 7, 8, 9, and 10 nm. FIG. 22(C) Overlay of the spectra shown in FIG. 22(A) and FIG. 22(B) for direct comparison. The spherical nanocrystals exhibit a clear blue shift as the size increases, whereas the mecon-shaped nanocrystals do not show a similarly monotonic shift. In both geometries, the absorption intensity increases with nanocrystal size.

FIGS. 23A-23G are directed to surface engineering of Ag-NCs and biological application. FIG. 23(A) Schematic illustration of surface engineering of Ag-NCs via ligand exchange. FIG. 23(B) Ligands that successfully replaced the native oleylamine ligands, grouped into two classes: bulky and thiol-based ligands (blue, left) and thiophene-based ligands (green, right). FIG. 23(C) FTIR spectra of Ag NCs before ligand exchange (top) and after ligand exchange with thiol-terminated polystyrene (PS-SH), 2-chloro-5-methylthiophene (2Cl5MeTP), semifluorinated-chain ligands, thiol-terminated polyethylene glycol (PEG-SH), methylene blue (MB), 11-mercaptoundecanoic acid (11-MUA), and PEDOT:PSS (from second top to bottom). FIG. 23(D) Ag NC dispersions after ligand exchange: PEG (MW 20k) in water, biotin-functionalized PEG-SH in water, PEG (MW 20k) in phosphate-buffered saline (PBS), 11-MUA in water, semifluorinated-chain ligands in toluene, PS-SH in toluene, and 2Cl5MeTP in toluene (left to right). FIG. 23(E) TEM image of MB-capped Ag-NCs. FIG. 23(F) UV-Vis absorption spectrum of MB-capped Ag-NCs, exhibiting both peaks originated from MB and Ag-NCs. FIG. 23(G) Representative images of HeLa cells. Live cells were treated with compounds (4 g/mL) for 1 hr at 37 °C, 5% CO2 and then washed 3× with PBS before being suspended in Fluorobrite DMEM and subjected to imaging. Scale bars=20 μm.

FIG. 24 is directed to FTIR-spectra of oleylamine and Ag-NCs. (top) oleylamine and (bottom) Ag-NCs.

FIGS. 25A-25C are Tables providing a list of incoming molecules used in the examples herein and ligand-exchange outcomes.

FIG. 26 is directed to FTIR-spectra of oleylamine and Ag-NCs. (top) oleylamine and (bottom) Ag-NCs.

FIG. 27 is directed to a photograph of PEG (MW=5k) capped Ag-NCs in water with different concentrations.

FIG. 28 is directed to a SAXS spectrum of FCC SLs from Ag-VII. (left) The thick blue line, thin purple line, and purple-red peaks represent the experimentally-obtained SAXS spectrum, fitted spectrum, and constituent peaks used for fitting, respectively. (right) 2D SAXS pattern. The scale bar is 0.5 nm.

FIG. 29 is directed to representative images of HeLa cells. Live cells were treated with compounds (4 g/mL) for 1 hr at 37 °C, 5% CO2 and then washed 3× with PBS before being suspended in Fluorobrite DMEM and subjected to imaging. Scale bars=20 m.

FIGS. 30A-30L are directed to spherical and mecon Ag-NCs and their SLs. FIG. 30A-30C Spherical Ag-NCs, and FIG. 30D-30F mecon Ag-NCs: low-magnification TEM images FIGS. 30A and 30D, HR-TEM images (scale bar, 3 nm) FIGS. 30B and 30E, top, the corresponding FFT patterns FIGS. 30B and 30E, bottom left, simulated FFT patterns FIGS. 30B and 30E, bottom right, and absorption spectra from experiments FIGS. 30C and 30F, solid lines) and simulations FIGS. 30C and 30F, dashed lines). In the panel c, the presented peaks were used for fitting the experimental absorption spectra. FIG. 30G-30J Atomic models of an individual spherical Ag-NC FIG. 30(G), an FCC SL unit cell from spherical Ag-NCs FIG. 30(H), an individual mecon Ag-NC FIG. 30(I), and a BCC SL unit cell from mecon Ag-NCs FIG. 30(J). FIGS. 30K and 30L 1D SAXS spectra of an FCC SL from spherical Ag-NCs. FIG. 30(K), and a BCC SL from mecon Ag-NCs FIG. 30(L). Open circles, solid lines, dashed lines, peaks, and bars in the panels represent integrated data points from the 2D SAXS patterns, 1D SAXS spectra, fitted SAXS spectra, constituent peaks for the fitting, and standard peak positions of the assigned structures, respectively. Insets: 2D SAXS patterns (scale bar, 0.5 nm⁻¹) (left), TEM images of the SLs (scale bar, 30 nm) (middle), and selected-area WAED patterns (scale bar, 3 nm⁻¹) (right). In the right inset panel of FIG. 30K, the indices from top to bottom are assigned to the patterns corresponding to from inner to outer positions, respectively.

FIGS. 31A-31F are directed to characterizations and phase diagram of N-W phase-intermediate SLs. FIG. 31(A) SAXS spectrum for a N-W phase-intermediate SL with τ of 33.8% from Ag-NCs with X of 0.62. Open circles, solid line, dashed line, and peaks represent integrated data points of 2D SAXS pattern, fitted SAXS spectrum, and constituent peaks for the fitting, respectively. Insets: N-W phase-intermediate unit cell and the lattice constants for the N-W phase-intermediate SLs with τ of 33.8% (left), and 2D SAXS pattern (right, scale bar, 0.5 nm⁻¹). FIG. 31(B) Schematics of the shared plane through the N-W (middle) pathway between the reference FCC (left) and BCC (right) structures. The difference in the opacity of the spheres represents that they are located in different layers along the viewing directions. FIG. 31(C) Diagram of SAXS-peak evolution from an FCC (bottom) to a BCC (top) through the N-W pathway (middle). The numbers at the intersections along the line positioned at τ of 33.8% (blue dots) correspond to the peak numbers assigned in the SAXS peaks shown in FIG. 31(A). FIG. 31(D) Rotational TEM study for the N-W phase-intermediate SL with τ of 33.8%. Leftmost column (i, vi, xi, xvi): TEM images showing SL fringes (scale bars, 40 nm). The SL fringes labeled as p 1-4 correspond to SAXS peaks 1-4 in FIG. 31A, respectively. Middle left column (ii, vii, xii, xvii): the corresponding SAED patterns (scale bar, 0.2 nm⁻¹). Middle column (iii, viii, xiii, xviii): computer models of the N-W SLs. Middle right column (iv, ix, xiv, xix): computer models of the individual NCs in the SLs. Rightmost column (v, x, xv, xx): the corresponding WAED patterns (scale bar, 3 nm⁻¹). FIG. 31(E) Phase diagram, X vs. particle size, plotted from 16 Ag-NC samples forming FCC, BCC, and N-W phase-intermediate SLs with different T values. FIG. 31(F) Phase diagram, τ vs. λ, plotted from 16 Ag-NC samples with different particle volumes and shapes (ranging between a sphere and a mecon).

FIGS. 32A-32L are directed to simulations of phase-intermediate SL formation from NCs with varying sphericity parameters. FIG. 32(A) Pair potential curves between NCs used in simulations. Potential curves for the stiff interaction model, the soft interaction model, and the total potential model (stiff and soft interactions combined) are presented with purple dashed, green dashed, and black solid lines, respectively. FIG. 32(B) Phase diagram, λ vs. τ, plotted from HPMC simulations using the stiff interaction model (left) and HPMD simulations using the total potential model (right). Red spheres on the right panel represent experimentally obtained data from Ag-NCs with the same particle volume (c.a. 520 nm³) and varying sphericity (X: 0.17-0.95). FIGS. 32C-32F Structural analysis for simulated SLs from Ag-NCs with X of 0.0 FIG. 32(C), 0.4 FIG. 32(D), 0.8 FIG. 32(E), and 1.0 FIG. 32(F): snapshots of the simulated SLs (top), FOODs for (111)_{Ag-FCC} facets (bottom left), BOODs for eight nearest neighbors (bottom middle), and overlaid presentations of (111)_{Ag-FCC} FOODs and eight nearest neighbor BOODs (bottom right). FIGS. 32G-32K WAED patterns for the experimentally-obtained SLs formed by the Ag-NCs (c.a. 520 nm³) with λ of 0.17 FIG. 32(G), 0.39 FIG. 32(H), 0.56 FIG. 32(I), 0.83 FIG. 32 (J), and 0.95 FIG. 32(K): WAED patterns (scale bars, 3 nm⁻¹) (top) and magnified signals with lines showing the L (longitudinal) and R (radial) directions (insets); the ratios of full-width half maximum between peaks integrated along the L and R directions for SAED (green bars) and WAED (purple bars) patterns (bottom). The corresponding SAED patterns used in this analysis are provided in FIG. S29.

FIG. 32(L) Computer models of neighboring NCs in the SLs with FCC (top), phase-intermediate (middle top, middle bottom), and BCC (bottom) structures, highlighting the evolution of orientational order of the constituent NCs and soft-ligand-induced facet-to-facet interactions.

FIGS. 33A-33I are directed to plasmonic properties of Ag-NC SLs. FIG. 33(A) Reflection optical image of BCC SLs from mecon Ag-NCs (scale bar, 40 m). FIG. 33(B) TEM image of BCC SLs from mecon Ag-NC with varying numbers of stacked layers (scale bar, 300 nm). FIG. 33(C) Schematic representation of transmission and reflection spectroscopy utilized in this study, along with the light-matter couplings emerging at the surface of (e.g., surface polariton) and within Ag-NC SLs (e.g., plasmon-polaritons standing waves). FIG. 33(D) Schematic illustration of the optical path applied in the measurements. FIGS. 33E-33G Experimental transmission (dashed lines) and reflection (solid lines) spectra of 1-6 layers FIG. 33(E) FCC SLs containing 1-6 SL layers from spherical Ag-NCs, FIG. 33(F) N-W phase-intermediate (P-I) SLs from Ag-NCs with λ of 0.56, and FIG. 33(G) BCC SLs from mecon Ag-NCs. FIG. 33(H) Simulated reflection (solid lines) and transmission (dashed lines) spectra of a BCC SL from mecon Ag-NCs (top), a N-W P-I SL from Ag-NCs with λ of 0.56 (middle), and an FCC SL from spherical Ag-NCs (bottom) with 24 SL layers (1.3 nm gap distance). The color-shaded areas indicate the polaritonic band gaps that develop for ultrastrong and deep-strong light-matter coupling. The dips in reflectivity within the gap are due to absorption by higher-order plasmonic modes. FIG. 33(I) Dispersion of the lower plasmon-polaritons for BCC SLs from mecon Ag-NCs (square), N-W P-I SLs from Ag-NCs with λ of 0.56 (hexagon), FCC SLs from spherical Ag-NCs (sphere), and tight BCC SLs from mecon Ag-NCs with a reduced interparticle gap distance (0.5 nm gap distance, triangles). Light-colored symbols are extracted from the simulations, and the dark-colored symbols (square, hexagon, and sphere) are the data points obtained from experimental measurements (BCC SL from spherical Ag-NCs, N-W P-I SL from Ag-NCs with λ of 0.56, and FCC SLs from mecon Ag-NCs, respectively). The solid lines, dashed lines, and dotted grey lines are the fitting lines with a Hopfield Hamiltonian, fitted transverse collective plasmon frequency, ωₜ, and free photon dispersion, respectively.

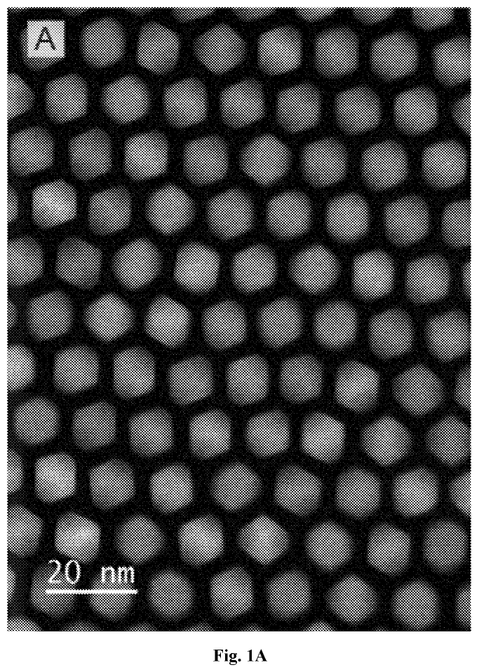

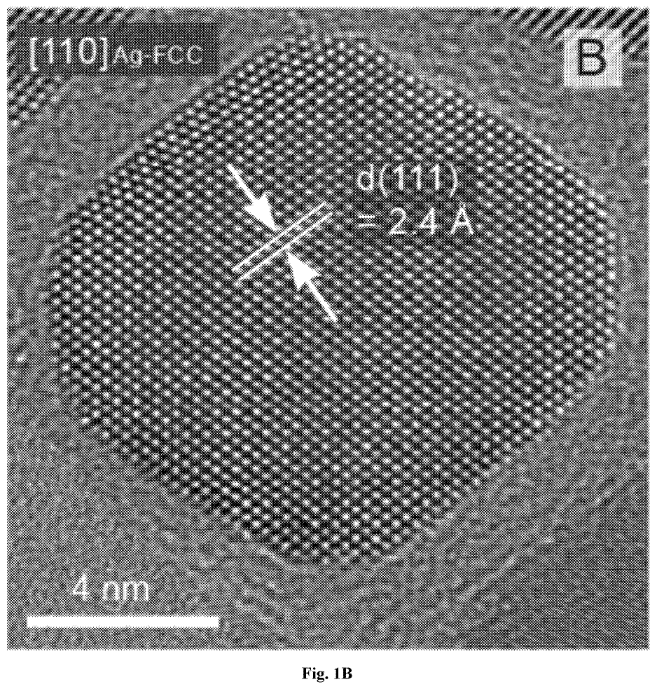

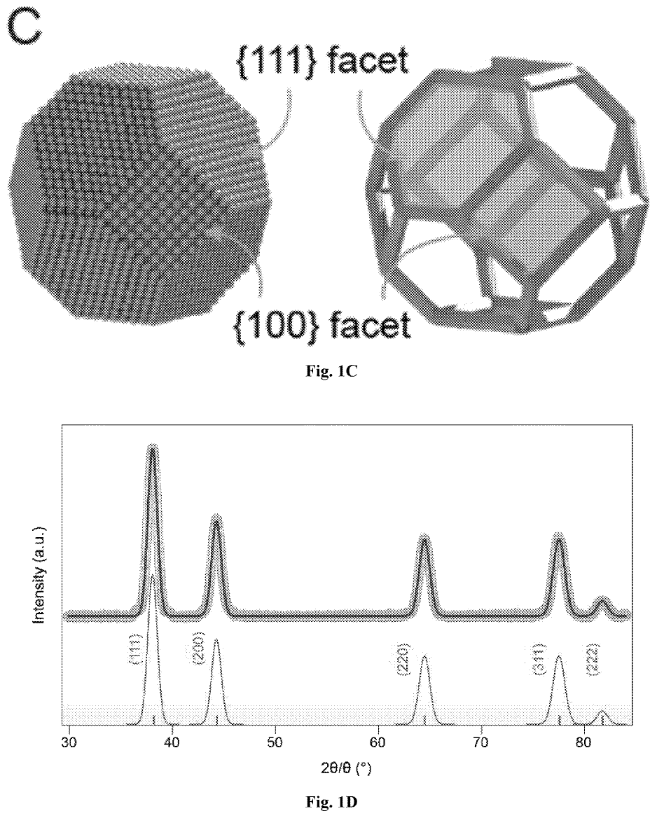

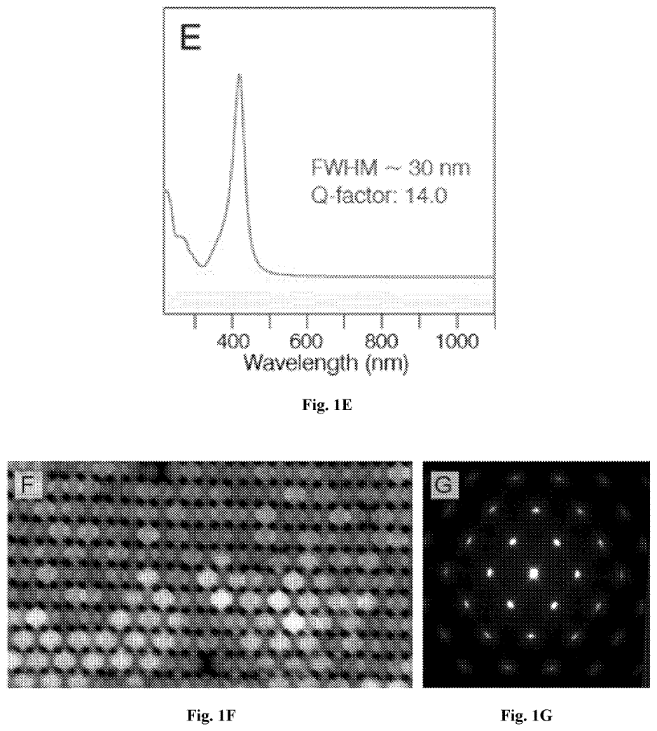

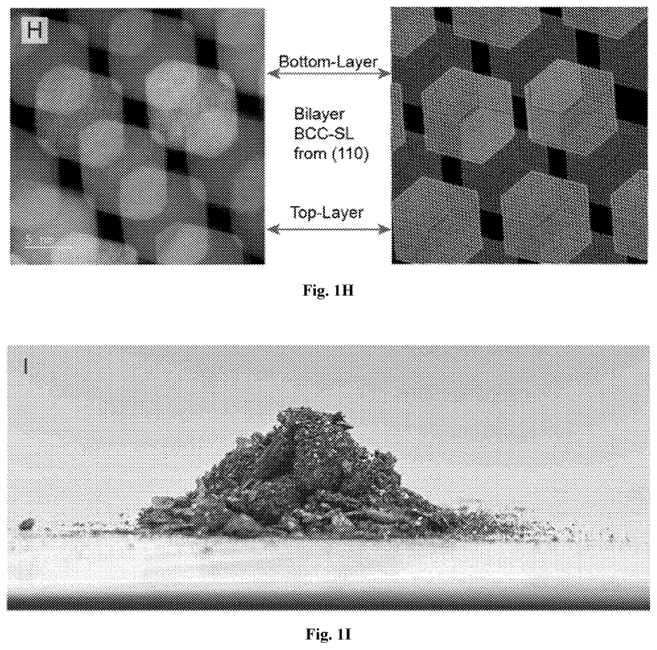

FIGS. 34A-34E are directed to TEM analysis of BCC SLs containing various layers presented in FIG. 33B. FIG. 34(A) A large TEM image presented in FIG. 33B. FIG. 34D-34D Magnified TEM images of 1-layer SLs FIG. 34(B), 2-layers SLs FIG. 34(C), and 3-layers SLs FIG. 34(D). FIG. 34(E) WAED pattern from the 3 layers SLs. It is noted that the SLs thicker than 1-layer SLs consistently show similar type of WAED patterns. The assigned structure is consistent with the structural model presented in FIG. 1L.

FIGS. 35A-35D are directed to images of Ag-NC SLs under optical microscopes. FIG. 35A-35B Images in reflection mode, FIG. 35(C) dark field mode, and FIG. 35(D) transmission mode.

FIG. 36 is directed to simulated optical properties of Ag-NC SLs consisting of 1-6 layers. (left) FCC SLs from spherical Ag-NCs, (center) N-W phase-intermediate SLs from Ag-NCs with λ of 0.56, and (right) BCC SLs from mecon Ag-NCs. Dashed and solid lines are transmission and reflection spectra, respectively. Note that the N-W phase-intermediate SL model employed in the electromagnetic simulations is a simplified model.

FIG. 37 is directed to FDTD simulated optical properties of FCC and BCC Ag-NC SLs. Simulated optical properties (transmission, reflection, and absorption) of FCC SLs from spherical Ag-NCs (left, purple lines) and BCC SLs from mecon Ag-NCs (right, blue lines) consisting of 12 layers (top), 24 layers (middle), and 48 layers (bottom).

FIG. 38 is directed to FDTD simulated optical properties of tight BCC SLs from mecon Ag-NCs with various layer numbers. Calculated transmission (left), reflection (center), and absorption (right) spectra of BCC SLs from mecon Ag-NCs with a smaller gap distance (i.e., 0.5 nm) consisting of 12 layers (top), 24 layers (middle), and 48 layers (bottom).

FIGS. 39A-39D are directed to plasmonic properties simulation for BCC SLs from different size Ag-NCs. Simulated optical properties (transmission for dashed line and reflection for solid lines) of 48-layers BCC SLs from 5 nm mecon Ag-NCs FIG. 39(A), 24-layers BCC SLs from 11.25 nm mecon Ag-NCs FIG. 39(B), and 6-layers BCC SLs from 59 nm mecon Ag-NCs FIG. 39(C). FIG. 39(D) Dispersion of the lower plasmon-polaritons for BCC SLs. 5 nm mecon Ag-NCs (purple circle marks), 11.25 nm mecon Ag-NCs (blue square marks), and 59 nm mecon Ag-NCs (pink circle marks). The solid lines, dotted lines, and dash lines are the fitting lines with a Hopfield Hamiltonian, fitted transverse collective plasmon frequency, ωₜ, and free photon dispersion, respectively.

FIG. 40 is directed to a Table providing results of electromagnetic simulation for light-matter coupling in various SLs.

### DETAILED DESCRIPTION

Aspects of the present disclosure are directed to a method of making precious metal nanocrystals. Such precious metal nanocrystals exhibit advantageous properties, such as plasmonic properties, for use in photonic applications (such as quantum photonic applications), light computing applications, sensing applications (such as ultrasensitive sensing), plasmon-assisted catalysis, and as therapeutic agents and other applications in biotechnology. Precious metal nanocrystals produced by the methods described herein exhibit high free-electron density, favorable electronic band structure, and strong light-matter interactions, high optical quality (Q) factors, large absorption cross sections associated with localized surface plasmon resonances (LSPRs), the capacity to support exceptionally strong near-field enhancements, and plasmon light-matter coupling in the deep-strong region. According to one aspect, precious metal nanocrystals produced by the methods described herein display pronounced size-, shape-, and facet-dependent properties, enabling continuous tuning of their optical response through structural design. According to one aspect, methods are contemplated to configure or engineer the precious metal nanocrystals by altering reactants as described herein, solvents as described herein and/or heating conditions as described herein, to provide desirable properties for diverse applications as described herein. According to one aspect, the precious metal nanocrystals can be functionalized using methods described herein to include surface-bound ligands to provide advantageous properties, such as post-synthetic functionalization with a wide variety of ligands, including thiol-terminated polyethylene glycol (PEG), biotinylated PEG, polystyrene (PS), and liquid-crystal-based molecules. According to one aspect, the methods described herein can be altered to produce different diameters of precious metal nanocrystals within the range of about 3 nm to about 15 nm. Additional ranges include about 4 nm to about 14 nm, about 4 nm to about 13 nm, about 4 nm to about 12 nm, about 4 nm to about 11 nm. It is to be understood that the disclosed ranges are not intending to be limiting or that the one pot method necessarily produces precious metal nanocrystals across the full range. Instead, the one pot method disclosed herein produces a narrow size or diameter distribution, tunable by altering reactants, solvents, and/or heating conditions as described herein, e.g., about less than 7% above and below the target size or diameter. According to one aspect, the methods described herein can be altered to tunably produce different structures and sizes of precious metal nanocrystals.

According to one aspect, the methods described herein produce structurally uniform precious metal nanocrystals. The one pot method disclosed herein produces a narrow shape distribution, tunable by altering reactants, solvents, and/or heating conditions as described herein, e.g., about less than 7% above and below the target shape. For example, the methods described herein produce precious metal nanocrystals of particular shape, such as a shape distribution being less than about 7%, where at least about 95% of the precious metal nanocrystals are withing about ±15% range of the intended shape. Depending on growth conditions, the precious metal nanocrystals may adopt a shape of either truncated octahedra (hereafter referred to as “mecons” for simplicity), spheres, and the in-between morphologies. As used herein, “mecon” refers to a truncated-octahedral morphology (or a morphology substantially similar thereto), optionally characterized by eight {111} facets and six {100} facets. In some embodiments, morphology is quantified using a sphericity parameter λ, where λ=0 corresponds to an ideal mecon and λ=1 corresponds to an ideal sphere, with 0≤λ≤1 representing intermediate morphologies. The simplicity of the protocol as described herein using different heating steps enables gram-scale synthesis without compromising size or shape uniformity. One advantage of the one pot synthesis method described herein is that the resulting precious metal nanocrystals are characterized by a narrow size distribution and a narrow shape distribution achieving a purity of less than about 7% distribution in size or diameter and shape of the intended or target size or diameter and intended or target shape.

According to one aspect, a method of making a precious metal nanocrystal is provided that includes creating a combination including a precious metal salt, a reducing agent, a stabilizing agent, a solvent, and a catalyst, optionally under an inert atmosphere, wherein precious metal cations are reduced to precious metal atoms. According to one aspect, the precious metal nanocrystals are produced in an oil phase. The combination is heated to a first temperature and for a first time period at which the precious metal atoms in the combination produce precious metal clusters. The combination is further heated to a second temperature and for a second time period at which the precious metal clusters form precious metal nanocrystals.

In certain embodiments, the reaction is conducted according to a heating profile comprising one or more thermal stages. Each thermal stage may be characterized by a target temperature, a hold time, and a heating and/or cooling ramp rate. The heating profile may further specify agitation, pressure, and atmosphere. One or more stages may be omitted, combined, repeated, or performed in a different order, without departing from the scope of the invention. In other embodiments, the heating profile comprises one or more heating stages or a plurality of heating stages, such as two, three, four, five, or more stages, which may be selected to improve batch-to-batch reproducibility, nanocrystal uniformity, crystallinity, and/or impurity removal.

### I. Exemplary Precious Metal Reactants

According to one aspect, an exemplary precious metal reactant may include one or more or a plurality of silver, gold, platinum, palladium, rhodium, ruthenium, iridium, osmium, or titanium and the like. According to one aspect, one or more or a plurality or combination of precious metal reactants may be used in the methods described herein the produce precious metal nanocrystals with one or more or a plurality of precious metals.

Exemplary precious metal reactants including silver include silver(II) acetate; silver(I) acetate; silver nitrate; silver sulfate; silver triflate; silver tetrafluoroborate; silver hexafluorophosphate; silver oxide; silver carbonate; silver halides (AgCl, AgBr, AgI); silver carboxylates (e.g., silver oleate, silver stearate, silver 2-ethylhexanoate); silver acetylacetonate; and mixtures or combinations thereof, and the like.

Exemplary precious metal reactants including gold include chloroauric acid (HAuCl₄) and salts/hydrates thereof; gold(III) chloride; gold(III) bromide; gold(I) halides; gold(III) acetate; gold acetylacetonate; gold thiolate complexes; gold phosphine complexes (e.g., triphenylphosphine gold chloride); and mixtures or combinations thereof, and the like.

Exemplary precious metal reactants including platinum include hexachloroplatinic acid (H₂PtC₁₆) and salts or hydrates thereof, platinum(II) chloride; platinum(IV) chloride; platinum acetylacetonate; platinum oxides; and mixtures or combinations thereof, and the like.

Exemplary precious metal reactants including palladium include palladium(II) acetate; palladium(II) chloride; palladium nitrate; palladium acetylacetonate; palladium oxides; and mixtures or combinations thereof, and the like.

Exemplary precious metal reactants including rhodium include rhodium(III) chloride (including hydrates); rhodium acetylacetonate; rhodium carboxylates; and mixtures or combinations thereof, and the like.

Exemplary precious metal reactants including ruthenium include ruthenium(III) chloride and hydrates thereof (including hydrates); ruthenium acetylacetonate; ruthenium carboxylates; and mixtures or combinations thereof and the like.

Exemplary precious metal reactants including iridium include iridium(III) chloride; iridium(IV) chloride; iridium acetylacetonate; iridium carboxylates; and mixtures or combinations thereof, and the like.

Exemplary precious metal reactants including osmium include osmium chlorides; osmium acetylacetonate; osmium oxides/oxo species; and mixtures or combinations thereof, and the like.

Exemplary precious metal reactants including titanium include titanium alkoxides (e.g., titanium isopropoxide), titanium halides, titanium acetylacetonate, titanium carboxylates, titanium oxides, and mixtures or combinations thereof, and the like.

It is to be understood that methods described herein can include one precious metal reactant in the reaction mixture to produce a precious metal nanocrystal with a single metal. It is to be understood that methods described herein can include two or more or a plurality or combination of precious metal reactants in the reaction mixture to produce alloy nanocrystals, doped nanocrystals or core-shell nanocrystals (e.g., Ag—Au, Pt—Pd, Pt—Ru), and the like.

### II. Exemplary Catalysts

According to one aspect, one or more or a plurality of catalysts may be used in the practice of the present method to catalyze formation of precious metal nanocrystals. A suitable catalyst may be a metal salt catalyst. An exemplary metal salt catalyst includes a copper (II) salt. Exemplary copper (II) salts include Copper(II) sulfate (CuSO₄), Copper(II) chloride (CuCl₂), Copper(II) hydroxide (Cu(OH)₂), Copper(II) nitrate (Cu(NO₃)₂), Copper(II) oxide (CuO), Copper(II) acetate (Cu(OAc)₂), Copper(II) fluoride (CuF₂), Copper(II) bromide (CuBr₂), Copper(II) carbonate (CuCO₃), Copper(II) carbonate hydroxide (Cu₂CO₃(OH)₂), Copper(II) chlorate (Cu(ClO₃)₂), Copper(II) arsenate (Cu₃(AsO₄)₂), Copper(II) azide (Cu(N₃)₂), Copper(II) acetylacetonate (Cu(O₂C₅H₇)₂), Copper(II) aspirinate (C₃₆H₂₈Cu₂O₁₆), Copper(II) cyanurate (CuC₃HN₃O₃), Copper(II) glycinate (Cu(H₂NCH₂CO₂)₂), Copper(II) phosphate (Cu₃(PO₄)₂), Copper(II) perchlorate (Cu(ClO₄)₂), Copper(II) selenite (CuSeO₃), Copper(II) sulfide (CuS), Copper(II) thiocyanate (Cu(SCN)₂), Copper(II) triflate (Cu(OSO₂CF₃)₂), Copper(II) tetrafluoroborate (Cu(BF₄)₂), Copper(II) acetate triarsenite (Cu(C₂H₃O₂)₂·3Cu(AsO₂)₂), Copper(II) benzoate (Cu(C₆H₅CO₂)₂), Copper(II) arsenite (CuHAsO₃), Copper(II) chromite (Cu₂Cr₂O₅), Copper(II) gluconate (C₁₂H₂₂CuO₁₄), Copper(II) peroxide (CuO₂), Copper(II) usnate (C₁₈H₁₄CuO₇), Copper(II) oxychloride (Cu₂(OH)₃Cl), Copper(II) naproxen (C₂₈H₂₆CuO₆), Copper(II) ibuprofenate (C₅₂H₆₈Cu₂O₈) and the like and mixtures or combinations thereof.

In some embodiments, the catalyst (e.g., a copper salt) or combination or mixture of catalysts is present in an amount of about 0.001 mol % to about 20 mol % relative to the precious metal precursor (for example, about 0.01 mol % to about 10 mol %, or about 0.1 mol % to about 5 mol %). In some embodiments, comparable nanocrystal size and shape uniformity may be achieved across a range of catalyst loadings, thereby improving robustness and scalability.

### III. Exemplary Reducing Agents

According to one aspect, one or more or a plurality or combination of reducing agents may be used in the practice of the present method to reduce the precious metal ion to its precious metal. Exemplary reducing agents include fatty amines. An exemplary fatty amine includes a C10 to C30 carbon chain saturated or unsaturated, straight chain or branched chain. Exemplary fatty amine reducing agents include oleylamine, octylamine, nonylamine, decylamine, dodecylamine, laurylamine, myristylamine, palmitylamine, stearylamine, dioctylamine, didodecylamine, trioctylamine, coco amine, tallow amine, soya amine and the like, and mixture or combinations thereof.

### IV. Exemplary Nanocrystal Growth Promoter Agents

According to one aspect, a nanocrystal growth promoter agent. In certain embodiments, a nanocrystal growth promoter agent is included to promote formation and/or growth of precious metal nanocrystals. Without wishing to be bound by theory, the growth promoter agent may perform one or more functions, including: (i) converting the precious metal reactant into an oil-soluble metal-ligand species (e.g., via ligand exchange to form a metal carboxylate) to improve homogeneity and control monomer availability; (ii) moderating reduction and nucleation kinetics (e.g., through acid-base interactions with an amine reducing agent and/or by modifying precursor speciation); (iii) coordinating to the nanocrystal surface to provide passivation, suppress aggregation, and/or influence facet-selective growth; and/or (iv) improving batch-to-batch reproducibility by facilitating removal or tolerance of trace volatiles and impurities. In some embodiments, the nanocrystal growth promoter agent comprises a fatty acid. The nanocrystal growth promoter may be used in the practice of the present method to promote nanocrystal growth. Exemplary nanocrystal growth promoter agents include one or more or a plurality or combination of fatty acids. An exemplary fatty acid includes a C10 to C30 carbon chain saturated or unsaturated, straight chain or branched chain. Exemplary fatty acid nanocrystal growth promoter agents include palmitoleic acid, oleic acid, elaidic acid, linoleic acid, a-linolenic acid, arachidonic acid, eicosapentaenoic acid, docosahexaenoic acid, erucic acid, stearidonic acid, y-linolenic acid, lauric acid, myristic acid, palmitic acid, stearic acid, arachidic acid, behenic acid, lignoceric acid and the like and mixture or combinations thereof.

Examples of saturated fatty acids include caprylic acid (C8), capric acid (C10), lauric acid (C12), tridecanoic acid (C13), myristic acid (C14), pentadecanoic acid (C15), palmitic acid (C16), margaric acid (C17), stearic acid (C18), nonadecanoic acid (C19), arachidic acid (C20), behenic acid (C22), lignoceric acid (C24), cerotic acid (C26), montanic acid (C28), melissic acid (C30), and the like, and mixtures or combinations thereof.

Examples of unsaturated fatty acids include myristoleic acid (C14:1), palmitoleic acid (C16:1), oleic acid (C18:1), elaidic acid (C18:1 trans), vaccenic acid (C18:1), linoleic acid (C18:2), a-linolenic acid (C18:3), y-linolenic acid (C18:3), stearidonic acid (C18:4), arachidonic acid (C20:4), eicosapentaenoic acid (EPA, C20:5), docosahexaenoic acid (DHA, C22:6), erucic acid (C22:1), nervonic acid (C24:1), and the like, and mixtures or combinations thereof.

Examples of branched fatty acids include isostearic acid; 2-ethylhexanoic acid; neodecanoic/versatic-type acids; tall oil fatty acids; and mixed fatty acid feeds, and the like, and mixtures or combinations thereof. Mixtures of fatty acids are commercially available.

Examples of fatty acid derivatives include fatty acid metal carboxylates, fatty acid ammonium carboxylates, fatty acid carboxylic anhydrides, fatty acid esters and fatty acid carboxylate salts (e.g., sodium/alkylammonium oleate), and the like, and mixtures or combinations thereof.

### V. Exemplary Nonpolar and Less Polar Solvents

According to one aspect, one or more or a plurality or combination of nonpolar or less polar solvents may be used in the practice of the present method insofar as the reaction may be referred to as “oil-based” or “oil-phased.” The nonpolar or less polar solvent should be sufficiently nonpolar so as to form a reaction medium with the precious metal salt, the reducing agent and the nanocrystal growth promoter agent insofar as the reducing agent and the nanocrystal growth promoter agent include nonpolar carbon chains as described herein. Exemplary nonpolar or less polar solvents include hydrocarbon-based solvents as are known in the art. Exemplary nonpolar or less polar solvents include diphenyl ether, 1-octadecene, hexane, heptane, octane, benzene, toluene, chloroform, carbon tetrachloride, diethyl ether, pentane, cyclohexane, methylcyclohexane, decalin, benzyl ether, squalane, squalene and the like, and mixtures or combinations thereof.

Exemplary linear or branched aliphatic hydrocarbons include pentane, hexane, heptane, octane, nonane, decane, dodecane, tetradecane, hexadecane, mineral spirits, isoparaffins, and mixtures thereof.

Exemplary cycloaliphatic hydrocarbons include cyclohexane, methylcyclohexane, ethylcyclohexane, decalin (cis/trans), and mixtures thereof.

Exemplary aromatic hydrocarbons include benzene, toluene, ethylbenzene, xylenes, mesitylene, and mixtures thereof.

Exemplary high-boiling nonpolar solvents include 1-octadecene, 1-eicosene, squalane, squalene, long-chain (C 10-C30) alkanes, and mixtures thereof.

Exemplary ethers include diethyl ether, diisopropyl ether, dibutyl ether, dioctyl ether, diphenyl ether, benzyl ether, dibenzyl ether, and mixtures thereof.

Exemplary halogenated solvents (which may be referred to as less polar solvents) include chloroform, dichloromethane, chlorobenzene, dichlorobenzenes, carbon tetrachloride, and mixtures thereof.

### VI. Exemplary Heating Regimens

According to one aspect, the reactants are heated in a step-wise fashion. According to one aspect, the reactants are heated to at least a first temperature from 0 °C to 100 °C and maintained at a time period from about 30 seconds to about 6 hours. The reaction temperature is then increased to at least a second temperature from 110 °C to 400 °C and maintained at a time period from about one second to about 24 hours. Additional stepwise temperature stages and time periods are contemplated. More generally, the reactants may be heated according to a thermal/heating profile comprising one or more stages, each defined by a target temperature, hold time, and heating/cooling ramp rate. One or more stages may be omitted, combined, repeated, or re-ordered. In some embodiments, a post-growth anneal/ripening stage and/or a quench or controlled cooling stage is used to improve uniformity, crystallinity, and reproducibility.

In certain embodiments, the heating regimen comprises a thermal profile including one or more preheating/conditioning stages (e.g., about 0-150 °C), one or more nucleation and/or growth stages (e.g., about 80-400 °C), and optionally one or more post-growth annealing/ripening stages. Each stage may be characterized by a target temperature, a hold time, and a heating and/or cooling ramp rate (e.g., about 0.1-50 °C/min). In some embodiments, the thermal profile further includes a quench or controlled cooling step to arrest growth.

### VII. Exemplary Ligands to Functionalize Precious Metal Nanocrystals

According to one aspect, the precious metal nanocrystals may include surface bound reducing agent. According to one aspect, the surface bound reducing agent may be exchanged with one or more or a plurality or combination of ligands under suitable exchange conditions. The ligand may provide an advantageous property. According to one aspect, the ligand may be a sulfur functionality for binding to the precious metal nanocrystal. Exemplary ligands include one or more or a plurality or combination of a therapeutic agent, a diagnostic agent, an imaging agent, a dispersing agent, an electronic agent, a liquid molecule, a sensor agent, a catalytic agent and the like, and mixtures or combinations thereof.

Exemplary ligands may comprise a therapeutic agent, optionally bearing a sulfur-containing anchoring group (e.g., thiol-terminated linker) or coupled via a bifunctional linker. Exemplary anti-cancer agents include doxorubicin, paclitaxel, cisplatin/carboplatin analog conjugates, camptothecin derivatives (e.g., SN-38 linkable forms), methotrexate or derivatives, salts or prodrugs thereof. Exemplary anti-inflammatory/analgesic agents include ibuprofen, naproxen, diclofenac (including conjugatable derivatives) or derivatives, salts or prodrugs thereof. Exemplary anti-microbial agents include vancomycin (derivatives), gentamicin (derivatives), rifampicin (derivatives), antimicrobial peptides (e.g., LL-37 fragments), or derivatives, salts or prodrugs thereof. Exemplary nucleic acid therapeutics include siRNA, antisense oligonucleotides, aptamers (typically via thiol/amine modifications) or derivatives, salts or prodrugs thereof. Exemplary steroids/hormones include dexamethasone (derivatives), prednisone (derivatives) or derivatives, salts or prodrugs thereof.

Exemplary ligands may comprise diagnostic agents that bind biomarkers, capture analytes, or enable assay readouts. Exemplary affinity ligands include antibodies, antibody fragments (Fab, scFv), nanobodies; protein A/G; streptavidin/avidin; biotin (as a ligand or handle). Exemplary nucleic acid probes include thiolated DNA/RNA oligos; molecular beacons; aptamers (e.g., thrombin-binding aptamer). Exemplary small-molecule recognition ligands include boronic acids (for diols/sugars), nitrilotriacetic acid (NTA) for His-tag capture (often via thiol linker), lectins, peptide binders. Exemplary enzyme substrates/inhibitors (assayable) include p-nitrophenyl derivatives, fluorogenic enzyme substrates (where compatible).

Exemplary ligands may comprise diagnostic agents that provide contrast for optical, fluorescent, MR, CT, PET/SPECT, or photoacoustic imaging. Exemplary fluorophores/dyes include fluorescein (FITC derivatives), rhodamine derivatives, cyanine dyes (Cy3, Cy5, Cy7), Alexa Fluor derivatives, BODIPY dyes, coumarins. Exemplary raman reporters (SERS tags) include 4-mercaptobenzoic acid (4-MBA), 4-aminothiophenol (4-ATP), 4-mercaptopyridine, 1,4-benzenedithiol, thiophenol derivatives, thiolated aromatic nitriles (as vibrational tags). Exemplary MRI chelates include Gd-DOTA, Gd-DTPA (and derivatives with conjugation handles); Mn-chelates. Exemplary radionuclide chelators include DOTA, NOTA, DTPA, deferoxamine (DFO) for radiometals (with thiol/amine linkers). Exemplary CT contrast motifs (optional) include iodinated aromatic ligands (as conjugates/handles).

Exemplary ligands may comprise dispersing agents to tune solubility in nonpolar, polar, aqueous, or biological media, including antifouling ligands. Exemplary PEG based dispersing agents include PEG and derivatives including HS-PEG-OH, HS-PEG-COOH, HS-PEG-NH2, HS-PEG-OCH3; PEG-phosphates/phosphonates. Exemplary zwitterionic ligands include sulfobetaines, carboxybetaines, phosphorylcholines (often with thiol anchors). Exemplary polymers include poly(vinylpyrrolidone) (PVP), poly(acrylic acid) (PAA), poly(methacrylic acid), poly(ethyleneimine) (PEI) (often via adsorption or grafting). Exemplary surfactants include citrate, SDS-derived anchors (more typical for aqueous systems), bile salts; (include as optional). Exemplary carboxylates/fatty acids include oleate, stearate (for nonpolar dispersions).

Exemplary ligands may comprise electronic agents (sometimes called “electronic coupling ligands”) that tune conductivity, tunneling barriers, charge injection, or interparticle coupling. Exemplary short dithiols/thiols include ethanedithiol (EDT), propanedithiol, butanedithiol, hexanedithiol; mercaptoethanol; cysteamine. Exemplary aromatic thiols/conjugated linkers include benzenethiol, benzenedithiol, mercaptobenzoic acid, thiophenol derivatives; thiolated oligophenylenes; thiolated thiophenes. Exemplary conductive polymers/dopants (as ligands or coatings) include PEDOT:PSS (as overlayer), polyaniline (derivatives), polythiophenes with anchoring groups. Exemplary halide/pseudohalide ligands (as surface ligands) include chloride, bromide, iodide; thiocyanate (SCN—) (often via exchange chemistry). Exemplary phosphines/phosphine oxides include trioctylphosphine (TOP), trioctylphosphine oxide (TOPO) (typically as coordinating species).

Exemplary ligands may comprise liquid or low-melting molecules (e.g., a molecule that is a liquid at 20-25 °C or has melting point below 25 °C) that impart fluid-like interfaces, reduced glass transition, lubricity, or self-healing behavior. Exemplary ionic liquids (ILs) include imidazolium-based ILs (e.g., EMIM, BMIM) with functional anions; phosphonium ILs; pyrrolidinium ILs (optionally with thiol/phosphonate handles). Exemplary low-melting thiols/thioethers include branched thiols (e.g., tert-alkyl thiols), thioethers with bulky substituents. Exemplary oligomeric fluids include short PEG oils, silicone-containing thiols/silanes (e.g., thiol-terminated PDMS oligomers). Exemplary room-temperature liquid aromatic thiols (as mixtures) include substituted thiophenols/alkylated aromatics (as mixtures).

Exemplary ligands may comprise sensor agents that bind analytes, change optical/electrical response, or act as recognition elements. Exemplary metal-ion chelators include EDTA derivatives; DTPA derivatives; NTA; crown ethers (e.g., 18-crown-6 derivatives); bipyridyl/terpyridyl ligands. Exemplary pH/redox responsive ligands include catechol derivatives; quinone/hydroquinone motifs; ferrocene derivatives (thiolated ferrocene). Exemplary glucose/diol binders include phenylboronic acid derivatives. Exemplary gas/volatile binders include thiourea/urea motifs; amine-rich ligands for CO2; sulfur-containing ligands for Hg2+ binding. Exemplary biorecognition agents include aptamers; peptides; antibody fragments; lectins.

Exemplary ligands may comprise catalytic agents or catalysis-modulating ligands for heterogeneous, electrocatalytic, or photocatalytic use. Exemplary are N-heterocyclic carbenes (NHCs) (often strong binders to metals) and precursors thereof. Exemplary phosphines/phosphites include triphenylphosphine derivatives; water-soluble phosphines (TPPTS derivatives). Exemplary are imidazoles/pyridines/bipyridines for coordination tuning. Exemplary are thiols/dithiols to tune surface sites (including mixed-ligand shells). Exemplary immobilization handles include silanes (e.g., mercaptopropyltrimethoxysilane, MPTS) to anchor films to oxides; catechols (dopamine derivatives) for oxide/metal interfaces.

### VIII. Exemplary Methods Using Two or More Precious Metal Reactants

According to aspects of the present disclosure, methods are contemplated of making nanocrystals from two or more precious metal reactants. Such methods include combining amounts of two or more precious metal reactants within the one pot reaction vessel along with the other reactants described herein. Two or more precious metal reactants may be added at the same time to the one-pot reaction vessel or they may be added at different times. Heating as described herein results in a precious metal nanocrystal including two or more precious metals, such as Ag—Au, Pt-Pd, or Pt—Ru or other combination of two or more precious metals described herein. Such a precious metal nanocrystal may be referred to as a precious metal alloy nanocrystal insofar as the precious metal alloy nanocrystal includes a mixture of two or more precious metal elements. Such a mixture may result when the amounts of each precious metal reactant are similar. Precious metal alloy nanocrystals are advantageous as they may provide desirable plasmonic properties.

Methods described herein of combining amounts of two or more precious metal reactants within the one pot reaction vessel along with the other reactants described herein is useful to produce precious metal doped nanocrystals. Two or more precious metal reactants may be added at the same time to the one-pot reaction vessel or they may be added at different times. Such a precious metal doped nanocrystal may include a precious metal dopant within a precious metal nanocrystal such as Ag—Au, Pt—Pd, or Pt—Ru or other combination of two or more precious metals described herein wherein one or more of the precious metals is the dopant. Such a precious metal dopant may result when the amount of a first precious metal reactant is much greater than the amount of a second precious metal reactant. Precious metal doped nanocrystals are advantageous as they may provide desirable plasmonic properties.

Methods described herein of combining amounts of two or more precious metal reactants within the one pot reaction vessel along with the other reactants described herein is useful to produce precious metal core-shell nanocrystals. Two or more precious metal reactants may be added at the same time to the one-pot reaction vessel or they may be added at different times. According to this aspect, a first precious metal may form a precious metal core and then a second precious metal may form a precious metal layer or shell encapsulating the core. Such a precious metal core-shell nanocrystal may include a first precious metal as the core and a second precious metal as the shell or layer, for example an Ag core with an Au shell, or a Pt core with a Pd shell, or a Pt core with a Ru shell. These combinations are exemplary only. It is to be understood that any combination of core-shell precious metals are contemplated. According to one aspect, several different precious metal reactants may be used to produce several different layers or shells encapsulating a prior layer or shell. It is envisioned that different precious metal reactants may be introduced into the one pot reaction vessel at different times, such that after core formation, each additionally added precious metal reactant forms a layer or shell. Precious metal core-shell nanocrystals are advantageous as they may provide desirable plasmonic properties.

The following examples are set forth as being representative of the present disclosure. These examples are not to be construed as limiting the scope of the present disclosure as these and other equivalent embodiments will be apparent in view of the present disclosure, figures and accompanying claims.

### Example I

### Synthesis of Exemplary Silver Nanocrystals

The following were used in the experimental examples where indicated. Silver acetate (Ag-acetate, 99.99% trace metal basis), diphenyl ether (DPE), copper (II) acetate (Cu(acetate)₂, 97%), oleic acid (OAcid, technical grade 90%), oleylamine (OAm, technical grade 70%), optionally hydrochloride (HCl), 4-tert-Butyltoluene, methylene blue (MB), Polystyrene (PS)-thiol terminated (MW 11k), 11-Mecaptoundecanoic acid (11-MUA), 2-Chloro-5-methylthiophene, 1-dodecanethiol, PEDOT:PSS, phosphite buffer solution (PBS), chloroform, toluene, hexanes, acetone, and were purchased from Aldrich. Methoxy-polyethylene-glycol thiol (PEG-SH, MW=5k, 20k) and biotin-functionalized PEG-thiol terminated, were purchased from Creative PEGWorks. All chemicals were used as purchased.

Aspects of the methods described herein advantageously use a one-pot synthesis method using a heating protocol where the reactants are heated up simultaneously within the one-pot system and synthesis is carried out via a decomposition reaction.

In a typical synthesis, 2 mmol (334 mg) of silver acetate, 0.01 mmol (1.8 mg) of copper (II) acetate, and 1 μL of HCl were combined with 14 mL of a solvent mixture containing oleic acid, oleylamine, and diphenyl ether (DPE) in a 100 mL round-bottom flask. After three cycles of degassing under vacuum at room temperature (RT), the reaction mixture was slowly heated to 70 °C and maintained under vacuum for 10 min. During this preheating stage, the original pale-yellow solution turned black. A nitrogen atmosphere was then introduced, and the flask was rapidly heated to 170 °C. The reaction was held at this temperature until silver nanocrystals (“Ag-NCs”) reached a desired size. Once the targeted size was reached, the mixture was quenched by immersion in an ice bath. Ag-NCs were isolated by purification using hexane (good solvent) and acetone (poor solvent). In some embodiments, the reaction is conducted without an added acid additive and/or without an added halide source, while still producing silver nanocrystals of comparable size and shape uniformity. In other embodiments, an acid additive and/or halide source (e.g., HCl or a metal halide) is included to tune precursor speciation and/or reaction kinetics

According to another heating aspect, after degassing, the solution was heated to 45 °C for 10 minutes, followed by heating to 80 °C for 20 minutes. Under a nitrogen blanket, the solution was further heated to a designated temperature (between 130 °C and 180 °C) and maintained for 5-20 minutes. These preheating processes were used for in situ nanocrystal-precursor formation.

According to one aspect, the reaction is carried out under an inert atmosphere. The inert atmosphere may be static or flowing, and may be established via vacuum/backfill cycles. Suitable inert atmospheres include nitrogen, argon, helium, neon, krypton, xenon and mixtures thereof and the like. Such inert atmospheres may be within a glovebox. According to one aspect, the reaction may be carried out under vacuum or reduced pressure to provide an inert atmosphere. According to one aspect, the reaction need not be maintained under an inert atmosphere. Suitable additional atmospheres include noninert atmospheres such as air and other oxygen containing atmospheres and the like.

### Example II

### Characterization of Silver Nanocrystals

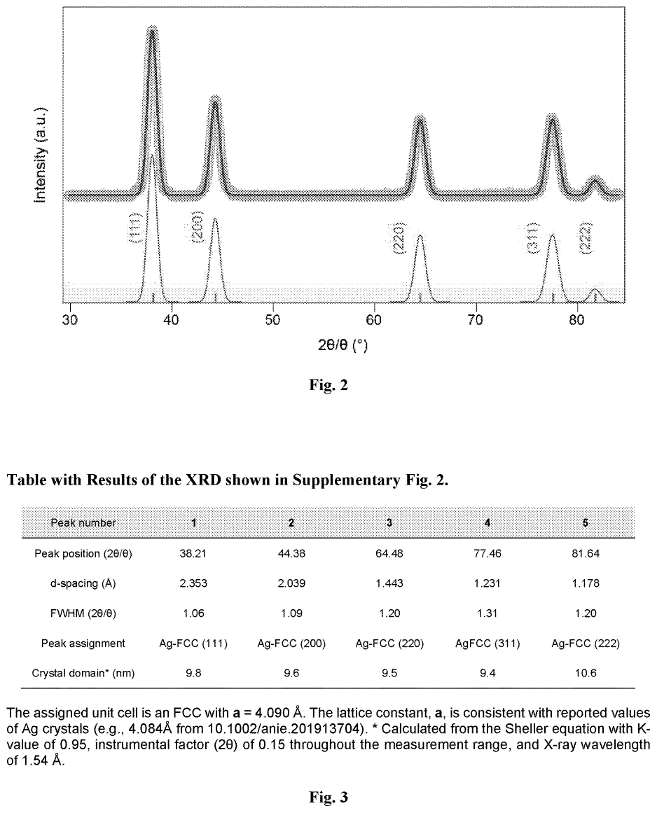

The resulting Ag-NCs exhibit excellent uniformity in both shape and size, with a typical size distribution within ±5% (see FIG. 1A). Exemplary size distributions include between ±1% and ±7% as described herein. The synthesized Ag-NCs possessed high crystallinity within a mecon-shaped crystal having 8 {111} and 6 {100} exposing facets (see FIG. 1B, C). STEM image presented in FIG. 1G showed Ag-NCs possessed a mecon shape with an average edge length of 3.6 nm, equivalent to a spherical-equivalent diameter of approximately 10.0 nm. The high-resolution transmission electron microscopy (HR-TEM) displayed the NCs from the [110]_{Ag-FCC} projection with nearly single-crystal domains (see FIG. 1B). X-ray diffraction (XRD) measurement showed a spectrum consistent with FCC Ag crystal structures (see FIG. 1D) and the estimated crystal domain size from Scherrer equation analysis using the XRD peak width values was 9.8 nm, which is consistent with TEM results and our assignment (see FIG. 2, FIG. 3). The exceptional size and shape uniformity was reflected in the absorption profile as well, where a sharp peak located at 421 nm possessed a full-width half-maximum (FWHM) of c.a. 30 nm and the quality factor (Q-factor) was 14.0 (see FIG. 1E).

Furthermore, spontaneous formation of orientation-regulated NC-superlattices (NC-SL) took place upon evaporation of Ag-NC hexane solution. STEM image in FIG. 1F exhibited a few-monolayer SLs possessing a body-centered cubic (BCC) superstructure along the [110]_{BCC-SL} projection. The selected-area wide-angle electron diffraction pattern presented single-crystal-like spotted pattern, indicating that all the constituent Ag-NCs in the SL were aligned to one specific orientation (see FIG. 1G). Based on these results, we assigned the SL structure to a BCC structure with a lattice constant of 14.1 nm and an orientational order where x-, y-, and z-BCC-SL axes and FCC Ag atomic axes are aligned perfectly (see FIG. 1H). A high magnification STEM image of the SLs strongly agreed with the proposed superstructure regarding the appearing atomic lattice fringe of the Ag-NCs, the projected shape of individual NCs, SL pattern and fringes, validating the assignment (see FIG. 1H). It is noted that silver is generally considered to exhibit a lower tendency to crystallize into single-crystalline atomic orders, and the present disclosure provides Ag-NC synthesis in non-polar solvents producing a high-quality Ag-NCs in a single-pot heating-up method to produce Ag-NCs with excellent size and shape uniformity and high crystallinity.

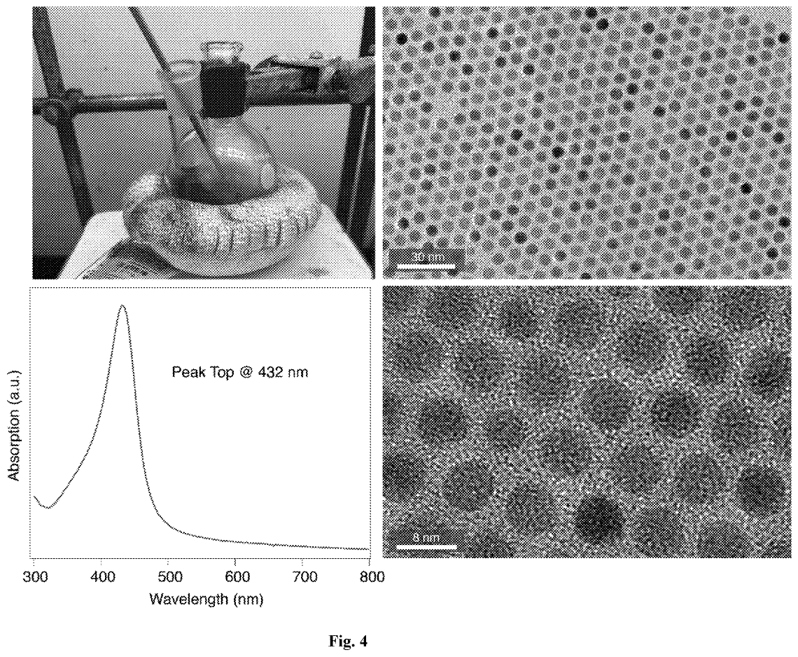

The one-pot heating method described herein is highly robust and readily overcame typical constraints for NC production, i.e., scalability and sensitivity to air. The one pot method described herein is readily scalable to a gram level as shown in the inset of FIG. 1I where 1.3 g of Ag-NCs can be obtained in a single batch. Moreover, while aspects of the method envision conducting the reaction under inert conditions employing a Schlenk line system, further aspects envision carrying out the reaction under air in the reaction flask to produce a comparable quality of Ag-NCs (see FIG. 4). In some embodiments, the synthesis does not require a Schlenk line or glovebox operation and may be performed under ambient laboratory atmosphere without materially degrading nanocrystal quality. These results demonstrated synthetic robustness, which is a key to translating this synthetic protocol in the lab to large scale production of high-quality Ag-NCs with high reproducibility.

### Example III

### Mechanism of Formation of Silver Nanocrystals

According to certain aspects, Ag-NC formation proceeds through a discrete four-step cluster evolution process within the single-pot reaction, catalyzed by copper acetate. Precious metal nanocrystals comprise a plurality of metal atoms ranging from 4 atoms to 150 atoms and more, as desired.

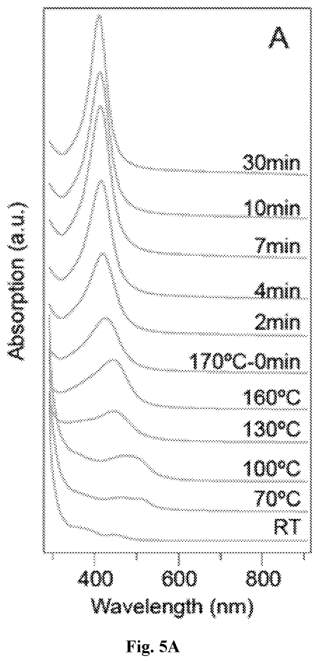

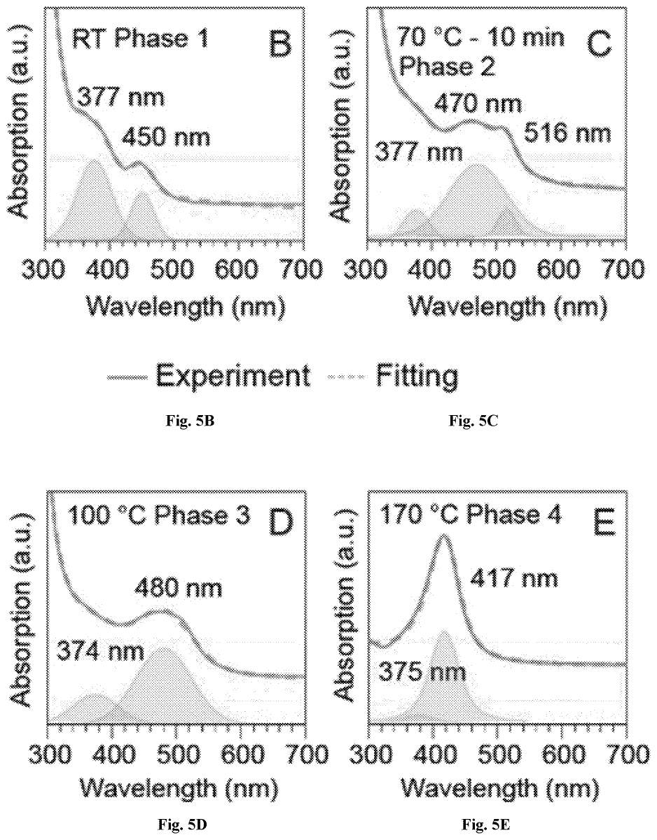

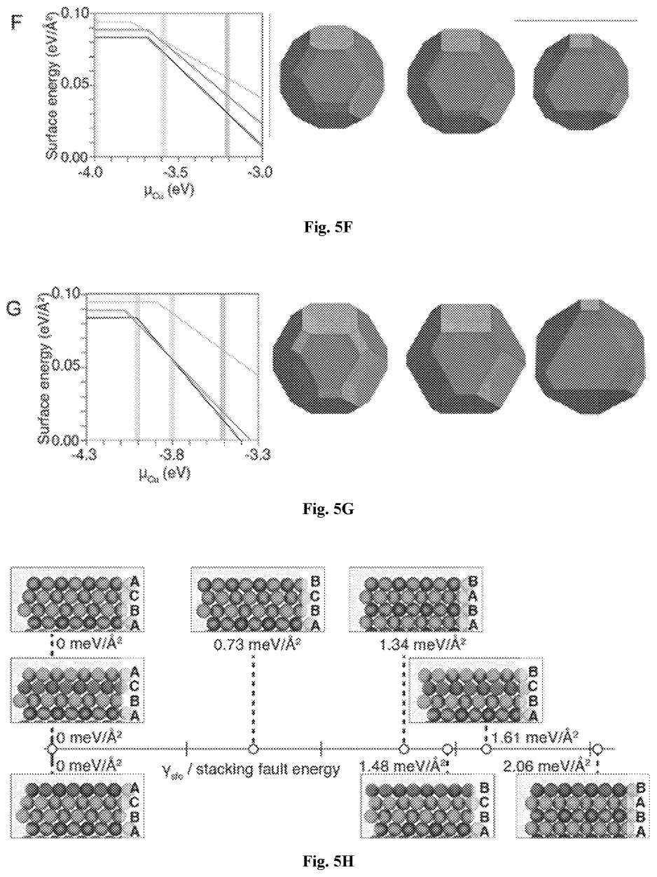

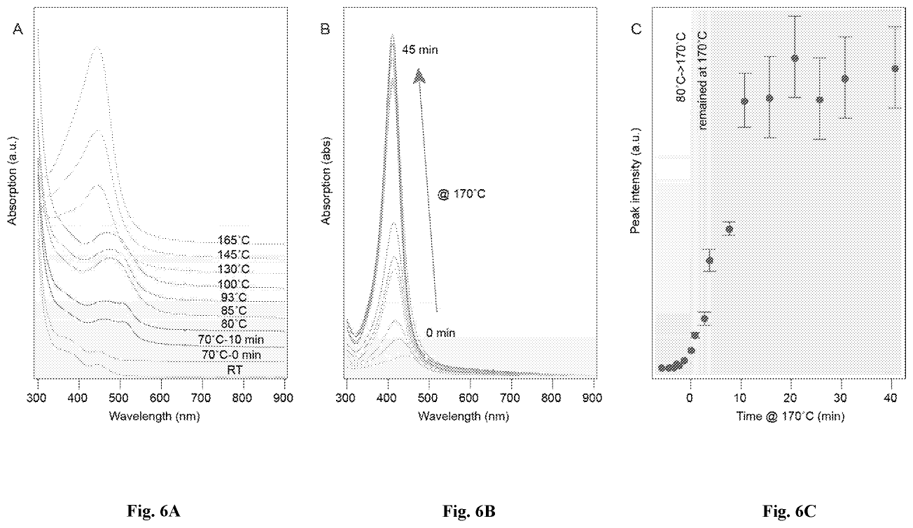

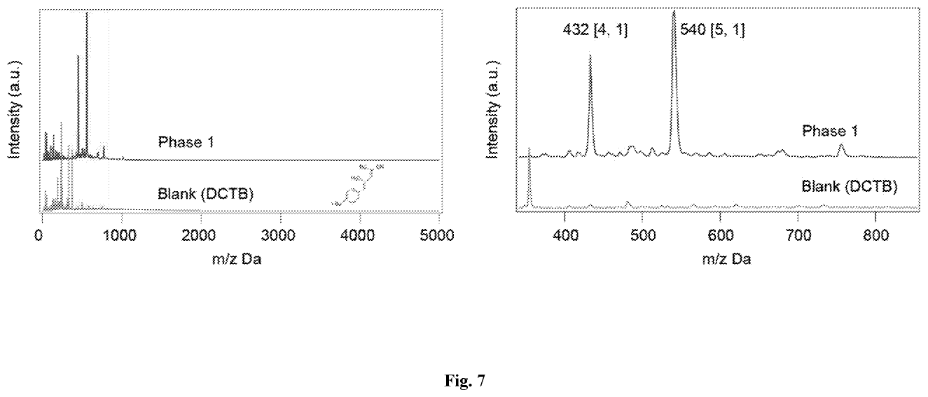

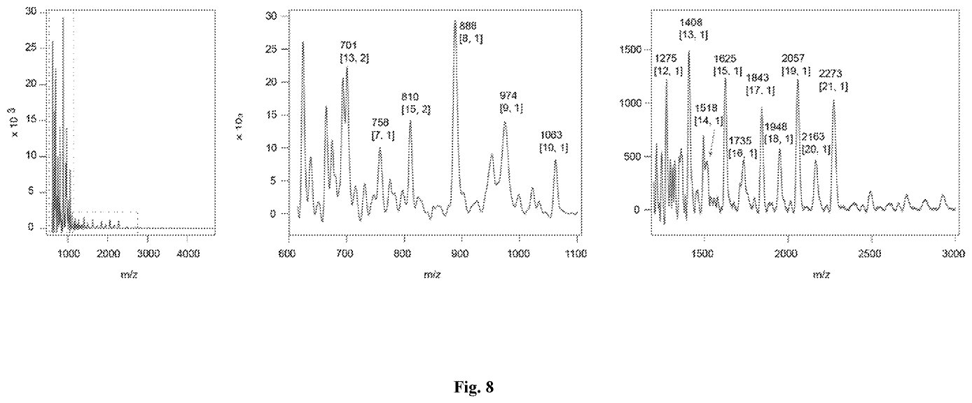

To elucidate the formation mechanism, aliquots were collected throughout the reaction and analyzed by UV-vis spectroscopy and complementary matrix-assisted laser desorption/ionization time-of-flight (MALDI-TOF) measurements (see FIG. 5A-E, FIG. 6, FIG. 7). A series of UV-vis spectroscopy unveiled that the spectral evolution experienced four distinct phases; Phase 1 (RT→70 °C): Two weak absorption peaks at ~377 nm and ~450 nm persisted during heating to 70 °C (see FIG. 5B, FIG. 6). Phase 2 (70 °C, 10 min ~): Two new peaks appeared ~470 nm, and ~516 nm with a drastic absorption intensity enhance, blackening of the reaction solution (see FIG. 5C, FIG. 6). Phase 3 (≈85 °C~): The two peaks merged into a dominant feature at ~480 nm (see FIG. 5D, FIG. 6). Phase 4 (130 °C→170 °C): A single, extremely intense peak appears at ~400-430 nm with its progressive increase in absorption extinction (see FIG. 5E, FIG. 6). The observed absorption spectral evolution was attributed to Ag cluster growth as the multi-peak spectra observed in Phases 1-3 are characteristic of molecular-like Ag clusters whereas the Phase-4 spectrum evolution is indicative of the transition to metallic Ag-NCs exhibiting emerging LSPR. Dominant species in each Phase was assigned based on comparison of reported and experimentally-observed spectral fingerprints to ~4-5 Ag atoms for Phase 1, ~29-36 Ag atoms for Phase 2, and ~75-79 Ag atoms for Phase 3, respectively. MALDI-TOF spectrum presented clear two peaks located at 432 (Ag4) and 540 (Ag5) m/z (see FIG. 7), while samples from Phase 2-4 showed a clear sign of decomposition (see FIG. 8). The optical response transitions from a molecular-like regime to a metallic, plasmonic regime occurs around beyond Ag136. Therefore, in Phase 4, NC growth took place via preceding stepwise cluster evolution.

### Example IV

### Effect of Reaction Components

The effect of various reaction components in the one pot reaction were analyzed. Control experiments demonstrated that copper acetate, oleylamine, and oleic acid each have an effect on the formation of uniform single-crystalline Ag-NCs.

When oleylamine was omitted, the reaction did not proceed, confirming its dual function as both the reducing agent responsible for converting Ag⁺ to Ag⁰ and the primary ligand stabilizing or promoting the emergent Ag-NC surfaces.

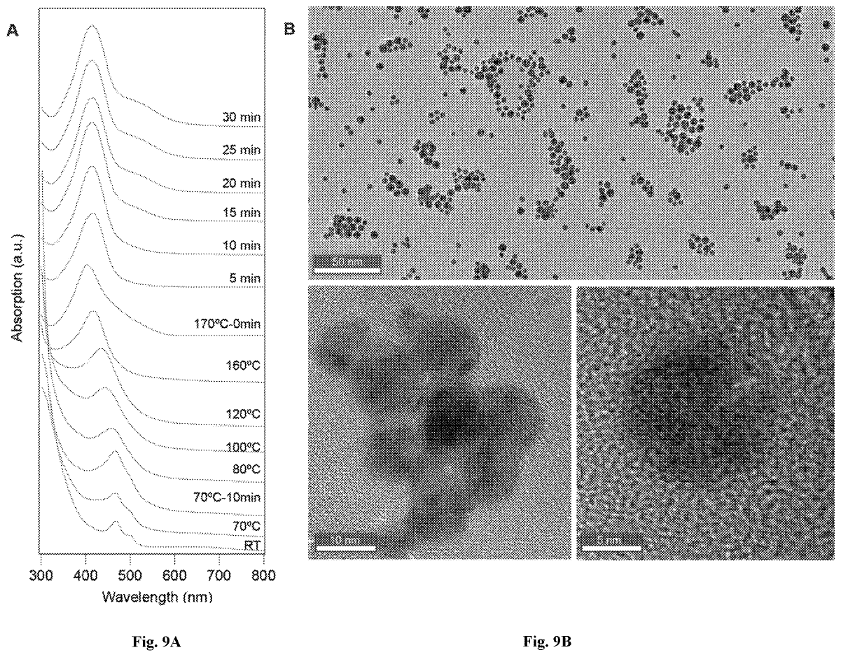

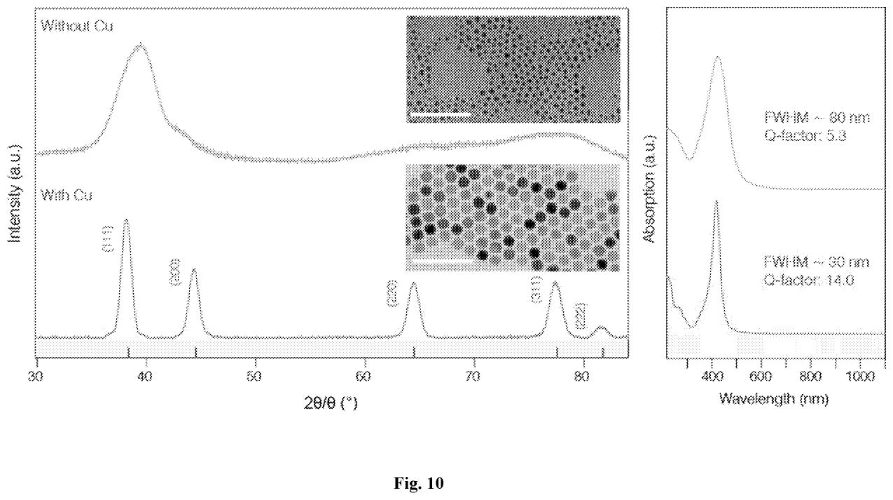

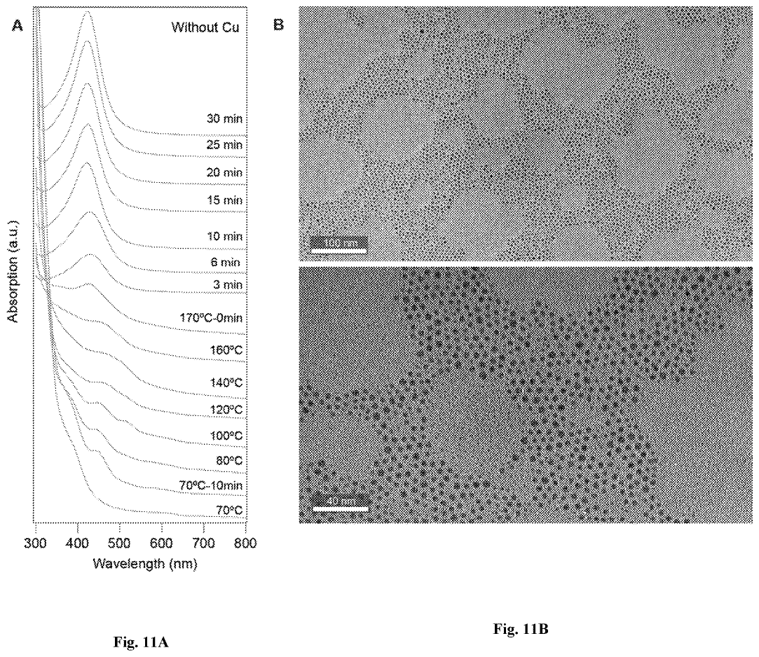

Oleic acid played a distinct regulatory function as well and may be referred to herein as a nanocrystal growth promoter agent. In its absence, the reaction yielded polydispersed and polycrystalline NCs as shown in FIG. 9A-FIG. 9B. The study of sampled aliquots suggested that the reaction solution without oleic acid bypassed the typical sequence of intermediate phases entirely (see FIG. 9A-FIG. 9B). Instead, absorption features near 460 and 499 nm appeared at room temperature and gradually evolved into a plasmonic peak around 400 nm as the reaction progressed (see FIG. 9A-FIG. 9B). This direct route, lacking the Phase 1 and 2 observed in the standard synthesis, led to poorly controlled NC growth (see FIG. 9A-FIG. 9B). These results suggest that oleic acid stabilizes specific early intermediates and modulates their interconversion, ensuring that the reaction proceeds through the defined multi-phase pathway required to produce monodisperse single-crystalline Ag NCs.

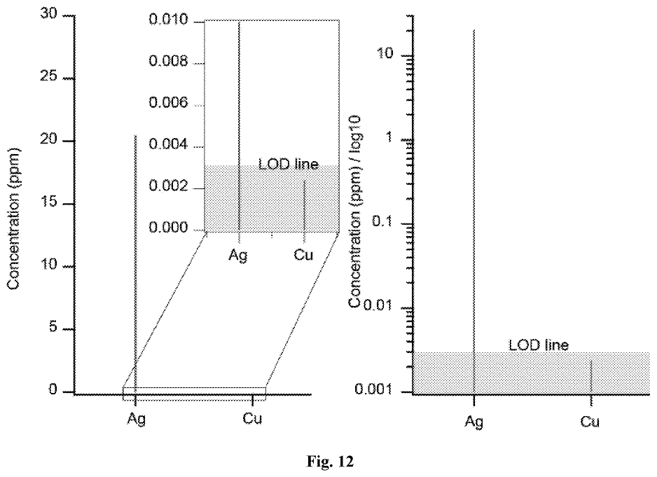

The reaction without copper acetate also produced Ag NCs with markedly polydisperse and polycrystalline features. XRD spectrum exhibited significantly wider peak width indicating small crystal domains and the HR-TEM directly showed polycrystallinity (see FIG. 10, FIG. 11). Moreover, the analysis of the aliquots suggested that the characteristic phase transitions occurred differently than in the standard reaction (see FIG. 11). Phase 1 appeared after 10 min of 70 °C until the reaction solution was heated to 80 °C, which is strikingly later than the standard reaction (see FIG. 11). From its appearance, the solution color at the point of 10 min at 70 °C remained orange without copper, which is a characteristic of early stage of the cluster formation, which is in striking contrast to the standard reaction solution turning into black, suggesting copper accelerates the transition from Phase 1 to 2 at the lower temperature. Phase 4, NC growth stage, also started late at 170 °C without copper, which is 40 °C higher than the standard reaction (see FIG. 11). Overall, while the reaction without Cu went through similar Phase-mediated processes, a trace amount of copper acetate remarkably catalyzed the advancement through the intermediate phases. Importantly, MALDI-TOF analysis and ICP measurements confirmed no detectable copper (or below detection limits), indicating a catalytic rather than incorporative role for copper in this synthesis (see FIG. 7, FIG. 8, FIG. 12).

The cluster-involved step-wise growth processes during Phase 1-3 resulted in successful Ag-NC formation, and NC-growth stage in Phase 4 may be driven through a ripening process because the other route, aggregation-driven growth, leads to polycrystalline materials. In a ripening-mediated NC-growth, however, monodisperse NC formation can be achieved only when monomer supply (i.e., dissolution of NCs and re-deposition of Ag monomers) has to be sufficiently rapid, of which condition is often referred to as production-controlled ripening regime. Aspects of the present method may utilize oleylamine as a reducing agent. Oleylamine also advantageously has a significantly weak binding affinity to Ag surfaces and thus promotes rapid monomer supplies and monodisperse Ag formation. Furthermore, a relatively high temperature (i.e., 130 °C) of the start of ripening stage in Phase 4 also facilitates a rapid ripening.

### Example V

### Density Functional Theory Study

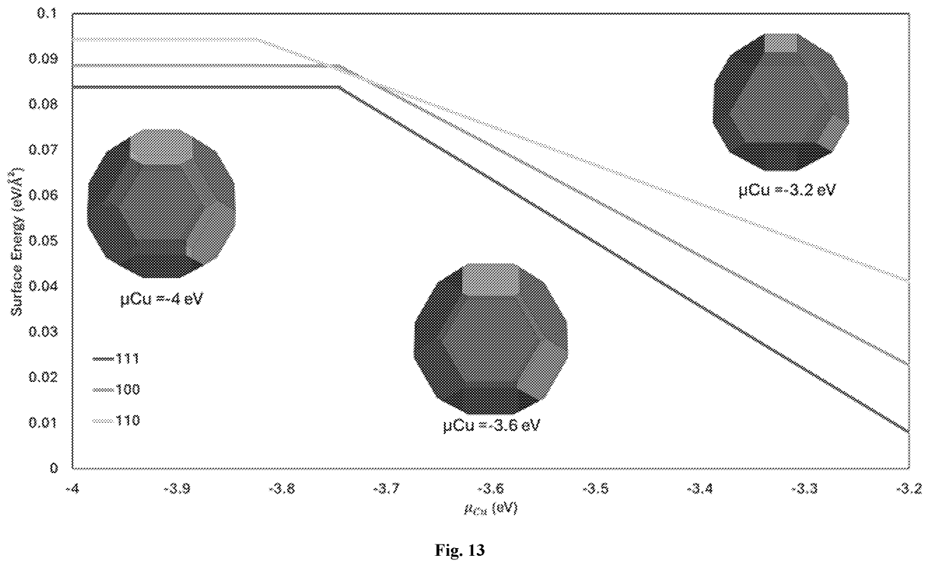

To understand the effect that Cu has on the shapes of the synthesized mecons, the surface energies of Ag slabs were calculated with different amounts of adsorbed Cu. These calculations show that the most favorable configurations for all the surfaces are either the bare Ag surface or an Ag surface covered with a full layer of Cu in the epitaxial FCC sites. The surface energies of the three low-index surfaces with minimum surface energy are shown in FIG. 13 as a function of the solution-phase Cu chemical potential. The {111} surface has the lowest energy among the bare surfaces at low m_{Cu}. With increasing m_{Cu}, the difference between g_{{111}} and the other surface energies becomes larger. This can be seen in the Wulff shapes in FIG. 13, which show a decreasing fraction of {110} and {100} surface area with increasing m_{Cu}. Wulff shapes were obtained using Wulffmaker known to those of skill in the art.

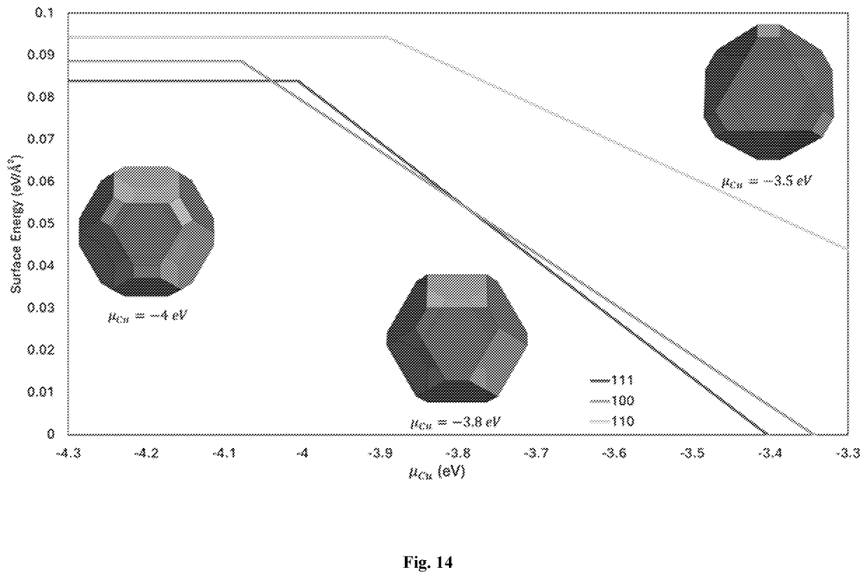

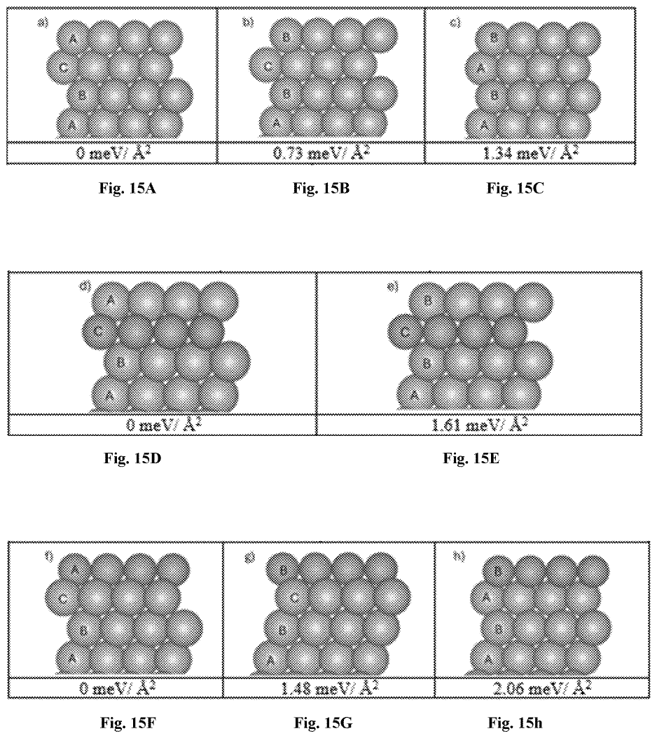

The possibility of intermixing between adsorbed Cu and Ag surface atoms was studied by probing the surface energies of slabs in which Cu atoms were placed in epitaxial FCC positions underneath a top layer of Ag. The results can be seen in FIG. 14, where the surface energies with Cu underneath the top Ag layer are lower than those with Cu on top. Additionally, γ₁₁₀ becomes large compared γ₁₀₀ and γ₁₁, so {110} surfaces are not seen in the Wulff shapes. Further, γ₁₀₀ becomes closer to γ₁₁₁ and is lower than γ₁₁₁ for a range of m_{Cu}. As a result, {100} surfaces appear more prominently in the Wulff shapes for intermixed Cu than for a Cu adlayer. The difference between γ₁₀₀ and γ₁₁₁ becomes larger than the difference for bare Ag surfaces for sufficiently high values of m_{Cu} (e.g., for m_{Cu}=−3.5 eV) and the result is truncated octahedral Wulff shapes, as seen with Cu adsorbed on top of the Ag surfaces.

Without wishing to be bound by scientific theory, the presence of Cu helps to increase the crystallinity of the Ag NPs. To understand this possibility, the near-surface stacking-fault energies of systems were compared with and without Cu. A pure FCC system without stacking faults has ABCABC . . . stacking of the {111} planes. Equation D3

$${γ}_{sfe} = \frac{{E}_{slab + s f} - {E}_{slab}}{A} \qquad ( D3 )$$

was used to determine stacking-fault energies in three systems: a pure Ag slab (see FIG. 15A-15C), a slab with Cu in the second layer, underneath a top Ag layer (see FIG. 15D-15E), and a slab with an adsorbed Cu layer (see FIG. 15F-15H). For each system, the configuration on the left (see FIGS. 15A, 15D and 15F) is a system with no stacking faults(γ_{sfe}=0). This configuration serves as a reference (E_{slab} in Equation D3) for configurations on the right in each of the top, middle and bottom rows.

In the pure Ag slab, γ_{sfe}=0.73 meV/Å² when the stacking fault resides on the top layer (see FIG. 15B) and γ_{sfe}=1.34 meV/Å² when the stacking fault resides just below the top Ag layer (see FIG. 15C]. Comparing FIG. 15B with FIG. 15E, when Cu lies just below the top layer (see FIG. 15E), the stacking-fault energy increases to 1.61 meV/Å². Comparing FIG. 15C and FIG. 15H, when Cu is on the top of the slab (see FIG. 15H), the stacking-fault energy increases to 2.06 meV/Å². It is evident from this comparison that Cu disfavors stacking-fault formation in the Ag crystal. A comparison between FIG. 15B, FIG. 15F and FIG. 15G reveals that if, as suggested, Cu adsorbs on the surface and is replaced by Ag, the mechanism is more likely to be through Ag replacing an epitaxial Cu layer (see FIG. 15F) than Ag replacing a Cu stacking fault, as the stacking-fault energy for the epitaxial Cu layer is about twice as high as that for an epitaxial Ag layer.

### Example VI

### Varying Reaction Conditions and Components to Control Shape and Plasmonic Properties

For Ag-NCs with an identical volume with different sphericity values, annealing experiments were conducted. Initially, mecon Ag-NCs were synthesized. After purification and collection, 15 mg of the Ag-NCs were redispersed in a mixture of 8 mL of 4-tert-butyltoluene and 2 mL of OAm in a flask. Following three cycles of freeze-pump-thaw degassing, the solution was heated to 160 °C-200 °C. The reaction was monitored by measuring the absorption peak of aliquots. To collect the samples, the reaction flask was rapidly cooled to room temperature using an ice-water bath. The product was collected via centrifugation, followed by precipitation with acetone.

Precise control over Ag-NC size and morphology was achieved by systematically varying reaction temperature, oleic acid and oleylamine concentrations, and annealing duration, yielding a library of 25 Ag-NC samples. In general, lower ligand concentrations and higher reaction temperatures produced larger nanocrystals, whereas annealing time most strongly governed shape evolution: extended annealing consistently transformed faceted mecon-type geometries into increasingly spherical particles. A representative 10.0 nm series (see FIG. 16A-D, FIG. 17) illustrates a continuous and highly uniform transition from faceted mecons to spheres while maintaining monodispersity, volume of a NC, and crystallinity.

Shape and size of Ag-NCs are the primary parameters governing third resulting plasmonic properties. To quantitatively describe these intermediate shapes, a sphericity parameter X was defined with λ=0 for a perfect mecon and λ=1 for a perfect sphere (see FIG. 16A). Intermediate geometries with 0≤λ≤1 were constructed by interpolating the center-to-surface distance between a theoretical mecon and a volume-equivalent sphere, weighted by the X value (see FIG. 16A-B). The computer-generated objects with various X showed a smooth transition from mecon to sphere (see FIG. 16A-B), which is consistent with relevant TEM images presented in FIG. 16C. In order to extract X values from 2D TEM, anisotropy was measured specifically, the aspect ratio between the long and short diameters (see FIG. 16B). Using HR-TEM images aligned along the frequently observed [110]Ag-fcc projection, the long and short diameters correspond to the distances between two (100) planes and two (111) planes, respectively. The theoretical aspect ratios are 1.18 for λ=0 and 1.00 for λ=1; X was obtained by interpolating between these limits using averages from ≥25 rigorously oriented images. For five 10.0 nm samples presented in FIG. 3C, X values of 0.17, 0.39, 0.45, 0.72, and 0.95 were obtained.

This series of Ag-NCs enabled direct isolation of shape-driven LSPR modulation. The most mecon-like sample (λ=0.17) exhibited a dominant peak at 426 nm with a pronounced shoulder near 370 nm (see FIG. 16E left). Increasing X caused a systematic blueshift of the main peak and gradual disappearance of the shoulder (see FIG. 16E), with the most spherical particles showing symmetric spectra centered at 406 nm (see FIG. 16E right). Because particle volumes are essentially constant across the series, these spectral changes are attributable to shape effects alone. For the 10.0 nm series, the main peak position showed a strong linear dependence on λ (R²=0.93; see FIG. 16F), described by:

Peak position (λ),nm=428.4−25.1×λ(Size=10.0 nm).

Direct dipole approximation (“DDA”) simulations independently reproduced these trends (see FIG. 16G). DDA simulation for Ag-NCs with the size of 10.0 nm and various X demonstrated the blue-shifting main peak and diminishing shoulder peak at 370 nm with increasing X (see FIG. 16G). The simulated main peak positions (purple marks in FIG. 16F) closely overlapped the experimental results (pink marks in FIG. 16F), confirming that LSPR features can be predictably tuned by morphology.

How size and shape jointly influence plasmonic behavior was studied. To capture the coupled effects, a simple linear model was constructed for peak position with functions of X and Size as described below:

Peak position (λ,Size)·nm=a+b×λ+c×Size+d×(λ×Size)
where a, b, c, and d are coefficients. 25 Ag-NCs in total were synthesized in the range of 5 nm≤Size≤11 nm and 0≤λ≤1 (see FIG. 16H-16I, FIG. 18, FIG. 19, FIG. 20), determined their X values and size using TEM, and measured the absorption spectra. All the parameters of the Ag-NCs, i.e., peak positions, size, and X, are listed in FIG. 18. Using these dataset, the four coefficients, a, b, c, and d, were determined through least-squares fitting, which appeared as

Peak position (λ,Size)·nm=435.1−18.6×λ−0.3×Size−1.3×(λ×Size).

The plots of experimentally-obtained and above-equation-giving peak top positions shows a linear relationship with the R² values of 0.85 (see FIG. 21), underscoring the accuracy of this model. To visualize the model continuously over the experimentally relevant domain (5-11 nm, 0≤λ≤1), peak positions were calculated on a 500×500 mesh and rendered as a X-size contour map (see FIG. 16H). Overlaying experimental datapoints on the contour background (solid mark in FIG. 16I) demonstrated the strong agreement. Furthermore, the color contour map, together with the fitted equation, provides a holistic view of the coupled size-shape dependence of the plasmonic response. For example, spherical Ag-NCs (higher λ) exhibit a pronounced blueshift with increasing size, whereas mecon-like Ag-NCs (lower λ) show a much weaker size dependence, with at most a slight blueshift (see FIG. 16I). To further validate these size trends, DDA simulations were performed for Ag-NCs at λ=1 and λ=0 over the size range of 5-11 nm (see FIG. 22). Consistent with the contour-map prediction, spherical particles display a clear blueshift with increasing size, while mecon-like particles show no strong systematic trend, supporting both the experimental measurements and the model (see FIG. 22).

### Example VII

### Surface Engineering of Ag-NCs and Biological Application

Ligand exchange on Ag-NCs was carried out using one of three approaches depending on ligand class: (1) the PEG-based ligands method, (2) immersion-precipitation for hydrophobic ligands, and (3) two solvent-layer interfacial exchange for ligands soluble in polar media.

A PEG-based method was used for PEG-SH ligands with molecular weights of 5 kDa, 20 kDa, and for biotin-functionalized PEG. Ag-NCs were first transferred to chloroform (c.a. 1 mg), then added to a freshly prepared chloroform solution of the PEG-based ligands (c.a. 10 mg in 100 L). The mixture was stirred overnight to promote ligand exchange. To isolate the PEG-coated NCs, hexane was added to induce precipitation, followed by centrifugation for 2 min at 300 rcf. The resulting precipitation was redispersed in water or PBS for subsequent characterization.

An immersion-precipitation method was used for ligand exchange with liquid-crystal-based ligands, 2-chloro-5-methylthiophene, and polystyrene-thiol (PS-SH; MW≈11 kDa). Ag-NCs were transferred to toluene (c.a. 1 mg) and mixed with freshly prepared toluene solutions of the target ligands (c.a., 5 mg in 1 mL). The mixture was stirred overnight. The ligand-exchanged Ag-NCs were precipitated by addition of acetone, collected, and then redispersed in toluene for further analysis.

A solvent-layer interfacial ligand exchange method was used for 11-mercaptoundecanoic acid (11-MUA), methylene blue (MB), and PEDOT:PSS. Ag-NCs were dispersed in toluene, serving as the non-polar phase. The polar phase consisted of 11-MUA and MB dissolved in water with pH adjusted using HCl or NaOH or PEDOT:PSS dispersed directly in methanol (as purchased). The toluene (upper) and polar (lower) phases were combined in a single vial to form two distinct layers. The vial was then shaken vigorously for 10 min to temporarily mix the phases and drive ligand exchange, resulting in transfer of Ag-NCs from the non-polar to the polar phase. Phase separation was re-established by adding hexane, then the non-polar (toluene/hexane) phase—which became colorless after NC transfer—was removed. Two additional washing cycles were performed by extracting residual non-polar components with fresh hexane.

According to the present disclosure, surface engineering enables systematic tuning of Ag-NC dispersibility, allowing them to remain stable in media appropriate for target applications, including bio-related uses, electronics, and other functional materials (see FIG. 23A). The native oleylamine capping layer of Ag-NCs in this study binds relatively weakly to silver and can be replaced by molecules containing sulfur functionality (see FIG. 24). To demonstrate the exceptional surface-engineering ability, ligand exchange experiments were performed with a diverse set of ligands (see FIG. 23B, FIG. 25), including polyethylene glycol (PEG; MW 5,000 and 20,000), a biotinylated PEG derivative, 11-mercaptoundecanoic acid (11-MUA), thiol-terminated polystyrene, methylene blue (MB), 2-chloro-5-methylthiophene (2C15MeTP), a semi-fluorinated thiol, azobenzene-based liquid-crystalline ligands, and PEDOT:PSS (see FIG. 23B-23C). The modified Ag-NCs exhibited excellent dispersibility in the intended medium; PEG-modified Ag-NCs, MB-functionalized Ag-NCs, and 11-MUA-capped Ag-NCs dispersed readily in water without aggregation, whereas thiophene-based ligands, azobenzene liquid-crystal ligands, semi-fluorinated ligands, and polystyrene rendered the Ag-NCs highly dispersible in toluene, and PEDOT:PSS-functionalized Ag-NCs were stably dispersed in methanol (see FIG. 23D). TEM confirmed preservation of the nanocrystal cores and revealed ligand-dependent modulation of interparticle spacing (see FIG. 23E). FTIR spectra verified replacement of oleylamine by the respective sulfur-containing ligands (see FIG. 23C). Notably, PEG-coated Ag-NCs could be concentrated to at least 20 mg mL- and remained stable in both water and phosphate-buffered saline (PBS), indicating excellent colloidal stability without oxidation or structural degradation (see FIG. 27, FIG. 28).

Ligand requirements that enable surface engineering of the Ag-NCs was studied. While S-Ag bond formation facilitates successful ligand exchange, ammonium sulfide, 1-dodecanethiol, and ammonium thiocyanate induced rapid structural degradation, converting the Ag core to Ag₂S and yielding no dispersibility in any solvent (see FIG. 23B, FIG. 25). Small-sized sulfur-terminated molecules with lack of steric hinderance lead to too strong reactivity to protect the Ag-NC cores. Conversely, similar-sized molecules containing C—S-C motifs such as 2C15MeTP and MB are among successful molecules for ligand exchange (see FIG. 23B, FIG. 25). Taken the modest binding energy of thiophene-Ag bonds, these molecules are restrictive for further reactions and successfully cap the surface of the Ag-NCs (see FIG. 23B, FIG. 25). Meanwhile, NH₄⁺ and PVP produced no meaningful change in dispersibility, indicating that purely amine-based interactions are insufficient to displace the native oleylamine-Ag surface interaction (see FIG. 25). Overall, successful ligand exchange occurs with molecules having an appropriate binding strength: either sterically bulky thiols or molecules with C—S-C motifs as found in thiophenes and MB (see FIG. 23B).

To this end, potential ligand usage was tested in biological systems for MB-capped Ag-NCs. HeLa cells were seeded in the inner wells of a 96-well clear flat-bottomed TC-treated plate (Genesee Scientific, #25-109) and cultured in DMEM supplemented with 10% FBS at 37 °C, 5% C02 until reaching 85% confluency. Lights in the biosafety cabinet were turned off for the duration of the subsequent experiment. The culturing media was aspirated, and cells were washed twice with 1×PBS. AgNC-PEG (4.5 mg/mL in MilliQ H₂O), methylene blue (MB) (2.0 mg/mL in MilliQ H₂O), and AgNC-MB (0.3 mg/mL in MilliQ H₂O) were first diluted to 0.3 mg/mL in sterile MilliQ H₂O and then to 4 g/mL in DMEM supplemented with 10% FBS. Live cells were treated with the compounds (4 g/mL) for 1 hr at 37 °C, 5% CO₂. After, media was aspirated, and the cells were washed three times with PBS before being resuspended in Fluorobrite DMEM. Cells were then subjected to imaging on the Keyence All-in-One Fluorescence Microscope (BZ-X810).

FIG. 23F presents the absorption spectrum and a photograph of MB-capped Ag-NCs aqueous dispersion. The green color of the solution came from “synthesis of colors”; yellow (Ag-NCs)+blue (MB)=green (MB-capped Ag-NCs) and the absorption spectrum clearly exhibits peaks orientated both from Ag—NCs and MB (see FIG. 23F). To assess the cytotoxicity, different concentrations (0-5.0 g/mL) of the MB-capped Ag-NCs were incubated with cervical cancer (HeLa) cells for 8 hours (see FIG. 29). MB only and PEG-capped Ag-NCs were also included as controls. Using the CCK-8 assay to measure cell viability, about 80% HeLa cell viability was observed under all conditions except 5 g/mL MB-capped Ag-NCs, where viability decreased sharply to ~15%. This cytotoxicity, even in the absence of photoactivation, could potentially be due to the synergistic anticancer effects of the Ag-NCs and MB or enhanced cellular delivery of the MB-capped Ag-NCs.

The cellular uptake of MB-capped Ag-NCs was investigated through fluorescence microscopy. Live HeLa cells were incubated with PEG-capped Ag-NCs, MB only, and MB-capped Ag-NCs at 4 g/mL for 1 hr and then washed with PBS to remove treatment compounds before being subjected to fluorescence imaging. As shown in FIG. 231, the MB-capped Ag-NCs treatment yielded observable intracellular fluorescence, comparable to that of the MB only condition, and cells treated with PEG-AgNCs showed only minimal fluorescence.

It is important to note that while MB is commonly used as a redox-based cell viability indicator that is reduced and decolorized in live cells, this process is often incomplete at the concentrations and timescales used for cellular imaging. Additionally, MB has been used clinically as a fluorescent dye to visualize tumors in surgery. Thus, the fluorescence observed from the MB and MB-capped Ag-NCs treatments under the experimental conditions herein are only reflections of internalization and fluorophore retention, rather than as an additional marker of viability/non-viability beyond the CCK-8 assay.

Based on the above studies, methods of surface-tailoring, biofunctionalization strategies, and biological application possibilities for Ag-NCs are disclosed.

### Example VIII

### Instruments and Software

The following instruments and software were used as indicated in the above examples. TEM and selected-area ED measurements were performed on a JEOL-2100F microscope, operated at 200 kV. High-angle annular dark-field scanning transmission electron microscopy (HAADF-STEM) images were acquired with a Hitachi HD 2700C dedicated STEM, equipped with a probe Cs corrector, and operated at 200 kV. HAADF-TEM was performed on an FEI Talos F200× TEM/STEM, also operating at 200 kV. Powder X-ray diffraction patterns were obtained on a Bruker D8 Discovery 2D X-ray Diffractometer, equipped with a Vantec 500 2D area detector and operating with Cu Kα (λ=1.541 Å) radiation. Absorption spectra were measured using an Agilent Technologies Cary 5000 UV-Vis-NIR Spectrophotometer Matrix-assisted laser desorption ionization-time-of-flight (MALDI-TOF) mass spectrometer measurements was conducted using Bruker Autoflex linear TOF system, Bruker Daltonics. The instrument is equipped with a MALDI ion source and a 355 nm Nd:YAG SmartBeam laser. For MALDI sample preparation, the as-synthesized Ag samples were dispersed in toluene. Separately, a 20 mg of DCTB (trans-2-[3-(4-tert-butylphenyl)-2-methyl-2-propenylidene]malononitrile) was prepared in 1 mL toluene. The sample solution and the DCTB matrix solution were mixed in a 1:1 (v/v) ratio, and the resulting mixture was spotted onto the MALDI sample plate and allowed to air-dry at room temperature. Computer models were constructed using Autodesk 3ds Max (Autodesk).

### Example IX

### Superlattice Formation Using Precious Metal Nanocrystals

Aspects of the present disclosure are directed to superlattice (“SL”) formation using precious metal nanocrystals. Exemplary precious metal nanocrystals may be produced by the methods described herein or may be produced by other methods include prior art methods. According to one aspect, Ag-NCs can self-assemble into SLs with stable dissymmetric configurations. According to certain aspects, exemplary precious metal silver nanocrystals with shapes similar to truncated octahedra (mecons) self-assemble into superlattices that are stable and resemble a previously unobserved phase that bridges face-centered and body-centered cubic structures along the Nishiyama-Wasserman martensitic pathway. These superlattices exhibited high structural purity and stability and created a robust and tunable dissymmetric phase landscape. Notably, light-matter coupling emerged in these silver nanocrystal superlattices through plasmon-photon hybridization at the quantum level.

According to one aspect, stable silver nanocrystal (Ag-NC) SLs were formed that resemble the in-transition phase of martensitic transformation under ambient conditions that was achieved through the controlled assembly of shape-engineered Ag-NCs. By fine tuning the Ag-NC shape from a sphere to a mecon (also known as truncated octahedron), a gradual SL evolution from an face-centered cubic (FCC) to a body-centered cubic (BCC) lattice was observed. The Ag-NCs with intermediate shapes form stable dissymmetric SLs that resemble transient in-transition structures along the Nishiyama-Wasserman (N-W) martensitic transformation pathway. See Z. Nishiyama, M. E. Fine, M. Meshii, C. M. Wayman, Martensitic transformation. Materials science and technology (Academic Press, 1978). Computer simulations reveal the critical role of both particle shape and soft ligands in stabilizing these dissymmetric SL structures. Furthermore, all the SL films obtained from 10-nm-ish Ag-NCs (FCC, dissymmetric, and BCC SLs) exhibit quantum-level plasmon-photon hybridization within the deep-strong light-matter coupling regime, i.e., coupling strength exceeding unity.

Synthesis of mecon-shaped Ag-NCs was carried out as follows: 333 mg of Ag-acetate, 1.9 mg Cu(acetate)₂, 1 μL of HCl, 1 mL of OAcid, 1 mL of OAm, and 12 mL of DPE were loaded into a 100-mL flask. The solution was degassed under vacuum for 5 minutes at room temperature, then heated to 45 °C for 10 minutes, followed by heating to 80 °C for 20 minutes. Under a nitrogen blanket, the solution was further heated to 180 °C and maintained for 5 minutes. After the reaction was completed, the flask was swiftly cooled to room temperature using an ice-water bath. The product was collected via centrifugation following precipitation with acetone, and the resulting Ag-NCs were stored in hexane.

Synthesis of spherical Ag-NCs was carried out as follows. The synthesized mecon Ag-NCs described above were used as the initial materials and transformed into spherical Ag-NCs through annealing process. Specifically, 15 mg of the mecon-shaped Ag-NCs were redispersed in a mixture of 8 mL of 4-tert-butyltoluene and 2 mL of OAm in a flask. Following three cycles of freeze-pump-thaw degassing using liquid nitrogen, the solution was heated to 200 °C and kept for 5 min. To collect the samples, the reaction flask was rapidly cooled to room temperature using an ice-water bath. The product was collected via centrifugation, followed by precipitation with acetone.

Synthesis of intermediate-shaped Ag-NCs with λ=0.62 was carried out as follows: 334 mg of Ag-acetate, 1.9 mg Cu(acetate)₂, 1 μL of HCl, 2 mL of OAcid, 2 mL of OAm, and 10 mL of DPE were loaded into a 100-mL flask. The solution was degassed under vacuum for 5 minutes at room temperature, then heated to 45 °C for 10 minutes, followed by heating to 80 °C for 20 minutes. With an identical volume with different sphericity values, we conducted annealing experiments. Under a nitrogen blanket, the solution was further heated to 150 °C and maintained for 5 minutes. After the reaction was completed, the flask was swiftly cooled to room temperature using an ice-water bath. The product was collected via centrifugation following precipitation with acetone, and the resulting Ag-NCs were stored in hexane.

Hexane suspensions of Ag-NCs produced by the methods described herein (at a concentration of c.a. 10 mg/mL) were used for SL formation through a slow solvent evaporation process. In particular, 4 mL of Ag-NC solution in hexane (10 mg/mL) was placed in a capped vial and allowed to dry over 3-6 weeks. This slow evaporation process was useful for obtaining structurally rigid SLs with sharp and well-defined SAXS peaks. The film samples for TEM and optical measurements were prepared using a liquid-air interface method. A 0.1-mL hexane solution of Ag-NCs (1 mg/mL) was placed on a pool of dimethylformamide in a 20-mL glass vial. Typically, evaporation took around 10 minutes, during which the Ag-NC SL films formed on the liquid substrate. The floating Ag-NC SLs were collected onto a desired substrate (e.g., TEM grid, glass substrate) for further measurements. More generally, films and/or superlattice films comprising the nanocrystals may be formed by solvent-evaporation-driven deposition techniques, including, without limitation, drop-casting, spin coating, dip coating, blade/doctor-blade coating, bar coating, slot-die coating, spray coating, inkjet printing, aerosol jet printing, convective assembly (e.g., vertical deposition), and liquid-air or liquid-liquid interfacial assembly (including Langmuir-type interfacial film formation and transfer). In such embodiments, the solvent and evaporation rate may be selected to control film thickness, ordering, interparticle spacing, and optical response. Films may have a thickness of between about 1 nm to about 1000 nm. Films may include from 1 to 1000 nanocrystal layers. The dimensions of films may be any length or width or circumference as desired. The shapes of such films may be any shape as desired. Films may be disposed on a substrate including glass, quartz, silicon, sapphire, a polymer film or a metal foil.

Synchrotron-based small-angle x-ray scattering (SAXS) measurements revealed that the spherical Ag-NCs were assembled into an FCC structure (a_{SL-FCC}=17.75 nm), whereas the mecon Ag-NCs formed a BCC SL (a_{SL-BCC}=14.12 nm), resembling the three-dimensional honeycomb structure (see FIG. 30H, FIG. 30J, FIG. 30K, FIG. 30L). TEM images of the obtained FCC and BCC SLs were consistent with the assigned structures viewed from the [111]_{SL-FCC} and [110]_{SL-BCC} projections, respectively see (FIG. 30K, FIG. 30L, middle insets). Selected-area wide-angle electron diffraction (WAED) measurements confirmed the atomic orientation alignments across all constituent Ag-NCs in the SLs (see FIG. 30K, FIG. 30L, right insets). In the FCC SLs, a six-fold symmetric WAED pattern was observed when viewed along the [111]_{SL-FCC} projection (see FIG. 30K, right and middle insets).

Detailed analysis based on simulated WAED patterns suggested that the spherical Ag-NC orientations were aligned such that the [110]_{Ag-FCC} projections appear in the (111)_{SL-FCC} plane, with three distinct in-plane rotational orders exhibiting a regulated angle offset of 120° (see FIG. 30H). In contrast, a single-crystal-like spotted WAED pattern, identical to the [110]_{Ag-FCC} diffraction pattern of Ag-NCs, was obtained for the BCC SLs when viewed along the [110]_{SL-BCC} projection (see FIG. 30L, right inset). This result indicated that in the BCC SL, the crystal lattice axis of Ag-NCs and the SL axis shared the same coordinate directions (i.e., x, y, and z axes) (see FIG. 30J), where maximized {111}_{Ag-FCC}-to-{111}_{Ag-FCC} facet alignments are exhibited).

Ag-NCs were synthesized with an intermediate shape between a mecon and a sphere. To quantify the shapes, a sphericity parameter, λ, was defined where λ=0 represents a perfect mecon and λ=1 corresponds to a perfect sphere. TEM measurements confirmed excellent size and shape uniformities of the synthesized Ag-NCs with a λ of 0.62), which was utilized to produce powder Ag-NC SLs. Synchrotron-based SAXS measurements revealed an intricate pattern, characterized by more than thirty well-resolved scattering peaks within the scattering vector q in the range from 0.05 to 0.30 Å⁻¹ (corresponding to a lattice spacing d of 12.56 to 2.09 nm, see FIG. 31A).

This SAXS pattern could not be attributed to any common SL structures assembled in single-component NC systems, such as FCC, BCC, hexagonal close packed (HCP), or any combination of these phases. Therefore, phase-intermediate structures were examined that arise during four common martensitic transformation pathways, that is, Bain, Pitsch, Nishiyama-Wasserman (N-W), and Kurjumov-Sachs pathways). See H. Sowa, Sphere packings as a tool for the description of martensitic phase transformations. Acta Crystallogr A 73, 39-45 (2017). Through structural analyses based on both real- and reciprocal-space results, it was identified that the Ag-NC SLs had a phase-intermediate structure along the N-W martensitic transformation pathway (see FIG. 31A, FIG. 31D). N-W phase-intermediate unit cells are described using a base-centered monoclinic Bravais lattice (see FIG. 31A right inset). In the N-W pathway, the crystallographic relationship with the reference FCC and BCC structures presents the (001)_{SL-N-W} as the shared lattice plane with the (111)_{SL-FCC} and (011)_{SL-BCC} planes, and the shared directions of [11̅0]_{SL-FCC}//[01̅0]_{SL-N-W}//[100]_{SL-BCC} and [1̅1̅2]_{SL-FCC}//[1̅00]_{SL-N-W}//[01̅1]_{SL-BCC} (see FIG. 31B). By descending the high symmetry (Oₕ point group) of FCC or BCC structures to the lower symmetry (C_{2/m} point group) of a N-W phase-intermediate structure, additional SAXS peaks emerge by gradually dissolving the peak degeneracy of the reference FCC or BCC lattices (see FIG. 31C). Through fitting the SAXS pattern using the N-W unit cell, the lattice constants were determined to be a=19.58 nm, b=12.13 nm, c=12.13 nm, α=90°, β=128.6°, and γ=900 (see FIG. 31A). This N-W phase-intermediate lattice comprises a 33.8% BCC (i.e., 66.2% FCC) structural contribution, defined as a phase-intermediate structural parameter, τ=33.8%). The shared plane in the N-W phase-intermediate unit cell with τ=33.8%, i.e., (001)_{SL-N-W} exhibited a 4.5% expansion along the [11̅0]_{SL-FCC} and 2.1% contraction along the [112]_{SL-FCC} compared to the reference FCC phase (see FIG. 31B). The obtained N-W phase-intermediate SLs showed high structural purity and remained stable for at least 6 months after formation despite their high structural complexity.

To identify the orientational order of the constituent Ag-NCs (λ=0.62) within this phase-intermediate SL, the structure from four distinct SL projections was probed: [001]_{SL-N-W}; [011]_{SL-N-W}; [102]_{SL-N-W}; and [105]_{SL-N-W} (see FIG. 31D). Correlating the NC and SL orientations, the [310]_{Ag-FCC}, [10]_{Ag-FCC}, [101]_{Ag-FCC}, and [100]_{Ag-FCC} atomic orientations Ag-NCs were confirmed to align with the [001]_{SL-N-W}, [011]_{SL-N-W}, [102]_{SL-N-W}, and [105]_{SL-N-W} SL projections, respectively (see FIG. 31D: iv, ix, xiv, xix). This orientation alignment was consistent with the assigned SL and atomic models (see FIG. 31D). In the SL model, {111}_{Ag-FCC}-to-{111}_{Ag-FCC} facet registrations between neighboring particles were consistently observed in the shared plane (i.e., (001)_{SL-N-W} plane) along the N-W pathway (see FIG. 31B). This retention of inter-{111}_{Ag-FCC} facet registry in the shared planes uniquely exists in N-W phase-intermediate structures but not in any phase-intermediate configurations along other martensitic transformation pathways. These findings suggest that inter-facet interactions among Ag-NCs play a critical role in stabilizing this unusual N-W phase-intermediate SL. See Y. Nagaoka et al., Superstructures generated from truncated tetrahedral quantum dots. Nature 561, 378-382 (2018); Y. Nagaoka et al., Single-component quasicrystalline nanocrystal superlattices through flexible polygon tiling rule. Science 362, 1396-1400 (2018); Y. Nagaoka et al., Dynamic Transformation of High-Architectural Nanocrystal Superlattices upon Solvent Molecule Exposure. J. Am. Chem. Soc. 146, 13093-13104 (2024); Z. Quan et al., Superlattices with non-spherical building blocks. Nano Today 5, 390-411 (2010); J. Gong et al., Shape-dependent ordering of gold nanocrystals into large-scale superlattices. Nat. Commun. 8, Article number: 14038 (2017).

To further demonstrate the general applicability of capturing N-W phase-intermediate structures, Ag-NCs with various sphericity parameters (λ: from 0.11 to 0.95) and particle volumes (ranging from c.a. 85 nm³ to 590 nm³, particle size of 5.5 nm to 10.4 nm) were synthesized and assembled into SLs (see FIG. 31E, FIG. 31F). N-W phase-intermediate SLs at different transitioning stages (0%<τ<100%) can be produced from the Ag-NCs with λ between ~0.35 and ~0.85 (see FIG. 31E, FIG. 31F). Increasing particle size broadens the stability window of the phase-intermediate SLs compared to smaller counterparts (see FIG. 31E). Moreover, the phase-intermediate SL structural parameter, τ, shows a strong correlation following a sigmoid curve with the Ag-NC sphericity parameter, λ (see FIG. 31F), indicating the phase-intermediate structural control and stabilization through precise engineering of particle shape. These results reveal a phase diagram containing a region where such highly dissymmetric structures can exist with a wide range of structural parameters (that is the full range of τ is accessible).

To investigate the formation mechanisms of the phase-intermediate structures, minimal models of ligand-coated Ag-NCs were developed and hard particle Monte Carlo (HPMC) and molecular dynamics (MD) simulations of the assembly processes were performed (see FIG. 32A-32F). A hard particle model using the stiff interaction potential curve that accounts for the Ag-NC shape (0≤λ≤1) and therefore isolates the role of particle shape was initially considered (see FIG. 32A, purple dashed line). However, the observed step-function-like, abrupt transition from the BCC to an FCC lattice when λ>0.5, which was consistent regardless of the starting structural configuration (see FIG. 32B left), indicating that the systems were unlikely to be kinetically arrested or otherwise trapped out of equilibrium. This result suggested that the hard particle model alone cannot explain the experimental observations of stabilized phase-intermediate structures.

Next, a soft repulsive interaction model between the particles was added to account for ligand-ligand interactions that, as hypothesized, could soften the shape of the Ag-NC core (see FIG. 32A, black solid line). MD simulations using this model (see FIG. 32A-32B) demonstrated the self-assembly and stabilization of N-W phase-intermediate structures (see FIG. 32B right). The plots of λ vs. τ from these simulations exhibited a smooth sigmoidal curve (see FIG. 32B right, blue and green spherical markers). Experimental data of SLs from Ag-NCs of identical particle volume (c.a. 520 nm³) but varying shape (λ: 0.17~0.95) aligned well with the sigmoidal curve (see FIG. 32B right, red spherical markers), demonstrating the strong agreement between experiments and simulation.

Further examination of the simulated SLs from particles with λ=0, 0.4, 0.8, and 1.0 provides greater insights into the orientational ordering of Ag-NCs (see FIG. 32C-32F). Across all tested X values, the bond orientational order diagrams (BOODs), computed for each particle's eight nearest neighbors, perfectly matched the {111}_{Ag-FCC} facet orientational order diagrams (FOODs) (see FIG. 32C-32F, bottom right), demonstrating that the {111}_{Ag-FCC} facets remained in contact in all the N-W phase-intermediate structures. Additionally, the FOODs of {111}_{Ag-FCC} and {100}_{Ag-FCC} facets display increasingly smeared signals with increasing λ (see FIG. 32C-32F, bottom left), indicating a gradual loss of Ag-NC facet alignment. This gradual decrease of particle orientational order was also confirmed in experiments by closely analyzing the ED patterns of SLs assembled from Ag-NCs with the same volume of c.a. 520 nm³ and various λ values of 0.17, 0.39, 0.56, 0.83, and 0.95 (see FIG. 32G-32K).

Although the SAED signals remained confined and spherical, the spot signals in the WAED patterns became increasingly smeared and elongated with increasing Ag-NC sphericity (see FIG. 32G-32K), which can be quantified by the width ratios of WAED peaks integrated along the longitudinal and radial directions (see purple bars in FIG. 32G-32K bottom). This result indicates increased particle rotational freedom with increasing Ag-NC sphericity, which is associated with the less sharply faceted (111) planes and thus weaker aligning torques, and reduced effective inter-facet interactions (see FIG. 32L). The excellent agreement between simulation results and experimental findings suggested that the N-W pathway was favored by local interactions, particularly through {111}_{Ag-FCC} facets, which remain preserved within the shared (001)_{SL-N-W} plane. Moreover, the tunable control over interaction magnitude enabled by shape-directed Ag-NC modifications and soft ligand interactions played a crucial role in stabilization of phase-intermediate SLs along the N-W martensitic pathway.

### Example X

### Light-Matter Coupling in Superlattice Films

Metallic NC SLs exhibit optical properties that arise from the light-matter coupling of their collective plasmons. See A. F. Kockum et al., Ultrastrong coupling between light and matter. Nat. Rev. Phys. 1, 19-40 (2019); J. Henzie et al., Self-assembly of uniform polyhedral silver nanocrystals into densest packings and exotic superlattices. Nat. Mater 11, 131-137 (2012); K. Bian et al., Formation of self-assembled gold nanoparticle supercrystals with facet-dependent surface plasmonic coupling. Nat. Commun. 9, 2365 (2018); N. S. Mueller et al., Deep strong light-matter coupling in plasmonic nanoparticle crystals. Nature 583, 780-784 (2020); M. Herran et al., Plasmonic bimetallic two-dimensional supercrystals for H₂ generation. Nat. Catal. 6, 1205-1214 (2023); Z. Zhu et al., Superstructures and SERS Properties of Gold Nanocrystals with Different Shapes. Angew. Chem. Int. Ed. 50, 1593-1596 (2011); E. B. Barros et al., Plasmon polaritons in nanoparticle supercrystals: Microscopic quantum theory beyond the dipole approximation. Phys. Rev. B 104, 035403 (2021). As used herein, “light-matter coupling” and “plasmon-photon hybridization” include regimes commonly referred to as strong coupling, ultrastrong coupling, and deep-strong coupling. In some embodiments, coupling is evidenced by mode splitting and/or anticrossing behavior in measured or simulated dispersion, and/or by the opening of a polaritonic gap in transmission/reflection spectra. In some embodiments, a reduced coupling strength is defined as η=Ω_{R}/ω_t, where Ω_{R} is a vacuum Rabi frequency and ω_t is a transverse collective plasmon frequency obtained, for example, from a Hopfield dispersion fit. In some embodiments, ultrastrong coupling corresponds to 1 on the order of ≥0.1, and deep-strong coupling corresponds to η on the order of ≥1; however, the invention is not limited to any particular threshold and includes systems intentionally designed to exhibit enhanced plasmonic interactions and/or strong plasmon-photon hybridization.

The interaction between plasmons localized on different NCs generates collective excitations that hybridize with photons into plasmon-polaritons, as previously demonstrated for spherical gold NC SLs. Because Ag-NCs are among the most plasmonic-responsive particles, optical responses of Ag-NC SLs with different numbers of NC layers in both transmission and reflection modes were measured (see FIG. 33A-33D, and FIG. 34A-34E. FIG. 35A-35D, FIG. 36, FIG. 37, FIG. 38). For all three SL architectures, i.e., FCC SLs from spherical Ag-NCs, phase-intermediate SLs from Ag-NCs with λ=0.56, and BCC SLs from mecon Ag-NCs, the transmission and reflection features shifted continuously toward lower energy, and new peaks emerged upon increasing the number of Ag-NC SL layers from one to six SL layers (see FIG. 33E-33G, and FIG. 36, FIG. 37). Numerical simulations of the optical spectra with a finite-difference time-domain software package reproduced the experimental spectra with excellent agreement (see FIG. 38). In the simulated 24-layer slabs, strong minima in reflectance below 2 eV arose from plasmon-polaritons standing waves across the SL slabs (see FIG. 33H). Between 2 and 4 eV, the total transmission dropped to zero (see FIG. 33H), consistent with the opening of a polaritonic gap in the electromagnetic spectrum. Such a gap is a hallmark of ultrastrong and deep-strong light-matter coupling, in which the coupling strength becomes comparable to, or exceeds, the bare excitation frequency, invalidating the conventional weak-coupling approximation and leading to non-perturbative light-matter hybridization and a qualitatively modified polaritonic dispersion. The Ag-NC SLs with fewer particle layers displayed less pronounced transmission and reflection features (see FIG. 33E-33G) because the SL thicknesses (<60 nm), were much less than the polariton wavelength (~150 nm for visible frequencies).

Light-matter coupling in the Ag-NC SLs was quantified by extracting the plasmon-polaritons energies from the simulated spectra and fitting them to a polaritonic Hopfield dispersion to determine the transverse collective plasmon frequency, ωₜ, and the vacuum Rabi frequency, Ω_{R}(see FIG. 33H-33I). Note that the experimentally determined polariton dispersion points agreed well with the polaritonic Hopfield dispersion fitted to simulations (see FIG. 33I). All three SLs exhibit Rabi frequencies >2 eV (FCC: 2.25 eV, phase-intermediate: 2.49 eV, BCC: 2.43 eV), exceeding their corresponding transverse collective plasmon energies (FCC: 2.16 eV, phase-intermediate: 2.37 eV, BCC: 2.30 eV) (see FIG. 33H-33I). The resulting reduced coupling strengths, η=Ω_{R}/ωₜ, thus reached the deep-strong light-matter coupling region (η>1) for all three SLs with a gradual and consistent increase from FCC (η=1.04), to phase-intermediate (η=1.05), to BCC (η=1.06).

These results demonstrate how the stable phase-intermediate structure provided an experimentally accessible structural bridge that traces the evolution of optical coupling across the FCC-BCC transformation pathway. The space-filling characteristic of the mecon shape in a BCC structure potentially allows such SLs to surpass the maximum packing fraction of 74% possible with FCC SLs from spheres. Simulations of a tight BCC structure with a packing fraction of 84.5% by reducing interparticle distance reached a decreased transverse collective plasmon frequency of ωₜ=1.54 eV and an increased Rabi frequency of Ω_{R}=2.77 eV (FIG. 41, FIG. S40). As a result, a much higher reduced coupling strength, η=1.80, was obtained.

According to the present disclosure, a unified design framework for achieving deep-strong coupling in self-assembled plasmonic NC SLs under ambient conditions is established.
(i) Packing fraction: Increasing the packing fraction of inorganic plasmonic cores while minimizing surfactant volume enhances collective coupling, leading to larger coupling constants and stronger polariton states. This trend is supported by simulations of mecon Ag-NC SLs, where reducing interparticle distance or increasing NC size both resulted in higher coupling strength (see FIG. 39 and FIG. 40). In contrast, variations in Bravais lattice symmetry, minor distortions, or local disorder play only secondary roles.
(ii) Shape engineering: Nonspherical, space-filling geometries, such as mecon-like-shaped NCs, can surpass the 74% packing limit of spheres, thereby further amplifying coupling strength. Simulations of BCC SLs assembled from 59-nm mecon Ag-NCs achieved a high packing fraction of 95.1% and a coupling constant of η=2.59, well exceeding those of FCC SLs composed of spherical Ag-NCs of identical size and interparticle distance (packing fraction of 70.4%, and η=1.36; FIG. 40).
(iii) Material selection: materials with higher free-electron densities, such as coinage metals, exhibit stronger plasmonic oscillators thus larger coupling strength. Consistently, the simulated FCC SLs composed of spherical Ag- and Au-NCs (identical size of 59 nm) both exhibited large coupling constants of 1.36 and 1.32, respectively (FIG. 40). The slightly higher value of Ag-NCs likely stems from their lower intrinsic losses relative to Au-NCs. Together, these insights establish a unifying design principle: maximizing free-carrier densities and core packing through shape-engineered architectures provides an effective route to achieving and tuning deep-strong light-matter coupling in self-assembled plasmonic SLs.

### Example XI

### Embodiments

The present disclosure provides a method of making a precious metal nanocrystal including the steps of creating a combination including one or more precious metal salts, a reducing agent, a nanocrystal growth promoter agent, a solvent, and a catalyst, optionally under an inert atmosphere, wherein precious metal cations are reduced to precious metal atoms, heating the combination to a first temperature and for a first time period at which the precious metal atoms in the combination produce precious metal clusters, heating the combination to a second temperature and for a second time period at which the precious metal clusters form precious metal nanocrystals. According to one aspect, the method further includes using an acid additive and/or a halide source. According to one aspect, the combination is free of an added acid additive and/or free of an added halide source. According to one aspect, the method further includes the step of isolating the precious metal nanocrystals. According to one aspect, the one or more precious metal salts comprise an ion of silver, gold, platinum, palladium, rhodium, ruthenium, iridium, osmium, or titanium. According to one aspect, the method includes two or more precious metal salts. According to one aspect, the reducing agent includes a fatty amine. According to one aspect, the fatty amine includes a C10 to C30 carbon chain, saturated or unsaturated, straight chain or branched chain. According to one aspect, the fatty amine includes oleylamine octylamine, nonylamine, decylamine, dodecylamine, laurylamine, myristylamine, palmitylamine, stearylamine, coco amine, tallow amine, or soya amine. According to one aspect, the nanocrystal growth promoter agent includes a fatty acid. According to one aspect, the fatty acid includes a C10 to C30 carbon chain, saturated or unsaturated, straight chain or branched chain. According to one aspect, the fatty acid includes palmitoleic acid, oleic acid, elaidic acid, linoleic acid, a-linolenic acid, arachidonic acid, eicosapentaenoic acid, docosahexaenoic acid, erucic acid, stearidonic acid, y-linolenic acid, lauric acid, myristic acid, palmitic acid, stearic acid, arachidic acid, behenic acid, or lignoceric acid. According to one aspect, the solvent includes a nonpolar solvent or a less polar solvent. According to one aspect, the nonpolar solvent or less polar solvent includes diphenyl ether, 1-octadecene, hexane, heptane, octane, benzene, toluene, chloroform, carbon tetrachloride, diethyl ether, pentane, cyclohexane, methylcyclohexane, decalin, benzyl ether, squalane, or squalene. According to one aspect, the catalyst includes a metal ion catalyst. According to one aspect, the metal ion catalyst is a metal salt. According to one aspect, the metal salt comprises a copper metal salt. According to one aspect, the copper metal salt includes Copper(II) sulfate (CuSO₄), Copper(II) chloride (CuCl₂), Copper(II) hydroxide (Cu(OH)₂), Copper(II) nitrate (Cu(NO₃)₂), Copper(II) oxide (CuO), Copper(II) acetate (Cu(OAc)₂), Copper(II) fluoride (CuF₂), Copper(II) bromide (CuBr₂), Copper(II) carbonate (CuCO₃), Copper(II) carbonate hydroxide (Cu₂CO₃(OH)₂), Copper(II) chlorate (Cu(ClO₃)₂), Copper(II) arsenate (Cu₃(AsO₄)₂), Copper(II) azide (Cu(N₃)₂), Copper(II) acetylacetonate (Cu(O₂C₅H₇)₂), Copper(II) aspirinate (C₃₆H₂₈Cu₂O₁₆), Copper(II) cyanurate (CuC₃HN₃O₃), Copper(II) glycinate (Cu(H₂NCH₂CO₂)₂), Copper(II) phosphate (Cu₃(PO₄)₂), Copper(II) perchlorate (Cu(ClO₄)₂), Copper(II) selenite (CuSeO₃), Copper(II) sulfide (CuS), Copper(II) thiocyanate (Cu(SCN)₂), Copper(II) triflate (Cu(OSO₂CF₃)₂), Copper(II) tetrafluoroborate (Cu(BF₄)₂), Copper(II) acetate triarsenite (Cu(C₂H₃O₂)₂·3Cu(AsO₂)₂), Copper(II) benzoate (Cu(C₆H₅CO₂)₂), Copper(II) arsenite (CuHAsO₃), Copper(II) chromite (Cu₂Cr₂O₅), Copper(II) gluconate (C₁₂H₂₂CuO₁₄), Copper(II) peroxide (CuO₂), Copper(II) usnate (C₁₈H₁₄CuO₇), Copper(II) oxychloride (Cu₂(OH)₃Cl), Copper(II) naproxen (C₂₈H₂₆CuO₆), or Copper(II) ibuprofenate (C₅₂H₆₈Cu₂O₈). According to one aspect, the first temperature is from 0 °C to 100 °C. According to one aspect, the second temperature is from 110 °C to 400 °C. According to one aspect, the precious metal nanocrystals range in diameter size from 3 nm to 15 nm. According to one aspect, the precious metal nanocrystals are characterized by a mecon morphology. According to one aspect, the precious metal nanocrystals are characterized by a spherical morphology. According to one aspect, the precious metal nanocrystals are characterized by a morphology between a mecon morphology and a spherical morphology. According to one aspect, the precious metal nanocrystals include surface bound reducing agent. According to one aspect, the method further includes the step of providing one or more ligands on the precious metal nanocrystals. According to one aspect, the precious metal nanocrystals include surface bound reducing agent and the one or more ligands are exchanged with the surface bound reducing agent. According to one aspect, the one or more ligands include a sulfur functionality. According to one aspect, the one or more ligands include a therapeutic agent, a diagnostic agent, an imaging agent, a dispersing agent, an electronic agent, a liquid molecule, a sensor agent or a catalytic agent.

The present disclosure provides a collection of precious metal nanocrystals including at least 95% mecon morphology and a diameter distribution within ±7% or less of a target diameter within 3 nm to 15 nm. The present disclosure provides a collection of precious metal nanocrystals including at least 95% spherical morphology and a diameter distribution within ±7% or less of a target diameter within 3 nm to 15 nm. The present disclosure provides a collection of precious metal nanocrystals including at least 95% morphology intermediate between mecon morphology and spherical morphology and a diameter distribution within ±7% or less of a target diameter within 3 nm to 15 nm.

The present disclosure provides a film including precious metal nanocrystals, wherein the precious metal nanocrystals have an architecture comprising a superlattice. According to one aspect, the precious metal nanocrystals include a spherical morphology, a mecon morphology, or a morphology intermediate therebetween. According to one aspect, the film has a coupling, wherein coupling is characterized by a reduced coupling strength η=Ω_{R}/ωₜ of at least about 0.1 (ultrastrong coupling) or exceeding 1 (deep-strong coupling). According to one aspect, the film comprises 1 to 1000 nanocrystal layers. According to one aspect, the film is disposed on a substrate including glass, quartz, silicon, sapphire, a polymer film or a metal foil.

The present disclosure provides a self-assembled stable superlattice including or formed from the self-assembly of precious metal nanocrystals having a mecon structure oriented in a body centered cubic lattice and exhibiting quantum level plasmon photon hybridization within a deep strong light matter coupling regime and having a deep-strong light-matter coupling region η>1. The present disclosure provides a self-assembled stable superlattice including or formed from the self-assembly of precious metal nanocrystals having a sphere structure oriented in a face centered cubic lattice and exhibiting quantum level plasmon photon hybridization within a deep strong light matter coupling regime and having a deep-strong light-matter coupling region η>1. The present disclosure provides a self-assembled stable superlattice including or formed from the self-assembly of precious metal nanocrystals having a structure intermediate between a mecon and a sphere in a dissymmetric orientation resembling an in transition phase of martensitic transformation and exhibiting quantum level plasmon photon hybridization within a deep strong light matter coupling regime and having a deep-strong light-matter coupling region η>1. The present disclosure provides a film formed from the self-assembled stable superlattice as described herein

The present disclosure provides a method of making a self-assembled stable superlattice of precious metal nanocrystals including the steps of suspending precious metal nanocrystals in a nonpolar medium, evaporating the nonpolar medium to result in the self-assembled stable superlattice of the precious metal nanocrystals. According to one aspect, the nonpolar medium includes one or more of hexane, cyclohexane, toluene, pentane, heptane, octane, or chloroform. According to one aspect, the nonpolar medium is evaporated over a time period from 5 seconds to 1 week.

1. A method of making a precious metal nanocrystal comprising
creating a combination including one or more precious metal salts, a reducing agent, a nanocrystal growth promoter agent, a solvent, and a catalyst, optionally under an inert atmosphere, wherein precious metal cations are reduced to precious metal atoms,
heating the combination to a first temperature and for a first time period at which the precious metal atoms in the combination produce precious metal clusters,
heating the combination to a second temperature and for a second time period at which the precious metal clusters form precious metal nanocrystals, and
optionally isolating the precious metal nanocrystals.

2. The method of claim 1, further comprising an acid additive and/or a halide source.

3. The method of claim 1, wherein the combination is free of an added acid additive and/or free of an added halide source.

4. (canceled)

5. The method of claim 1 wherein the one or more precious metal salts comprise an ion of silver, gold, platinum, palladium, rhodium, ruthenium, iridium, osmium, or titanium.

6. The method of claim 1 comprising two or more precious metal salts.

7. The method of claim 1 wherein the reducing agent comprises a fatty amine.

8. (canceled)

9. (canceled)

10. The method of claim 1 wherein the nanocrystal growth promoter agent comprises a fatty acid.

11. (canceled)

12. (canceled)

13. The method of claim 1 wherein the solvent comprises a nonpolar solvent or a less polar solvent.

14. (canceled)

15. The method of claim 1 wherein the catalyst comprises a copper metal ion catalyst.

16. (canceled)

17. (canceled)

18. (canceled)

19. The method of claim 1 wherein the first temperature is from 0 °C to 100 °C.

20. The method of claim 1 wherein the second temperature is from 110 °C to 400 °C.

21. The method of claim 1 wherein the precious metal nanocrystals range in diameter size from 3 nm to 15 nm.

22. The method of claim 1 wherein the precious metal nanocrystals are characterized by a mecon morphology, a spherical morphology or a morphology between a mecon morphology and a spherical morphology.

23. (canceled)

24. (canceled)

25. (canceled)

26. The method of claim 1 further comprising the step of providing one or more ligands on the precious metal nanocrystals.

27. (canceled)

28. (canceled)

29. (canceled)

30. A collection of precious metal nanocrystals comprising at least 95% mecon morphology, at least 95% spherical morphology, or at least 95% morphology intermediate between mecon morphology and spherical morphology and a diameter distribution within ±7% or less of a target diameter within 3 nm to 15 nm.

31. (canceled)

32. (canceled)

33. A film comprising precious metal nanocrystals, wherein the precious metal nanocrystals have an architecture comprising a superlattice.

34. (canceled)

35. (canceled)

36. (canceled)

37. (canceled)

38. A self-assembled stable superlattice comprising precious metal nanocrystals having a mecon structure, a sphere structure, or a structure intermediate between a mecon and a sphere, and exhibiting quantum level plasmon photon hybridization within a deep strong light matter coupling regime and having a deep-strong light-matter coupling region η>1.

39. (canceled)

40. (canceled)

41. A film formed from the self-assembled stable superlattice of claim 38.

42. (canceled)

43. (canceled)

44. A method of making a self-assembled stable superlattice of precious metal nanocrystals comprising
suspending precious metal nanocrystals in a nonpolar medium,
evaporating the nonpolar medium to result in the self-assembled stable superlattice of the precious metal nanocrystals.

45. (canceled)

46. (canceled)
